(19) United States
(12) Patent Application Publication
(10) Pub. No.: US 2024/0321960 A1
(43) Pub. Date: Sep. 26, 2024

(54) MULTI-STACK SEMICONDUCTOR DEVICE

(71) Applicant: Samsung Electronics Co., Ltd., Suwon-si (KR)

(72) Inventors: Jinchan Yun, Suwon-si (KR); Sungil Park, Suwon-si (KR); Jaehyun Park, Suwon-si (KR); Dongkyu Lee, Suwon-si (KR); Kyuman Hwang, Suwon-si (KR)

(21) Appl. No.: 18/613,324

(22) Filed: Mar. 22, 2024

(30) Foreign Application Priority Data
Mar. 24, 2023 (KR) 10-2023-0039262
Jul. 17, 2023 (KR) 10-2023-0092595

(51) Int. Cl. H01L 29/06; H01L 27/092; H01L 29/08; H01L 29/423; H01L 29/66; H01L 29/775; H01L 29/786

(52) U.S. Cl. CPC H01L 29/0673; H01L 27/092; H01L 29/0649; H01L 29/0847; H01L 29/42392; H01L 29/66439; H01L 29/775; H01L 29/78696

(57) ABSTRACT

A multi-stack semiconductor device includes a substrate, a device isolation layer, first channels, first gate lines covering the first channel, extending in a second horizontal direction, and spaced apart from each other in the first horizontal direction, first source/drain areas arranged on both sides of each of the first channels in the first horizontal direction, a second channel arranged apart from the first gate line in the vertical direction over any one of the first gate lines, a second gate line, second source/drain areas, a third channel arranged apart from the second gate line in the vertical direction over the second gate line, a third gate line, third source/drain areas, and a first lower source/drain contact extending in the vertical direction and connected to each of the first source/drain area, the second source/drain area, and the third source/drain area.

### CROSS-REFERENCE TO RELATED APPLICATION

This application is based on and claims priority under 35 U.S.C. § 119 to Korean Patent Application No. 10-2023-0039262, filed on Mar. 24, 2023, and Korean Patent Application No. 10-2023-0092595, filed on Jul. 17, 2023, in the Korean Intellectual Property Office, the disclosures of which are incorporated by reference herein in their entirety.

### BACKGROUND

The inventive concept relates generally to a multi-stack semiconductor device, and more particularly, to a multi-stack semiconductor device stacked in the vertical direction.

With the development of electronic technology, downscaling of integrated circuit devices has rapidly progressed. Also, in order to further increase the integration density of integrated circuit devices, stacked integrated circuit devices have been researched.

### SUMMARY

The inventive concept provides a multi-stack semiconductor device with improved operation reliability, reduced process difficulty, and increased integration.

Also, the problems to be solved by the inventive concept are not limited to the above problems, and other problems may be clearly understood by those of ordinary skill in the art from the following description.

In order to achieve technical objects, the inventive concept provides the following multi-stack semiconductor devices.

According to an aspect of the inventive concept, there is provided a multi-stack semiconductor device including a substrate, a device isolation layer defining an active area of the substrate, first channels arranged apart from each other in a vertical direction over the active area and spaced apart from each other in a first horizontal direction, first gate lines covering the first channel, extending in a second horizontal direction, and spaced apart from each other in the first horizontal direction, first source/drain areas arranged on both sides of each of the first channels in the first horizontal direction, a second channel arranged apart from the first gate line in the vertical direction over any one of the first gate lines, a second gate line covering the second channel and extending in the second horizontal direction, second source/drain areas arranged on both sides of the second channel in the first horizontal direction, a third channel arranged apart from the second gate line in the vertical direction over the second gate line, a third gate line covering the third channel and extending in the second horizontal direction, third source/drain areas arranged on both sides of the third channel in the first horizontal direction, and a first lower source/drain contact extending in the vertical direction and connected to each of the first source/drain area, the second source/drain area, and the third source/drain area.

According to another aspect of the inventive concept, there is provided a multi-stack semiconductor device including a substrate, a device isolation layer defining an active area of the substrate, a first channel arranged apart from each other in a vertical direction over the active area, a first gate line covering the first channel and extending in a second horizontal direction, a fourth gate line arranged apart from the first gate line in a first horizontal direction and extending in the second horizontal direction, first source/drain areas arranged on both sides of the first channel in the first horizontal direction, a second channel arranged apart from each other in the vertical direction over the first gate line and a second channel arranged apart from each other in the vertical direction over the fourth gate line, second gate lines covering the second channel, extending in the second horizontal direction, and spaced apart from each other in the first horizontal direction, second source/drain areas arranged on both sides of each of the second channels in the first horizontal direction, a third channel arranged apart from each other in the vertical direction over a second gate line overlapping the first channel in the vertical direction among the second gate lines, a third gate line covering the third channel and extending in the second horizontal direction, third source/drain areas arranged on both sides of the third channel in the first horizontal direction, and a first lower source/drain contact extending in the vertical direction and connected to each of the first source/drain area, the second source/drain area, and the third source/drain area.

According to another aspect of the inventive concept, there is provided a multi-stack semiconductor device including a substrate, a device isolation layer defining an active area of the substrate, first channels arranged apart from each other in a vertical direction over the active area and spaced apart from each other in a first horizontal direction, first gate lines covering the first channel, extending in a second horizontal direction, and spaced apart from each other in the first horizontal direction, first source/drain areas arranged on both sides of each of the first channels in the first horizontal direction, a second channel arranged apart from the first gate line in the vertical direction over any one of the first gate lines, a second gate line covering the second channel and extending in the second horizontal direction, second source/drain areas arranged on both sides of the second channel in the first horizontal direction, a first insulating layer arranged on an upper surface of each of the first source/drain areas and the second source/drain areas, a third channel arranged apart from the second gate line in the vertical direction over the second gate line, a third gate line covering the third channel and extending in the second horizontal direction, third source/drain areas arranged on both sides of the third channel in the first horizontal direction, a fifth insulating layer arranged over a first gate line not overlapping the second gate line among the first gate lines, a first lower source/drain contact extending in the vertical direction and connected to each of the first source/drain area, the second source/drain area, and the third source/drain area, a first upper gate contact connected to the third gate line, a second upper gate contact connected to a first gate line not overlapping the second gate line among the first gate lines, a first lower gate contact connected to a first gate line overlapping the second gate line among the first gate lines, a first upper source/drain contact connected to each of the second source/drain area and the third source/drain area, a second lower source/drain contact connected to a first source/drain area arranged on a side of the second upper gate contact in the first horizontal direction, a first upper signal line electrically connected to the first upper source/drain contact, a second upper signal line electrically connected to the first upper gate contact and the second upper gate contact, a first lower signal line electrically connected to the first lower source/drain contact, a second lower signal line electrically connected to the second lower source/drain contact, and a third lower signal line electrically connected to the first lower gate contact, wherein each of the first gate lines includes a first sub-gate and a first main gate, a first sub-gate insulating layer is arranged on an upper surface of the first sub-gate, and a first main gate insulating layer is arranged on an upper surface of the first main gate, the second gate line includes a second sub-gate and a second main gate, a second sub-gate insulating layer is arranged on an upper surface of the second sub-gate, and a second main gate insulating layer is arranged on an upper surface of the second main gate, and the fifth insulating layer overlaps each of the second gate line and the third gate line in the first horizontal direction.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a circuit diagram of a NOR circuit according to some embodiments of the inventive concept;

FIGS. 2A and 2B are schematic diagrams illustrating multi-stack semiconductor devices according to the inventive concept for implementing the NOR circuit of FIG. 1;

FIGS. 3A and 3B are plan views depicting example layout diagrams for describing the multi-stack semiconductor device of FIG. 2A;

FIGS. 4A to 4D are cross-sectional views taken along lines A1-A1′, A2-A2′, B1-B1′, and B2-B2′ of FIGS. 3A and 3B, respectively;

FIGS. 5A and 5B are plan views depicting example layout diagrams for describing the multi-stack semiconductor device of FIG. 2B;

FIGS. 6A to 6D are cross-sectional views taken along lines A1-A1′, A2-A2′, B1-B1′, and B2-B2′ of FIGS. 5A and 5B, respectively;

FIGS. 7A to 18E are plan views and cross-sectional views for describing intermediate processes in an example method of manufacturing the multi-stack semiconductor device of FIG. 2A, and FIGS. 19A to 29H are plan views and cross-sectional views for describing intermediate processes in an example method of manufacturing the multi-stack semiconductor device of FIG. 2B;

FIG. 30 is a circuit diagram of a NAND circuit according to some embodiments of the inventive concept;

FIGS. 31A and 31B are schematic diagrams illustrating multi-stack semiconductor devices according to the inventive concept for implementing the NAND circuit of FIG. 30;

FIGS. 32A and 32B are plan views depicting example layout diagrams for describing the multi-stack semiconductor device of FIG. 31A; and

FIGS. 33A and 33B are plan views depicting example layout diagrams for describing the multi-stack semiconductor device of FIG. 31B.

### DETAILED DESCRIPTION

Hereinafter, embodiments will be described in detail with reference to the accompanying drawings. Herein, like reference numerals will denote like elements, and redundant descriptions thereof will be omitted for conciseness.

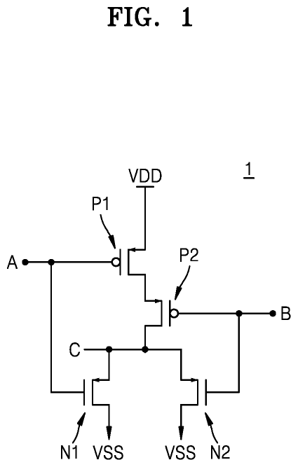

FIG. 1 is a circuit diagram of a NOR circuit 1 according to some embodiments of the inventive concept.

Referring to FIG. 1, the NOR circuit 1 may include first and second p-channel metal-oxide-semiconductor field-effect transistors (PMOSFETs) P1 and P2, respectively, connected in series to each other, and first and second n-channel metal-oxide-semiconductor field-effect transistors (NMOSFETs) N1 and N2, respectively, connected in parallel to each other, and the first and second NMOSFETs N1 and N2 may be connected in series to the second PMOSFET P2. An output node may be located between the second PMOSFET P2 and the first and second NMOSFETs N1 and N2.

The first and second PMOSFETs P1 and P2 may be connected in series to each other between the output node and a supply voltage terminal for providing first power VDD, and the first and second NMOSFETs N1 and N2 may be connected in parallel to each other between the output node and a ground voltage terminal for providing second power VSS. In the NOR circuit 1, each of the first PMOSFET P1 and the first NMOSFET N1 may receive a first signal A through a gate thereof, each of the second PMOSFET P2 and the second NMOSFET N2 may receive a second signal B through a gate thereof, and a third signal C may be output from the output node.

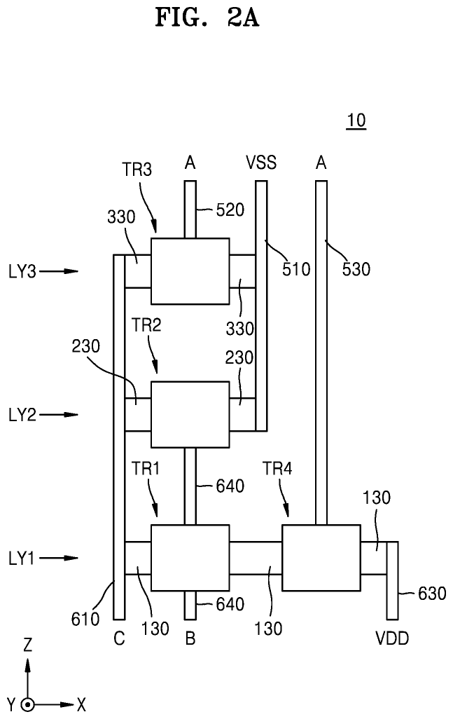

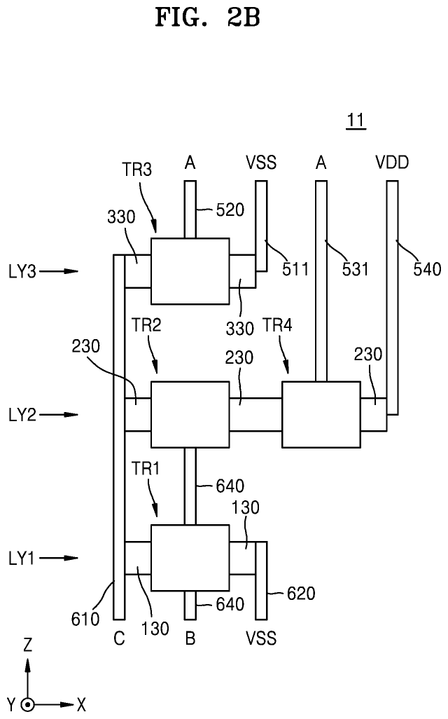

FIGS. 2A and 2B are schematic diagrams illustrating multi-stack semiconductor devices 10 and 11, respectively, according to the inventive concept for implementing the NOR circuit 1 of FIG. 1.

First, referring to FIG. 2A, the multi-stack semiconductor device 10 may include a first transistor TR1, a second transistor TR2, a third transistor TR3, a fourth transistor TR4, a first upper gate contact 520, a second upper gate contact 530, a first upper source/drain contact 510, a first lower gate contact 640, a first lower source/drain contact 610, and a second lower source/drain contact 630. The first transistor TR1 may represent transistor P2 in the NOR circuit 1 of FIG. 1, the second transistor TR2 may represent transistor N2, the third transistor TR3 may represent transistor N1, and the fourth transistor TR4 may represent transistor P1.

The first transistor TR1 and the fourth transistor TR4 may be located in a first layer LY1, the second transistor TR2 may be located in a second layer LY2, and the third transistor TR3 may be located in a third layer LY3. The first to third layers LY1, LY2, and LY3 may be located at different vertical levels (i.e., in a Z-axis direction), the second layer LY2 may be located at a higher vertical level than the first layer LY1, and the third layer LY3 may be located at a higher vertical level than the second layer LY2. That is, the first transistor TR1 and the fourth transistor TR4 may be located at the same vertical level, the second transistor TR2 may be located at a higher vertical level than the first transistor TR1 and the fourth transistor TR4, and the third transistor TR3 may be located at a higher vertical level than the second transistor TR2.

The first transistor TR1 and the fourth transistor TR4 may be arranged in a line in a first horizontal direction (i.e., in an X-axis direction) perpendicular to the vertical direction. Hereinafter, in the drawings, an X-axis direction may represent a direction in which the first transistor TR1 and the fourth transistor TR4 are arranged in a line, a Z-axis direction may represent a direction in which the first transistor TR1 and the second transistor TR2 are spaced apart from each other, and a second horizontal direction (i.e., a Y-axis direction) may represent a direction perpendicular to the Z-axis direction and intersecting the X-axis direction.

Also, hereinafter, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The first transistor TR1 and the fourth transistor TR4 may be arranged in a line in the first horizontal direction X. According to embodiments, the first transistor TR1 and the fourth transistor TR4 may be connected in series and may share a first source/drain area 130 formed between the first transistor TR1 and the fourth transistor TR4.

The second transistor TR2 may be stacked over any one of the first transistor TR1 and the fourth transistor TR4. For example, the second transistor TR2 may be stacked over the first transistor TR1 in the vertical direction Z. In this case, the fourth transistor TR4 may not overlap each of the second transistor TR2 and the third transistor TR3 in the vertical direction Z. However, the inventive concept is not limited thereto, and the second transistor TR2 may be stacked over the fourth transistor TR4 in the vertical direction Z. The third transistor TR3 may be stacked over the second transistor TR2 in the vertical direction Z. The term “overlap” (or “overlapping,” or like terms), as used herein, is intended to broadly refer to a first element that intersects with at least a portion of a second element in the vertical direction (i.e., Z-axis direction), but does not require that the first and second elements be completely aligned with one another in a horizontal plane (i.e., in the X-axis direction and/or Y-axis direction).

Each of the first to fourth transistors TR1, TR2, TR3, and TR4 may be a field-effect transistor having a gate-all-around (GAA) structure; however, the inventive concept is not limited thereto, and each of the first to fourth transistors TR1, TR2, TR3, and TR4 may be a field-effect transistor having a fin structure.

The first upper gate contact 520 may be electrically connected to the third transistor TR3. The first upper gate contact 520 may be arranged to provide the first signal A to the third transistor TR3. The second upper gate contact 530 may be electrically connected to the fourth transistor TR4. The second upper gate contact 530 may be arranged to provide the first signal A to the fourth transistor TR4. The first upper gate contact 520 may extend downward in the vertical direction Z to the third layer LY3, and the second upper gate contact 530 may extend downward in the vertical direction Z to the first layer LY1.

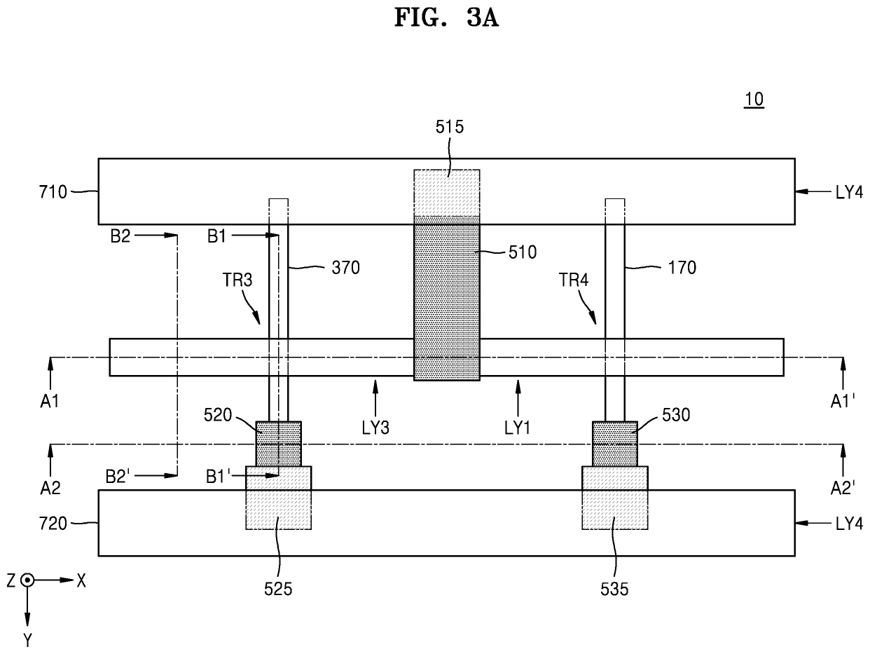

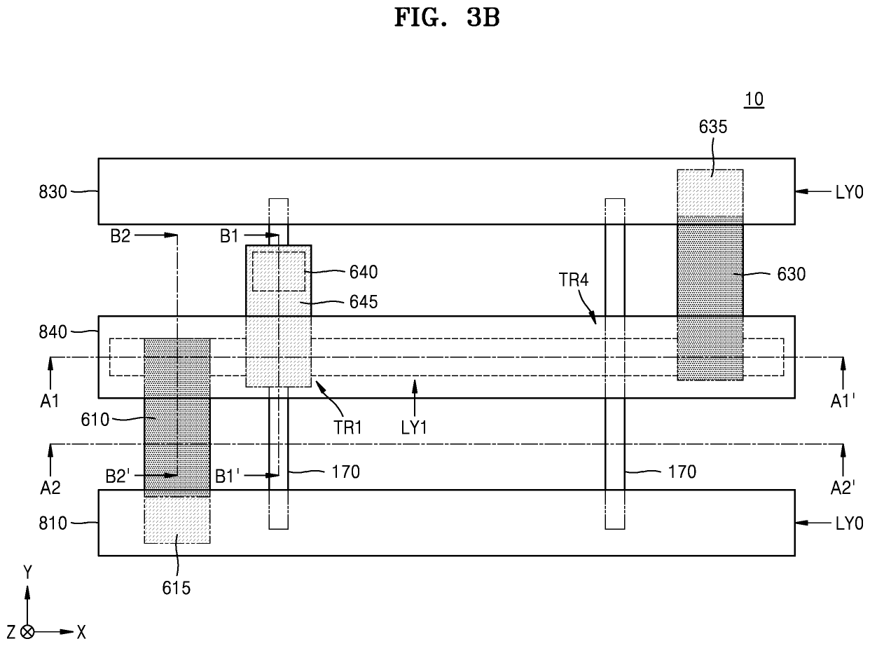

According to one or more embodiments, each of the first upper gate contact 520 and the second upper gate contact 530 may be electrically connected to the same upper signal line, for example, a second upper signal line 720 (see FIG. 3A).

The first upper source/drain contact 510 may be electrically connected to each of the second transistor TR2 and the third transistor TR3. Particularly, the first upper source/drain contact 510 may be electrically connected to each of a second source/drain area 230 of the second transistor TR2 and a third source/drain area 330 of the third transistor TR3. The first upper source/drain contact 510 may be arranged to provide the second power VSS to each of the second transistor TR2 and the third transistor TR3.

According to one or more embodiments, the vertical level of the lower surface of the first upper source/drain contact 510 may be higher than the vertical level of the lower surface of the second upper gate contact 530, and the vertical level of the lower surface of the first upper gate contact 520 may be higher than the vertical level of the lower surface of the first upper source/drain contact 510.

The first upper source/drain contact 510 may include a metal, a conductive metal nitride, or a combination thereof. For example, the first upper source/drain contact 510 may include tungsten (W), copper (Cu), aluminum (A1), titanium (Ti), tantalum (Ta), titanium nitride (TiN), tantalum nitride (TaN), or any alloy thereof or any combination thereof.

The first lower gate contact 640 may be electrically connected to the first transistor TR1. The first lower gate contact 640 may be arranged to provide the second signal B to the first transistor TR1. The first lower gate contact 640 may also be used to provide the second signal B to the second transistor TR2. The first lower source/drain contact 610 may be electrically connected to each of the first transistor TR1, the second transistor TR2, and the third transistor TR3. The first lower source/drain contact 610 may have a shape extending in the vertical direction Z. The first lower source/drain contact 610 may be electrically connected to the first source/drain area 130 formed on the side opposite to the fourth transistor TR4 among the first source/drain areas 130 formed on both sides of the first transistor TR1 in the first horizontal direction X. Likewise, the first lower source/drain contact 610 may be electrically connected to the first source/drain area 130 not shared with the fourth transistor TR4 among the first source/drain areas 130 formed on both sides of the first transistor TR1 in the first horizontal direction X. The first lower source/drain contact 610 may be electrically connected to the second source/drain area 230 of the second transistor TR2 and may be electrically connected to the third source/drain area 330 of the third transistor TR3. In this case, the first lower source/drain contact 610 may be electrically connected to the second source/drain area 230 formed on the side opposite to the first upper source/drain contact 510 among the second source/drain areas 230 and may be electrically connected to the third source/drain area 330 formed on the side opposite to the first upper source/drain contact 510 among the third source/drain areas 330. The first lower source/drain contact 610 may be arranged to provide, to a first lower signal line 810 (see FIG. 3B), the third signal C output from the first transistor TR1, the second transistor TR2, and the third transistor TR3. The second lower source/drain contact 630 may be electrically connected to the fourth transistor TR4. Particularly, the second lower source/drain contact 630 may be electrically connected to the first source/drain area 130 formed on the side opposite to the first transistor TR1 among the first source/drain areas 130 of the fourth transistor TR4. That is, the second lower source/drain contact 630 may be electrically connected to the first source/drain area 130 not shared with the first transistor TR1 among the first source/drain areas 130 of the fourth transistor TR4. The second lower source/drain contact 630 may be arranged to provide the first power VDD to the fourth transistor TR4.

Consequently, the multi-stack semiconductor device 10 may include at least four transistors TR1, TR2, TR3, and TR4 and may have, for example, a shape in which four transistors are arranged in two lines in the first horizontal direction X, wherein three transistors are stacked in the vertical direction Z in one line and one transistor is provided in the first layer LY1 in the other line. According to embodiments, the multi-stack semiconductor device 10 may include four transistors TR1, TR2, TR3, and TR4 arranged in an ‘L’ shape on the X-Z plane.

Referring to FIG. 2B, the multi-stack semiconductor device 11 may include a first transistor TR1, a second transistor TR2, a third transistor TR3, a fourth transistor TR4, a first upper gate contact 520, a second upper gate contact 531, a first upper source/drain contact 511, a second upper source/drain contact 540, a first lower gate contact 640, a first lower source/drain contact 610, and a third lower source/drain contact 620. The first transistor TR1 may represent transistor N2 in the NOR circuit 1 of FIG. 1, the second transistor TR2 may represent transistor P2, the third transistor TR3 may represent transistor N1, and the fourth transistor TR4 may represent transistor P1. Hereinafter, redundant descriptions with those of the multi-stack semiconductor device 10 given above with reference to FIG. 2A will be omitted and differences therebetween will be mainly described.

The first transistor TR1 may be located in the first layer LY1, the second transistor TR2 and the fourth transistor TR4 may be located in the second layer LY2, and the third transistor TR3 may be located in the third layer LY3. The second transistor TR2 and the fourth transistor TR4 may be located at the same vertical level, both the second transistor TR2 and the fourth transistor TR4 may be located at a higher vertical level than the first transistor TR1, and the third transistor TR3 may be located at a higher vertical level than the second transistor TR2 and the fourth transistor TR4.

The second transistor TR2 and the fourth transistor TR4 may be arranged in a line in the first horizontal direction X. According to embodiments, the second transistor TR2 and the fourth transistor TR4 may be connected in series and may share the second source/drain area 230 formed between the second transistor TR2 and the fourth transistor TR4. The fourth transistor TR4 may not overlap each of the first transistor TR1 and the third transistor TR3 in the vertical direction Z.

The first upper gate contact 520 may be electrically connected to the third transistor TR3, and the second upper gate contact 531 may be electrically connected to the fourth transistor TR4.

The first upper gate contact 520 may be arranged to provide the first signal A to the third transistor TR3, and the second upper gate contact 531 may be arranged to provide the first signal A to the fourth transistor TR4. The first upper gate contact 520 may extend downward in the vertical direction Z to the third layer LY3, and the second upper gate contact 531 may extend downward in the vertical direction Z to the second layer LY2. According to embodiments, each of the first upper gate contact 520 and the second upper gate contact 531 may be electrically connected to the same upper signal line, for example, a second upper signal line 720 (see FIG. 5A).

The first upper source/drain contact 511 may be electrically connected to the third transistor TR3. Particularly, the first upper source/drain contact 511 may be electrically connected to the third source/drain area 330 of the third transistor TR3. In this case, the first upper source/drain contact 511 may not be connected to the second transistor TR2. The first upper source/drain contact 511 may be arranged to provide the second power VSS to the third transistor TR3. The second upper source/drain contact 540 may be electrically connected to the fourth transistor TR4. Particularly, the second upper source/drain contact 540 may be electrically connected to the second source/drain area 230 formed on the side opposite to the second transistor TR2 among the second source/drain areas 230 formed on both sides of the fourth transistor TR4. That is, the second upper source/drain contact 540 may be electrically connected to the second source/drain area 230 not shared with the second transistor TR2 among the second source/drain areas 230 of the fourth transistor TR4. The second upper source/drain contact 540 may be arranged to provide the first power VDD to the fourth transistor TR4.

According to embodiments, the lower surface of the first upper source/drain contact 511 and the lower surface of the first upper gate contact 520 may be substantially located in the third layer LY3, and the lower surface of the second upper source/drain contact 540 and the lower surface of the second upper gate contact 531 may be substantially located in the second layer LY2.

The first lower gate contact 640 may be electrically connected to the first transistor TR1. The first lower gate contact 640 may be arranged to provide the second signal B to the first transistor TR1. The first lower gate contact 640 may also be electrically connected to the second transistor TR2 and may be arranged to provide the second signal B to the second transistor TR2.

The first lower source/drain contact 610 may be electrically connected to each of the first transistor TR1, the second transistor TR2, and the third transistor TR3. The first lower source/drain contact 610 may be electrically connected to each of the first source/drain area 130 of the first transistor TR1, the second source/drain area 230 of the second transistor TR2, and the third source/drain area 330 of the third transistor TR3. The first lower source/drain contact 610 may be arranged to provide, to a first lower signal line 810 (see FIG. 5B), the third signal C output from the first transistor TR1, the second transistor TR2, and the third transistor TR3. The third lower source/drain contact 620 may be electrically connected to the first transistor TR1. Particularly, the third lower source/drain contact 620 may be electrically connected to the first source/drain area 130 of the first transistor TR1. The third lower source/drain contact 620 may be arranged to provide the second power VSS to the first transistor TR1.

The multi-stack semiconductor device 11 may include at least four transistors TR1, TR2, TR3, and TR4 and may have, for example, a shape in which four transistors are arranged in two lines in the first horizontal direction X, wherein three transistors are stacked in the vertical direction Z in one line and one transistor is provided in the second layer LY2 in the other line. According to embodiments, the multi-stack semiconductor device 11 may include four transistors TR1, TR2, TR3, and TR4 arranged in an ‘ ’ shape on the X-Z plane.

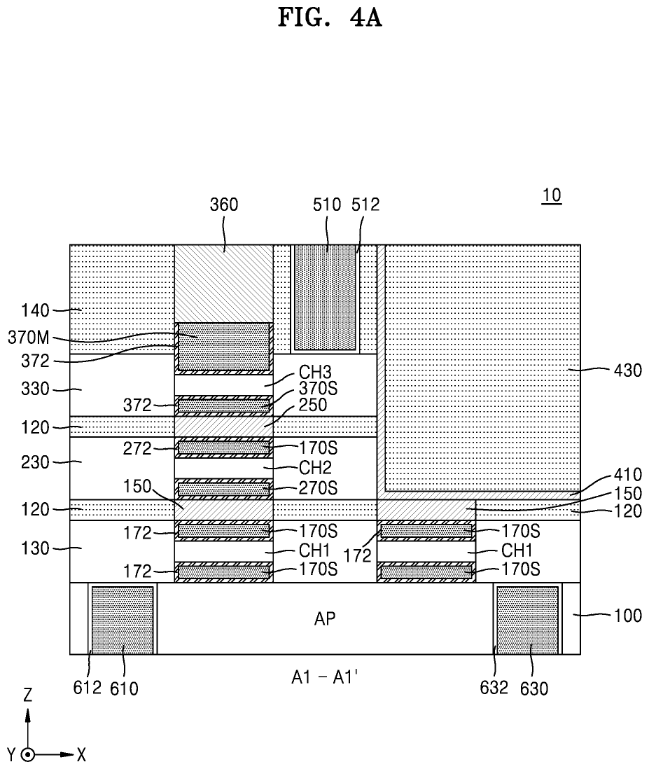

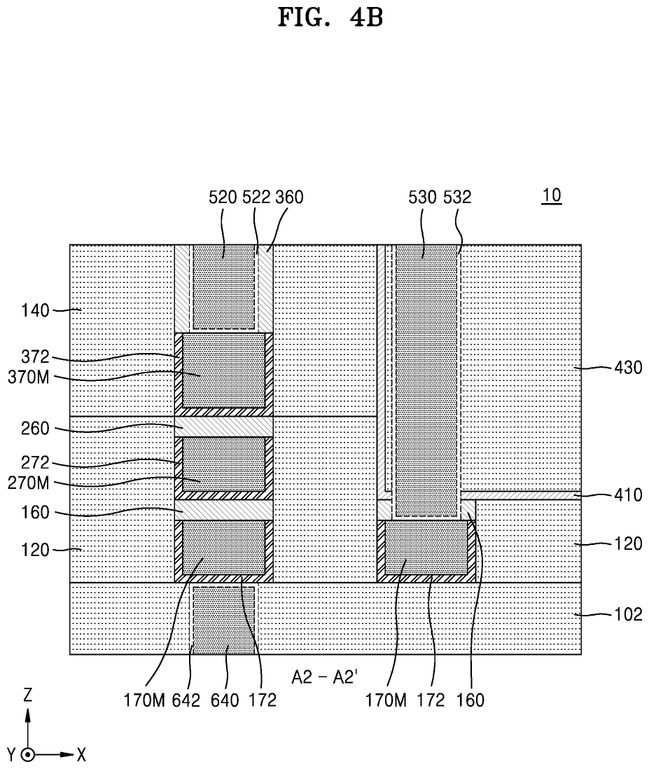

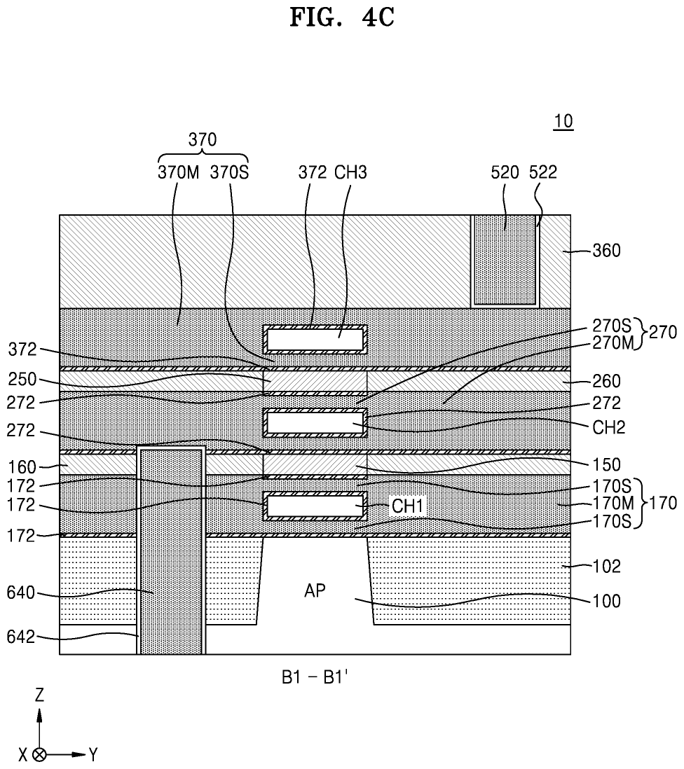

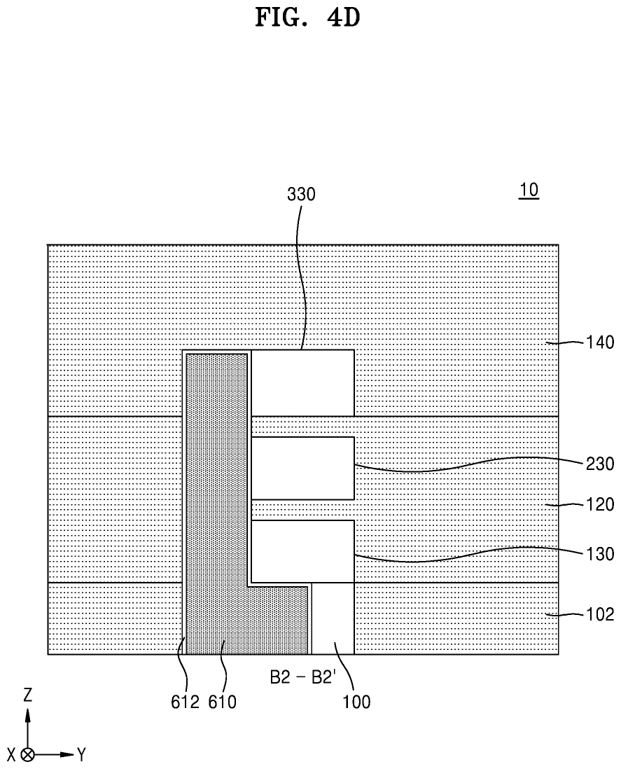

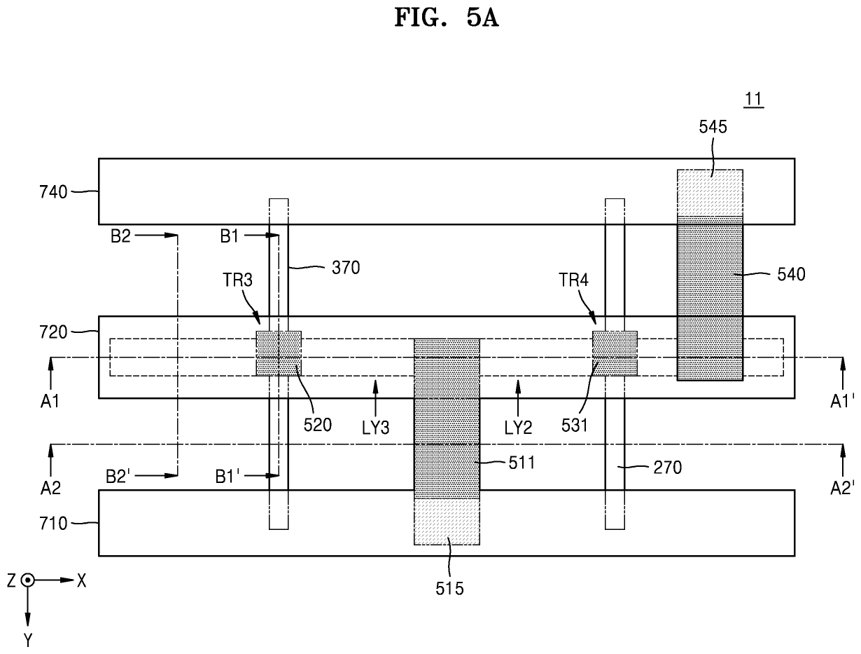

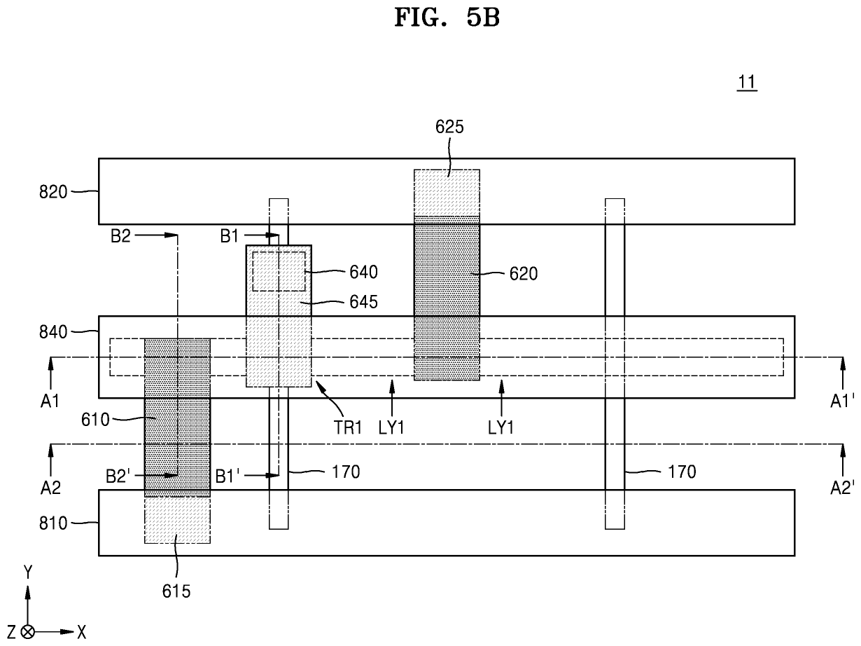

FIGS. 3A and 3B are plan views depicting example layout diagrams for describing the multi-stack semiconductor device 10 of FIG. 2A. FIGS. 4A to 4D are cross-sectional views taken along lines A1-A1′, A2-A2′, B1-B1′, and B2-B2′ of FIGS. 3A and 3B, respectively. Hereinafter, redundant descriptions with those given above with reference to FIGS. 1 and 2A will be omitted and differences therebetween will be mainly described.

Referring to FIGS. 3A, 3B, and 4A to 4D, the multi-stack semiconductor device 10 may further include a first upper signal line 710, a second upper signal line 720, a first lower signal line 810, a second lower signal line 830, and a third lower signal line 840. Each of the first upper signal line 710 and the second upper signal line 720 may extend in the first horizontal direction X and may be located in a fourth layer LY4 in the vertical direction Z. According to one or more embodiments, the fourth layer LY4 may be located at a higher vertical level than the third layer LY3, relative to a reference base structure (e.g., an upper surface of a substrate on which the semiconductor device 10 is formed). Thus, the first upper signal line 710 located in the fourth layer LY4 may be located higher than the third transistor TR3, the first upper source/drain contact 510, and a first upper source/drain via 515 in the vertical direction Z, and the second upper signal line 720 may be located higher than the third transistor TR3, the first upper gate contact 520, a first upper gate via 525, the second upper gate contact 530, and a second upper gate via 535 in the vertical direction Z.

The first upper signal line 710 may be configured to provide the second power VSS, for example, negative potential or ground potential power, to each of the second transistor TR2 and the third transistor TR3. According to embodiments, the first upper signal line 710 may be configured to provide the second power VSS to each of the second transistor TR2 and the third transistor TR3 through the first upper source/drain via 515 and the first upper source/drain contact 510. The first upper signal line 710 may be physically connected to (i.e., contact) the first upper source/drain via 515, the first upper source/drain via 515 may be physically connected to the first upper source/drain contact 510, and the first upper source/drain contact 510 may be physically connected to the second transistor TR2 (see FIG. 2A) and the third transistor TR3. However, the inventive concept is not limited thereto, and the first upper signal line 710 may be configured to provide the second power VSS to the second transistor TR2 and the third transistor TR3 through the first upper source/drain contact 510 without using the first upper source/drain via 515. The term “contact,” as may be used herein, is intended to broadly refer to electrical and/or physical contact between two or more layers, structures or other elements.

The first upper source/drain via 515 may be located at a higher vertical level than the first upper source/drain contact 510. According to embodiments, the first upper source/drain via 515 may connect the first upper signal line 710 with the first upper source/drain contact 510 and may extend in the vertical direction Z. At least a portion of the first upper source/drain via 515 may overlap each of the first upper signal line 710 and the first upper source/drain contact 510 in the vertical direction Z.

The second upper signal line 720 may be configured to provide the first signal A to each of the third transistor TR3 and the fourth transistor TR4. Particularly, the second upper signal line 720 may be arranged to provide the first signal A to each of a third gate line 370 of the third transistor TR3 and a first gate line 170 of the fourth transistor TR4. The second upper signal line 720 may be configured to provide the first signal A to the third transistor TR3 through the first upper gate via 525 and the first upper gate contact 520. Also, the second upper signal line 720 may be configured to provide the first signal A to the fourth transistor TR4 through the second upper gate via 535 and the second upper gate contact 530.

The second upper signal line 720 may be physically connected to (i.e., contact) each of the first upper gate via 525 and the second upper gate via 535, the first upper gate via 525 may be physically connected to the first upper gate contact 520, and the second upper gate via 535 may be physically connected to the second upper gate contact 530. However, the inventive concept is not limited thereto, and the second upper signal line 720 may be configured to provide the first signal A to the third transistor TR3 through the first upper gate contact 520 and to the fourth transistor TR4 through the second upper gate contact 530 without using the first upper gate via 525 and the second upper gate via 535.

The first upper gate via 525 may be located at a higher vertical level than the first upper gate contact 520. According to embodiments, the first upper gate via 525 may connect the second upper signal line 720 with the first upper gate contact 520 and may extend in the vertical direction Z. At least a portion of the first upper gate via 525 may at least partially overlap each of the second upper signal line 720 and the first upper gate contact 520 in the vertical direction Z.

The second upper gate via 535 may be located at a higher vertical level than the second upper gate contact 530. According to embodiments, the second upper gate via 535 may connect the second upper signal line 720 with the second upper gate contact 530 and may extend in the vertical direction Z. At least a portion of the second upper gate via 535 may at least partially overlap each of the second upper signal line 720 and the second upper gate contact 530 in the vertical direction Z. The lower surface of the first upper gate contact 520 may be located at a higher vertical level than the lower surface of the second upper gate contact 530.

Each of the first lower signal line 810, the second lower signal line 830, and the third lower signal line 840 may extend in the first horizontal direction X and may be located lower than the first layer LY1 in the vertical direction Z. A layer where each of the first lower signal line 810, the second lower signal line 830, and the third lower signal line 840 is located may be defined as a 0th layer LY0. The 0th layer LY0 may be located at a lower vertical level than the first layer LY1. Thus, the first lower signal line 810, the second lower signal line 830, and the third lower signal line 840 located in the 0th layer LY0 may be located at a lower vertical level than the first transistor TR1, the fourth transistor TR4, the first lower source/drain contact 610, a first lower source/drain via 615, the first lower gate contact 640, a first lower gate via 645, the second lower source/drain contact 630, and a second lower source/drain via 635.

The first lower signal line 810 may be configured to output the third signal C from the first transistor TR1, the second transistor TR2, and the third transistor TR3. The first lower signal line 810 may output the third signal C from the first transistor TR1, the second transistor TR2, and the third transistor TR3 through the first lower source/drain contact 610 and the first lower source/drain via 615. The first lower source/drain contact 610 may be physically connected to the first transistor TR1, the second transistor TR2, and the third transistor TR3. However, the inventive concept is not limited thereto, and the first lower signal line 810 may receive the third signal C from the first transistor TR1, the second transistor TR2, and the third transistor TR3 through the first lower source/drain contact 610 without using the first lower source/drain via 615. The first lower source/drain via 615 may connect the first lower source/drain contact 610 with the first lower signal line 810 and may extend in the vertical direction Z. At least a portion of the first lower source/drain via 615 may at least partially overlap the first lower source/drain contact 610 and the first lower signal line 810 in the vertical direction Z.

The second lower signal line 830 may be configured to provide the first power VDD, for example, positive voltage supply, to the fourth transistor TR4. The second lower signal line 830 may be configured to provide the first power VDD to the fourth transistor TR4 through the second lower source/drain via 635 and the second lower source/drain contact 630. The second lower signal line 830 may be physically connected to the second lower source/drain via 635. However, the inventive concept is not limited thereto, and the second lower signal line 830 may be configured to provide the first power VDD to the fourth transistor TR4 through the second lower source/drain contact 630 without using the second lower source/drain via 635. The second lower source/drain via 635 may connect the second lower source/drain contact 630 with the second lower signal line 830 and may extend in the vertical direction Z. At least a portion of the second lower source/drain via 635 may at least partially overlap the second lower source/drain contact 630 and the second lower signal line 830 in the vertical direction Z.

The third lower signal line 840 may be configured to provide the second signal B to the first transistor TR1 and the second transistor TR2. The third lower signal line 840 may be configured to provide the second signal B to the first transistor TR1 and the second transistor TR2 through the first lower gate via 645 and the first lower gate contact 640. The third lower signal line 840 may be physically connected to the first lower gate contact 640, and the first lower gate contact 640 may be physically connected to the first transistor TR1 and the second transistor TR2. However, the inventive concept is not limited thereto, and the third lower signal line 840 may be configured to provide the second signal B to the first transistor TR1 and the second transistor TR2 through the first lower gate contact 640 without using the first lower gate via 645. The first lower gate via 645 may connect the third lower signal line 840 with the first lower gate contact 640 and may extend in the vertical direction Z. At least a portion of the first lower gate via 645 may at least partially overlap the third lower signal line 840 and the first lower gate contact 640 in the vertical direction Z.

The multi-stack semiconductor device 10 may include a substrate 100 located under the first transistor TR1 and the fourth transistor TR4 in the vertical direction Z. The substrate 100 may include an active area AP that is an area protruding (i.e., extending) upward in the vertical direction Z. The substrate 100 may include a semiconductor material such as silicon (Si) or germanium (Ge) or a compound semiconductor such as silicon germanium (SiGe), silicon carbide (SiC), gallium arsenide (GaAs), indium arsenide (InAs), indium gallium arsenide (InGaAs), or indium phosphide (InP). The substrate 100 may include a conductive area, for example, a well doped with dopants or a structure doped with dopants. A device isolation layer 102 may be located on the side surface of the active area AP in the second horizontal direction Y. The active area AP of the substrate 100 may be defined by the device isolation layer 102. The device isolation layer 102 may cover the sidewall of the active area AP while filling a plurality of trench areas formed on the side of the active area AP in the second horizontal direction Y. The device isolation layer 102 may include a silicon oxide layer; however, the inventive concept is not limited thereto. The term “cover” (or “covering, or other like terms), as may be used herein, is intended to broadly refer to a material, layer or structure being on or over another material, layer or structure, but does not require the material, layer or structure to entirely cover the other material, layer or structure. Thus, for example, a material or layer having openings or holes therein may still be considered to cover another material or layer.

Each of the first transistor TR1 and the fourth transistor TR4 may include a first channel CH1, a first gate line 170, and a first source/drain area 130. The first channel CH1 may be stacked over the active area AP while being spaced apart therefrom in the vertical direction Z. The first channel CH1 of the first transistor TR1 and the first channel CH1 of the fourth transistor TR4 may be arranged spaced apart from each other in the first horizontal direction X over the active area AP extending in the first horizontal direction X. According to embodiments, the first channel CH1 may include a nanosheet; however, the inventive concept is not limited thereto. According to one or more embodiments, each of the first transistor TR1 and the fourth transistor TR4 may include a plurality of first channels CH1. The plurality of first channels CH1 included in each of the first transistor TR1 and the fourth transistor TR4 may be stacked and spaced apart from each other in the vertical direction Z. For example, the first transistor TR1 may include a plurality of first channels CH1 overlapping each other in the vertical direction Z, and the fourth transistor TR4 may also include a plurality of first channels CH1 overlapping each other in the vertical direction Z. Each of the first channels CH1 may function as a channel area. The number of first channels CH1 included in each of the first transistor TR1 and the fourth transistor TR4 is not particularly limited.

A channel may be formed near the upper and lower surfaces of the first channel CH1. According to one or more embodiments, the first channel CH1 may include the same material as the substrate 100, although embodiments are not limited thereto. According to some embodiments, the first channel CH1 may be configured having a multi-bridge channel (MBC) structure and four sides thereof may be surrounded by the first gate line 170. Here, the four sides may include both (opposing) sides in the second horizontal direction Y and both (opposing) sides in the vertical direction Z.

The first gate line 170 may be arranged over the active area AP and the device isolation layer 102. The first gate line 170 may extend in the second horizontal direction Y and may cover the first channel CH1 arranged over the active area AP. The first gate line 170 may include a first sub-gate 170S covering the upper and lower portions of the first channel CH1 in the vertical direction Z and a first main gate 170M extending in the second horizontal direction Y over the device isolation layer 102. The thickness of the first sub-gate 170S in the vertical direction Z may be less than the thickness of the first main gate 170M in the vertical direction Z. The first gate line 170 may cover the upper and lower surfaces of the first channel CH1 in the vertical direction Z and opposing side surfaces of the first channel CH1 in the second horizontal direction Y. The first source/drain area 130 may be formed on opposing side surfaces of the first channel CH1 in the first horizontal direction X. Each of the first transistor TR1 and the fourth transistor TR4 may include the first gate line 170. The first gate line 170 of the first transistor TR1 and the first gate line 170 of the fourth transistor TR4 may be spaced apart from each other in the first horizontal direction X. The first gate line 170 of the first transistor TR1 may extend in the second horizontal direction Y while covering the first channel CH1 of the first transistor TR1, and the first gate line 170 of the fourth transistor TR4 may extend in the second horizontal direction Y while covering the first channel CH1 of the fourth transistor TR4. Each of the first gate lines 170 may include a metal, a metal nitride, a metal carbide, or any combination thereof. The metal may be selected from among Ti, W, ruthenium (Ru), niobium (Nb), molybdenum (Mo), hafnium (Hf), nickel (Ni), cobalt (Co), platinum (Pt), yttertrum (Yb), terbium (Tb), dysprosium (Dy), erbium (Er), and palladium (Pd). The metal nitride may be selected from among titanium nitride (TiN) and tantalum nitride (TaN). The metal carbide may be titanium aluminum carbide (TiAIC). However, the component materials of the first gate line 170 are not limited thereto.

A first gate dielectric layer 172 may be arranged between the first channel CH1 and the first gate line 170. The first gate dielectric layer 172 may include a stack structure of a dielectric layer and a high-k (high dielectric constant) dielectric layer. The dielectric layer may include a low dielectric constant (low-k) dielectric material layer with a dielectric constant of about 9 or less, for example, a silicon oxide layer, a silicon oxynitride layer, or a combination thereof. In embodiments, the dielectric layer may be omitted. The high-k dielectric layer may include a material having a higher dielectric constant than a silicon oxide layer. For example, the high dielectric layer may have a dielectric constant of about 10 to about 25. The high-k dielectric layer may include a hafnium oxide; however, the inventive concept is not limited thereto.

The first gate dielectric layer 172 may cover the active area AP and the upper surface of the device isolation layer 102 and may cover the first channel CH1. The first sub-gate 170S may be spaced apart from the first source/drain area 130 in the first horizontal direction X with the first gate dielectric layer 172 therebetween. The first sub-gate 170S may be spaced apart from the substrate 100 in the vertical direction Z with the first gate dielectric layer 172 therebetween. The first sub-gate 170S may be spaced apart from a first sub-gate insulating layer 150 in the vertical direction Z with the first gate dielectric layer 172 therebetween. The first gate dielectric layer 172 may cover the lower surface of the first main gate 170M and both side surfaces of the first main gate 170M in the first horizontal direction X.

The first source/drain area 130 may be formed on both sides of the first channel CH1 in the first horizontal direction X. The first source/drain area 130 may be formed on both sides of each of the first channel CH1 of the first transistor TR1 and the first channel CH1 of the fourth transistor TR4 in the first horizontal direction X. In some embodiments, the first source/drain area 130 formed between the first channel CH1 of the first transistor TR1 and the first channel CH1 of the fourth transistor TR4 may be shared by the first transistor TR1 and the fourth transistor TR4. In this case, three first source/drain areas 130 may be formed.

Each of the first source/drain areas 130 may include an epitaxially grown semiconductor layer. In embodiments, each of the first source/drain areas 130 may include an epitaxially grown Si layer, an epitaxially grown SiC layer, or a plurality of epitaxially grown SiGe layers. When the first source/drain area 130 constitutes an NMOS transistor, the first source/drain area 130 may include a Si layer doped with an n-type dopant or a SiC layer doped with an n-type dopant. The n-type dopant may be selected from among phosphorus (P), arsenic (As), and antimony (Sb). When the first source/drain area 130 constitutes a PMOS transistor, the first source/drain area 130 may include a SiGe layer doped with a p-type dopant. The p-type dopant may be selected from among boron (B) and gallium (Ga).

A first insulating layer 120 may be formed to cover each of the first source/drain area 130 and the second source/drain area 230. The first insulating layer 120 may cover the upper surface of the first source/drain area 130 and opposing side surfaces of the first source/drain area 130 in the second horizontal direction Y and may cover the upper and lower surfaces of the second source/drain area 230 and opposing side surfaces of the second source/drain area 230 in the second horizontal direction Y. The first insulating layer 120 may cover at least a portion of opposing side surfaces of each of the first source/drain area 130 and the second source/drain area 230 in the second horizontal direction Y. The first source/drain area 130 and the second source/drain area 230 overlapping each other in the vertical direction Z may be spaced apart from each other in the vertical direction Z by the first insulating layer 120. The second source/drain area 230 and the third source/drain area 330 overlapping each other in the vertical direction Z may be spaced apart in the vertical direction Z by the first insulating layer 120.

The first insulating layer 120 may cover opposing side surfaces of a portion of the first gate line 170 in the first horizontal direction X, which does not overlap the active area AP in the vertical direction Z. The first insulating layer 120 may cover opposing side surfaces of a portion of a second gate line 270 in the first horizontal direction X, which does not overlap the active area AP in the vertical direction Z. The portion of the first gate line 170 that does not overlap the active area AP in the vertical direction Z may be understood as the first main gate 170M. Also, the portion of the second gate line 270 that does not overlap the active area AP in the vertical direction Z may be understood as a second main gate 270M. The first main gate 170M may be spaced apart from the first insulating layer 120 in the first horizontal direction X with the first gate dielectric layer 172 therebetween, and the second main gate 270M may be spaced apart from the first insulating layer 120 in the first horizontal direction with a second gate dielectric layer 272 therebetween.

The first insulating layer 120 may include a silicon oxide, SiOC, SiOCN, SiCN, SiBN, SION, SiBCN, SiOF, SiOCH, or any combination thereof. The first insulating layer 120 may include a single layer including one material selected from among the materials listed above or may include multiple layers including a plurality of materials layers selected from among the materials listed above. The terms SiOC, SiOCN, SiCN, SiBN, SION, SiBCN, SiOF, and SiOCH used herein refer to materials including elements included in the respective terms but do not refer to chemical formulas representing stoichiometric relationships.

A second insulating layer 140 may be configured to cover the third source/drain area 330. The second insulating layer 140 may cover the upper surface of the third source/drain area 330 and opposing side surfaces of the third source/drain area 330 in the second horizontal direction Y. The second insulating layer 140 may cover at least a portion of opposing side surfaces of the third source/drain area 330 in the second horizontal direction Y. Because the second insulating layer 140 may include substantially the same material as the first insulating layer 120, redundant descriptions thereof will be omitted for conciseness.

The second insulating layer 140 may cover both side surfaces of a portion of the third gate line 370 in the first horizontal direction X, which does not overlap the active area AP in the vertical direction Z. The portion of the third gate line 370 that does not overlap the active area AP in the vertical direction Z may be understood as a third main gate 370M. The third main gate 370M may be spaced apart from the second insulating layer 140 in the first horizontal direction X with a third gate dielectric layer 372 therebetween.

A first main gate insulating layer 160 may be configured to cover the upper surface of the first main gate 170M of the first gate line 170. The first main gate insulating layer 160 may extend in the second horizontal direction Y. The first sub-gate insulating layer 150 may be configured to cover the upper surface of the first sub-gate 170S of the first gate line 170. The first main gate insulating layer 160 may cover each of the upper surface of the first main gate 170M of the first transistor TR1 and the upper surface of the first main gate 170M of the fourth transistor TR4. The first sub-gate insulating layer 150 may cover each of the upper surface of the first sub-gate 170S of the first transistor TR1 and the upper surface of the first sub-gate 170S of the fourth transistor TR4.

The first gate line 170 may be separated from the second gate line 270 by the first main gate insulating layer 160 and the first sub-gate insulating layer 150. More particularly, the first gate line 170 may be spaced apart from the second gate line 270 in the vertical direction Z with the first main gate insulating layer 160 and the first sub-gate insulating layer 150 therebetween.

The second transistor TR2 may be arranged over the first transistor TR1 in the vertical direction Z. The second transistor TR2 may include a second channel CH2, the second gate line 270, and a second source/drain area 230. The second channel CH2 may be arranged apart from the first channel CH1 in the vertical direction Z with the first sub-gate insulating layer 150 therebetween. Particularly, the second channel CH2 may be arranged apart from the first channel CH1 of the first transistor TR1 with the first sub-gate insulating layer 150 formed over the first transistor TR1 therebetween. In this case, a fourth insulating layer 410 and a fifth insulating layer 430 may be formed over the first sub-gate insulating layer 150 formed over the fourth transistor TR4. According to embodiments, the second channel CH2 may include a nanosheet; however, the inventive concept is not limited thereto. According to embodiments, the second transistor TR2 may include a plurality of second channels CH2. In this case, the plurality of second channels CH2 may be stacked and spaced apart from each other in the vertical direction Z. For example, the second transistor TR2 may include a plurality of second channels CH2 overlapping each other in the vertical direction Z. The number of second channels CH2 included in the second transistor TR2 is not particularly limited.

The second gate line 270 may be arranged over the first sub-gate insulating layer 150 and the first main gate insulating layer 160. Particularly, the second gate line 270 may be formed over the first sub-gate insulating layer 150 and the first main gate insulating layer 160 formed over the first transistor TR1. In this case, the fourth insulating layer 410 and the fifth insulating layer 430 may be sequentially formed over the first sub-gate insulating layer 150 and the first main gate insulating layer 160 formed over the fourth transistor TR4.

The second gate line 270 may extend in the second horizontal direction Y and may cover the second channel CH2 formed over the first sub-gate insulating layer 150. The second gate line 270 may include a second sub-gate 270S covering the upper and lower portions of the second channel CH2 in the vertical direction Z and a second main gate 270M extending in the second horizontal direction Y over the first main gate insulating layer 160. Because the second gate line 270 is substantially the same as or similar to the first gate line 170, redundant descriptions thereof will be omitted for conciseness.

The second gate dielectric layer 272 may be arranged between the second channel CH2 and the second gate line 270. The second gate dielectric layer 272 may cover the upper surface of each of the first sub-gate insulating layer 150 and the first main gate insulating layer 160, may cover the second channel CH2, and may cover the lower surface of the second sub-gate insulating layer 250. The second sub-gate 270S may be spaced apart from the first sub-gate insulating layer 150 in the vertical direction Z with the second gate dielectric layer 272 therebetween. The second gate dielectric layer 272 may cover the lower surface of the second main gate 270M and both side surfaces of the second main gate 270M in the first horizontal direction X.

The second source/drain area 230 may be formed on both sides of the second channel CH2 in the first horizontal direction X. The second source/drain area 230 may be spaced apart from the second sub-gate 270S in the first horizontal direction X with the second gate dielectric layer 272 therebetween.

A second main gate insulating layer 260 may be formed to cover the upper surface of the second main gate 270M of the second gate line 270. The second main gate insulating layer 260 may extend in the second horizontal direction Y. The second sub-gate insulating layer 250 may be formed to cover the upper surface of the second sub-gate 270S of the second gate line 270.

The third transistor TR3 may be arranged over the second transistor TR2 in the vertical direction Z. The third transistor TR3 may include a third channel CH3, a third gate line 370, and a third source/drain area 330. The third channel CH3 may be arranged apart from the second channel CH2 in the vertical direction Z with the second sub-gate insulating layer 250 therebetween. According to embodiments, the third transistor TR3 may include a plurality of third channels CH3. In this case, the plurality of third channels CH3 may be stacked and spaced apart from each other in the vertical direction Z. For example, the third transistor TR3 may include a plurality of third channels CH3 overlapping each other in the vertical direction Z. The number of third channels CH3 included in the third transistor TR3 is not particularly limited.

The third gate line 370 may be arranged over the second sub-gate insulating layer 250 and the second main gate insulating layer 260. The third gate line 370 may extend in the second horizontal direction Y and may cover the third channel CH3 formed over the second sub-gate insulating layer 250. The third gate line 370 may include a third sub-gate 370S covering the upper and lower portions of the third channel CH3 in the vertical direction Z and a third main gate 370M extending in the second horizontal direction Y over the second main gate insulating layer 260. Because the third gate line 370 is substantially the same as or similar to the first gate line 170 and the second gate line 270, redundant descriptions thereof will be omitted for conciseness.

The third gate dielectric layer 372 may be arranged between the third channel CH3 and the third gate line 370. The third gate dielectric layer 372 may cover the upper surface of each of the second sub-gate insulating layer 250 and the second main gate insulating layer 260, may cover the third channel CH3, and may cover the lower surface of a third insulating layer 360. The third sub-gate 370S may be spaced apart from the second sub-gate insulating layer 250 in the vertical direction Z with the third gate dielectric layer 372 therebetween. The third gate dielectric layer 372 may cover the lower surface of the third main gate 370M and opposing side surfaces of the third main gate 370M in the first horizontal direction X.

The third source/drain area 330 may be formed on opposing sides of the third channel CH3 in the first horizontal direction X. The third source/drain area 330 may be spaced apart from the third sub-gate 370S in the first horizontal direction X with the third gate dielectric layer 372 therebetween.

The third insulating layer 360 may be formed to cover the upper surface of the third gate line 370. The third insulating layer 360 may extend in the second horizontal direction Y. The second insulating layer 140 may be located on opposing side surfaces of the third insulating layer 360 in the first horizontal direction X.

The first upper source/drain contact 510 may be connected to the third source/drain area 330 by passing through (i.e., extending into) the second insulating layer 140 in the vertical direction Z. In this case, the third source/drain area 330 connected to the first upper source/drain contact 510 may overlap the first source/drain area 130 shared by the first transistor TR1 and the fourth transistor TR4 in the vertical direction Z. Likewise, the third source/drain area 330 connected to the first upper source/drain contact 510 may be located between the third channel CH3 and the fifth insulating layer 430.

According to embodiments, the first upper source/drain contact 510 may be connected to the second source/drain area 230 and the third source/drain area 330 by sequentially passing through the second insulating layer 140 and the first insulating layer 120. In this case, the second source/drain area 230 connected to the first upper source/drain contact 510 may overlap the first source/drain area 130 shared by the first transistor TR1 and the fourth transistor TR4 in the vertical direction Z. Likewise, the second source/drain area 230 connected to the first upper source/drain contact 510 may be located between the second channel CH2 and the fifth insulating layer 430. The third source/drain area 330 connected to the first upper source/drain contact 510 may overlap the first source/drain area 130 shared by the first transistor TR1 and the fourth transistor TR4 in the vertical direction Z. Likewise, the third source/drain area 330 connected to the first upper source/drain contact 510 may be located between the third channel CH3 and the fifth insulating layer 430.

The first upper source/drain contact 510 may be connected to each of the second source/drain area 230 and the third source/drain area 330. The first upper source/drain contact 510 may include molybdenum (Mo), tungsten (W), cobalt (Co), ruthenium (Ru), manganese (Mn), titanium (Ti), tantalum (Ta), aluminum (A1), copper (Cu), or any combination thereof or any alloy thereof; however, the inventive concept is not limited thereto. A barrier layer 512 may surround the first upper source/drain contact 510. The term “surround” (or “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The barrier layer 512 may include a metal or a conductive metal nitride. For example, the barrier layer 512 may include Ti, Ta, W, TiN, TaN, WN, WCN, TiSiN, TaSiN, WSIN, or any combination thereof; however, the inventive concept is not limited thereto. In some embodiments, the first upper source/drain contact 510 may include only a metal plug including a single metal.

The first upper gate contact 520 may be connected to the third gate line 370 by passing through the third insulating layer 360 in the vertical direction Z. According to embodiments, the first upper gate contact 520 may be connected to at least one of the third main gate 370M and the third sub-gate 370S. The first upper gate contact 520 may include a contact plug including molybdenum (Mo), copper (Cu), tungsten (W), cobalt (Co), ruthenium (Ru), manganese (Mn), titanium (Ti), tantalum (Ta), aluminum (A1), or any combination thereof or any alloy thereof; however, the component materials of the contact plug are not limited thereto.

A barrier layer 522 may surround the first upper gate contact 520. In some embodiments, the first upper gate contact 520 may include only a metal plug including a single metal.

The second upper gate contact 530 may be connected to the first gate line 170 of the fourth transistor TR4 by passing through the fourth insulating layer 410 and the fifth insulating layer 430 in the vertical direction Z. According to embodiments, the second upper gate contact 530 may be connected to the first gate line 170 of the fourth transistor TR4 by passing through any one of the first sub-gate insulating layer 150 and the first main gate insulating layer 160. A barrier layer 532 may surround the second upper gate contact 530. In some embodiments, the second upper gate contact 530 may include only a metal plug including a single metal.

The first lower source/drain contact 610 may be connected to the first source/drain area 130, the second source/drain area 230, and the third source/drain area 330 by passing through the device isolation layer 102, the first insulating layer 120, and the second insulating layer 140 in the vertical direction Z. In this case, the first source/drain area 130 connected to the first lower source/drain contact 610 may be the first source/drain area 130 formed on the side opposite to the fourth transistor TR4 among the first source/drain areas 130 of the first transistor TR1, the second source/drain area 230 connected to the first lower source/drain contact 610 may be the second source/drain area 230 overlapping the first source/drain area 130 in the vertical direction Z among the second source/drain areas 230, and the third source/drain area 330 connected to the first lower source/drain contact 610 may be the third source/drain area 330 overlapping the second source/drain area 230 in the vertical direction Z among the third source/drain areas 330.

According to one or more embodiments, the first lower source/drain contact 610 may be connected to the first source/drain area 130 by passing through the substrate 100 in the vertical direction Z. The first lower source/drain contact 610 may contact the lower surface of the first source/drain area 130 and the side surface of the first source/drain area 130 in the second horizontal direction Y.

A first barrier layer 612 may surround the first lower source/drain contact 610. In some embodiments, the first lower source/drain contact 610 may include only a metal plug including a single metal.

The second lower source/drain contact 630 may be connected to the first source/drain arca 130 of the fourth transistor TR4 by passing through the active area AP in the vertical direction Z. In this case, the first source/drain area 130 may be the first source/drain area 130 that is not shared with the first transistor TR1 among the first source/drain areas 130 formed on both sides of the fourth transistor TR4 in the first horizontal direction X.

A second barrier layer 632 may surround the second lower source/drain contact 630. In some embodiments, the second lower source/drain contact 630 may include only a metal plug including a single metal.

The first lower gate contact 640 may be connected to the first gate line 170 and the second gate line 270 by passing through the substrate 100, the device isolation layer 102, the first gate line 170, and the second main gate insulating layer 260 in the vertical direction Z. In this case, the first lower gate contact 640 may be connected to the first main gate 170M and the second main gate 270M. The first lower gate contact 640 may not overlap the first channel CH1 in the vertical direction Z.

A third barrier layer 642 may surround the first lower gate contact 640. In some embodiments, the first lower gate contact 640 may include only a metal plug including a single metal.

In the multi-stack semiconductor device 10 according to the inventive concept, the first to third transistors TR1, TR2, and TR3 may be stacked in the vertical direction Z, and the fourth transistor TR4 may be arranged laterally separated from the first transistor TR1 in the first horizontal direction X while having the same vertical level (i.e., in a same plane) as the first transistor TR1 with respect to an upper surface of the substrate 100. Also, the first lower source/drain contact 610 may be simultaneously connected to the first to third source/drain areas 130, 230, and 330 of the first to third transistors TR1, TR2, and TR3. Accordingly, when the third signal C is output from the first to third source/drain areas 130, 230, and 330, because the third signal C may be output only through the first lower source/drain contact 610, the number of signal lines receiving the third signal C may be reduced. Also, as the number of signal lines decreases, the size of the multi-stack semiconductor device 10 may be reduced to improve the integration degree and the required aspect ratio may be reduced to increase the process convenience.

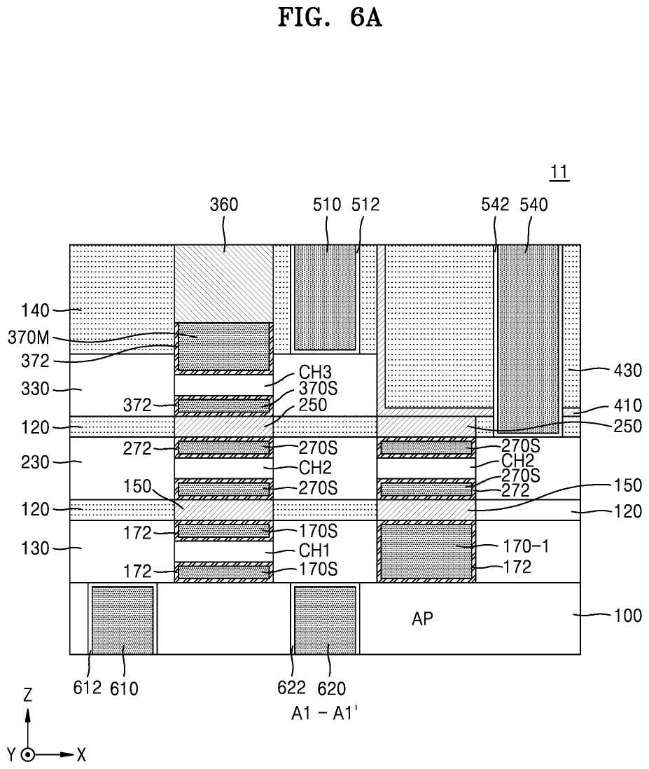

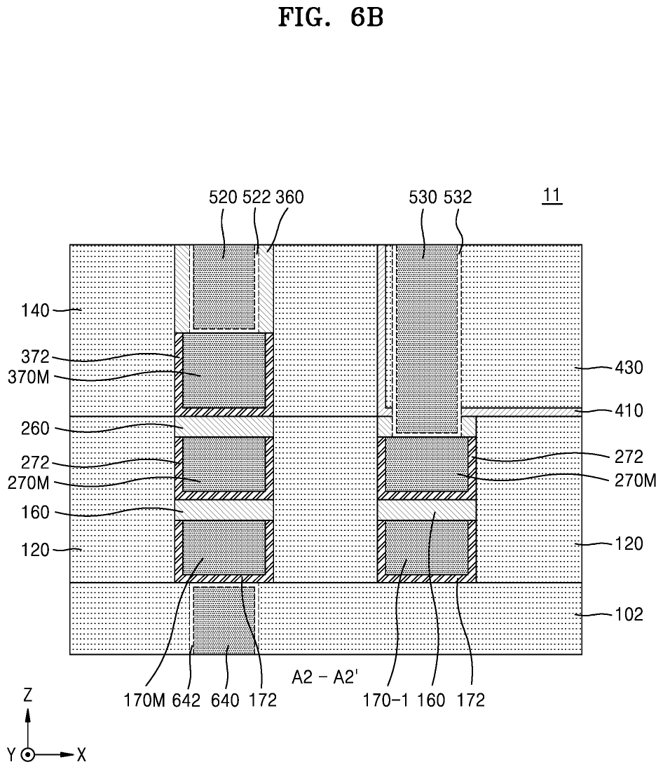

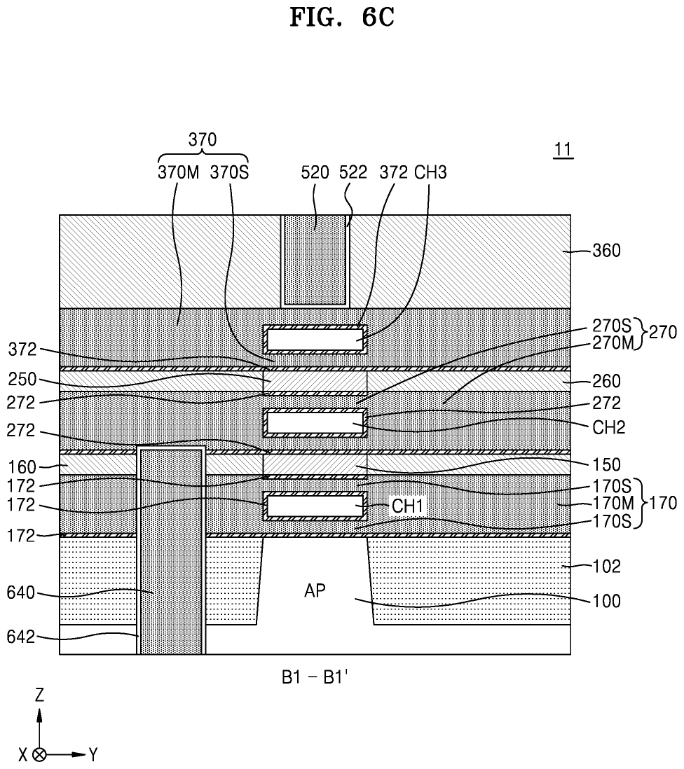

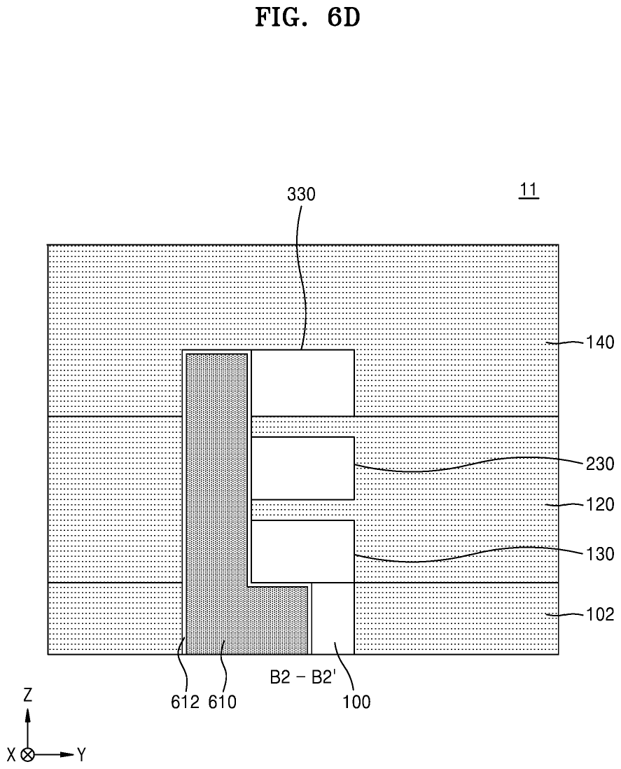

FIGS. 5A and 5B are plan views depicting example layout diagrams for describing the multi-stack semiconductor device 11 of FIG. 2B. FIGS. 6A to 6D are cross-sectional views taken along lines A1-A1′, A2-A2′, B1-B1′, and B2-B2′ of FIGS. 5A and 5B, respectively. Hereinafter, redundant descriptions between the multi-stack semiconductor device 11 of FIGS. 5A, 5B, and 6A to 6D and the multi-stack semiconductor device 10 described above with reference to FIGS. 2A, 3A, 3B, and 4A to 4D will be omitted and differences therebetween will be mainly described. Also, redundant descriptions with those of the multi-stack semiconductor device 11 given above with reference to FIG. 2B will be omitted for conciseness.

Referring to FIGS. 5A, 5B, and 6A to 6D, the multi-stack semiconductor device 11 may further include a first upper signal line 710, a second upper signal line 720, a third upper signal line 740, a first lower signal line 810, a second lower signal line 820, and a third lower signal line 840. Each of the first upper signal line 710, the second upper signal line 720, and the third upper signal line 740 may extend in the first horizontal direction X and may be located in the fourth layer LY4.

The first upper signal line 710 may be configured to provide the second power VSS to the second transistor TR2. According to embodiments, the first upper signal line 710 may be configured to provide the second power VSS to the third transistor TR3 through the first upper source/drain via 515 and the first upper source/drain contact 511. However, the inventive concept is not limited thereto, and the first upper signal line 710 may be configured to provide the second power VSS to the third transistor TR3 through the first upper source/drain contact 511 without using the first upper source/drain via 515.

The second upper signal line 720 may be configured to provide the first signal A to each of the third transistor TR3 and the fourth transistor TR4. Particularly, the second upper signal line 720 may be configured to provide the first signal A to each of the third gate line 370 of the third transistor TR3 and the second gate line 270 of the fourth transistor TR4. The second upper signal line 720 may be configured to provide the first signal A to the third transistor TR3 through the first upper gate via 525 and the first upper gate contact 520. Also, the second upper signal line 720 may be configured to provide the first signal A to the fourth transistor TR4 through the second upper gate via 535 and the second upper gate contact 531. However, the inventive concept is not limited thereto, and the second upper signal line 720 may be configured to provide the first signal A to the third transistor TR3 through the first upper gate contact 520 and to the fourth transistor TR4 through the second upper gate contact 531 without using the first upper gate via 525 and the second upper gate via 535.

The third upper signal line 740 may be configured to provide the first power VDD to the fourth transistor TR4. Particularly, the third upper signal line 740 may be configured to provide the first power VDD to the second source/drain area 230 not shared with the second transistor TR2 among the second source/drain areas 230 of the fourth transistor TR4. The third upper signal line 740 may be configured to provide the first power VDD to the fourth transistor TR4 through the second upper source/drain via 545 and the second upper source/drain contact 540. However, the inventive concept is not limited thereto, and the third upper signal line 740 may be configured to provide the first power VDD to the fourth transistor TR4 through the second upper source/drain contact 540 without using the second upper source/drain via 545.

Each of the first lower signal line 810, the second lower signal line 820, and the third lower signal line 840 may extend in the first horizontal direction X and may be located in the 0th layer LY0. The first lower signal line 810 may provide the third signal C from the first transistor TR1, the second transistor TR2, and the third transistor TR3 as an output of the semiconductor device 11.

The second lower signal line 820 may be configured to provide the second power VSS to the first transistor TR1. The second lower signal line 820 may be configured to provide the second power VSS to the first transistor TR1 through the third lower source/drain via 625 and the third lower source/drain contact 620. However, the inventive concept is not limited thereto, and the second lower signal line 820 may be configured to provide the second power VSS to the first transistor TR1 through the third lower source/drain contact 620 without using the third lower source/drain via 625.

The third lower signal line 840 may be configured to provide the second signal B to the first transistor TR1 and the second transistor TR2. The third lower signal line 840 may be configured to provide the second signal B to the first transistor TR1 and the second transistor TR2 through the first lower gate via 645 and the first lower gate contact 640. However, the inventive concept is not limited thereto, and the third lower signal line 840 may be configured to provide the second signal B to the first transistor TR1 and the second transistor TR2 through the first lower gate contact 640 without using the first lower gate via 645.

The first transistor TR1 may be provided over the active area AP of the substrate 100. The first transistor TR1 may include a first channel CH1, a first gate line 170, and a first source/drain area 130. The first channel CH1 may be stacked over the active area AP while being spaced apart therefrom in the vertical direction Z. In this case, the first channel CH1 may be formed only in an area overlapping the second transistor TR2 in the vertical direction Z and may not be formed in an area overlapping the fourth transistor TR4 in the vertical direction Z.

According to embodiments, the first transistor TR1 may include a plurality of first channels CH1. In this case, the plurality of first channels CH1 may be stacked and spaced apart from each other in the vertical direction Z.

The first gate line 170 may be arranged over the active area AP and the device isolation layer 102. A fourth gate line 170-1 may be arranged over the active area AP and the device isolation layer 102. The first gate line 170 and the fourth gate line 170-1 may be arranged apart from each other in the first horizontal direction X and may each extend in the second horizontal direction Y. In this case, the first gate line 170 may cover the first channel CH1, and the fourth gate line 170-1 may not cover the first channel CH1. The first gate line 170 may include a first sub-gate 170S covering the upper and lower portions of the first channel CH1 in the vertical direction Z and a first main gate 170M extending in the second horizontal direction Y over the device isolation layer 102. Because the fourth gate line 170-1 does not cover the first channel CH1, it may not be divided into a sub-gate and a main gate.

A first gate dielectric layer 172 may be arranged between the first channel CH1 and the first gate line 170. The first gate dielectric layer 172 may be arranged between the fourth gate line 170-1 and the first source/drain area 130. Both sides of the fourth gate line 170-1 in the vertical direction Z and both sides of the fourth gate line 170-1 in the first horizontal direction X may be surrounded by the first gate dielectric layer 172.

The first source/drain area 130 may be formed on opposing sides of the first channel CH1 in the first horizontal direction X and may also be formed on one side of the fourth gate line 170-1 in the first horizontal direction X. Accordingly, three first source/drain areas 130 may be formed.

A first insulating layer 120 may be formed on each of the first source/drain area 130 and the second source/drain area 230. The first insulating layer 120 may cover the upper surface of the first source/drain area 130 and both side surfaces of the first source/drain area 130 in the second horizontal direction Y and may cover the upper and lower surfaces of the second source/drain area 230 and both side surfaces of the second source/drain area 230 in the second horizontal direction Y. The first insulating layer 120 may be on at least a portion of both side surfaces of each of the first source/drain area 130 and the second source/drain area 230 in the second horizontal direction Y. A second insulating layer 140 may be formed on the third source/drain area 330.

A first main gate insulating layer 160 may be formed on the upper surface of the first main gate 170M of the first gate line 170. The first main gate insulating layer 160 may extend in the second horizontal direction Y. The first sub-gate insulating layer 150 may be formed on the upper surface of the first sub-gate 170S of the first gate line 170.

The first sub-gate insulating layer 150 formed over the fourth gate line 170-1 may separate the fourth gate line 170-1 from the second channel CH2 of the fourth transistor TR4 in the vertical direction Z. The first main gate insulating layer 160 formed over the fourth gate line 170-1 may separate the fourth gate line 170-1 from the second gate line 270 of the fourth transistor TR4 in the vertical direction Z.

The second transistor TR2 may be arranged over the first transistor TR1 in the vertical direction Z. The second transistor TR2 may include a second channel CH2, a second gate line 270, and a second source/drain area 230.

The fourth transistor TR4 may be arranged over the fourth gate line 170-1 in the vertical direction Z. The fourth transistor TR4 may include a second channel CH2, a second gate line 270, and a second source/drain area 230.

The second source/drain area 230 located between the second transistor TR2 and the fourth transistor TR4 may be shared by the second transistor TR2 and the fourth transistor TR4. The first sub-gate insulating layer 150 may be located between the fourth transistor TR4 and the fourth gate line 170-1. The fourth transistor TR4 may include a plurality of second channels CH2, and the number of second channels CH2 included in the fourth transistor TR4 is not particularly limited. The second gate line 270 may be arranged over the first sub-gate insulating layer 150 and the first main gate insulating layer 160. The second gate line 270 may extend in the second horizontal direction Y. The second gate line 270 may include a second sub-gate 270S and a second main gate 270M. The second source/drain area 230 may be formed on opposing sides of the second channel CH2 in the first horizontal direction X.

The third transistor TR3 may be arranged over the second transistor TR2 in the vertical direction Z. The third transistor TR3 may include a third channel CH3, a third gate line 370, and a third source/drain area 330. The third gate line 370 may be arranged over the second sub-gate insulating layer 250 and the second main gate insulating layer 260. The third gate line 370 may extend in the second horizontal direction Y and may cover the third channel CH3 formed over the second sub-gate insulating layer 250. The third gate line 370 may include a third sub-gate 370S covering the upper and lower portions of the third channel CH3 in the vertical direction Z and a third main gate 370M extending in the second horizontal direction Y over the second main gate insulating layer 260.

The fourth insulating layer 410 and the fifth insulating layer 430 may be formed over the fourth transistor TR4. The fourth insulating layer 410 and the fifth insulating layer 430 may be arranged apart from the fourth transistor TR4 in the vertical direction Z with the second sub-gate insulating layer 250 and the second main gate insulating layer 260 therebetween. The fourth insulating layer 410 and the fifth insulating layer 430 may overlap the third source/drain area 330 in the first horizontal direction X and may not overlap the second source/drain area 230 in the first horizontal direction X.

According to one or more embodiments, the first upper source/drain contact 511, extending through the second insulating layer 140 in the vertical direction Z, may be connected to the third source/drain area 330. The second upper source/drain contact 540 may be connected to the second source/drain area 230 of the fourth transistor TR4 by sequentially passing through the fourth insulating layer 410, the fifth insulating layer 430, and the first insulating layer 120. A barrier layer 542 may be configured to surround (i.e., extend around) the second upper source/drain contact 540. In some embodiments, the second upper source/drain contact 540 may include only a metal plug including a single metal.

The first upper gate contact 520 may be connected to the third gate line 370 by passing through the third insulating layer 360 in the vertical direction Z. According to embodiments, the first upper gate contact 520 may be connected to any one of the third main gate 370M and the third sub-gate 370S.

The second upper gate contact 531 may be connected to the second gate line 270 of the fourth transistor TR4 by passing through the fourth insulating layer 410 and the fifth insulating layer 430 in the vertical direction Z. According to embodiments, the second upper gate contact 531 may be connected to the second gate line 270 of the fourth transistor TR4 by passing through any one of the second sub-gate insulating layer 250 and the second main gate insulating layer 260.

The first lower source/drain contact 610 may be connected to the first source/drain area 130, the second source/drain area 230, and the third source/drain area 330 by passing through the device isolation layer 102, the first insulating layer 120, and the second insulating layer 140 in the vertical direction Z.

The third lower source/drain contact 620 may be connected to the first source/drain area 130 of the first transistor TR1 by passing through the active area AP in the vertical direction Z. In this case, the first source/drain area 130 connected to the third lower source/drain contact 620 may be the first source/drain area 130 located between the first transistor TR1 and the fourth gate line 170-1. A barrier layer 622 may be formed to surround the third lower source/drain contact 620. In some embodiments, the third lower source/drain contact 620 may include only a metal plug including a single metal.

The first lower gate contact 640 may be connected to the first gate line 170 and the second gate line 270 by passing through the substrate 100, the device isolation layer 102, the first gate line 170, and the second main gate insulating layer 260 in the vertical direction Z.

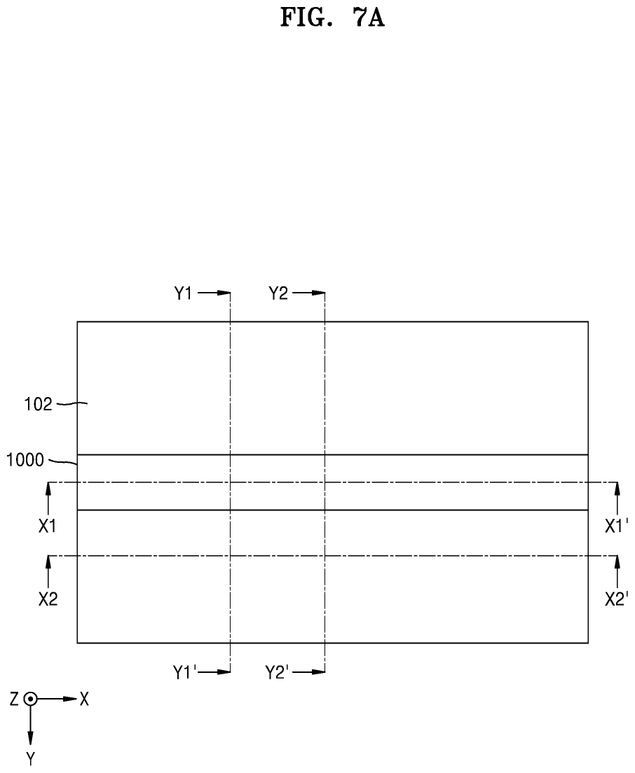

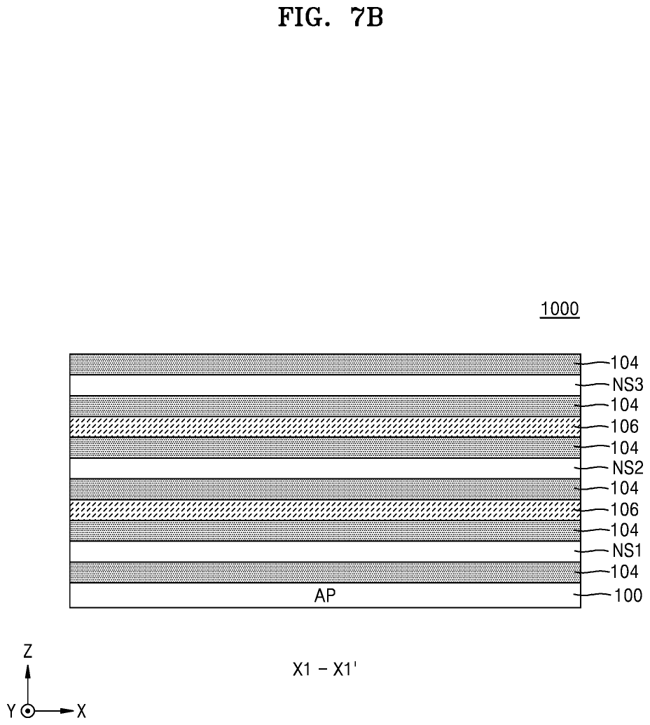

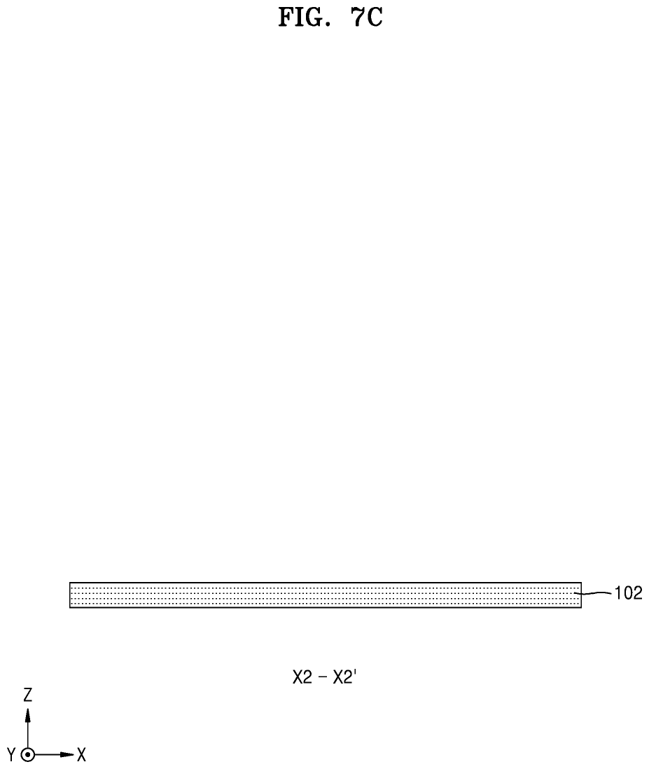

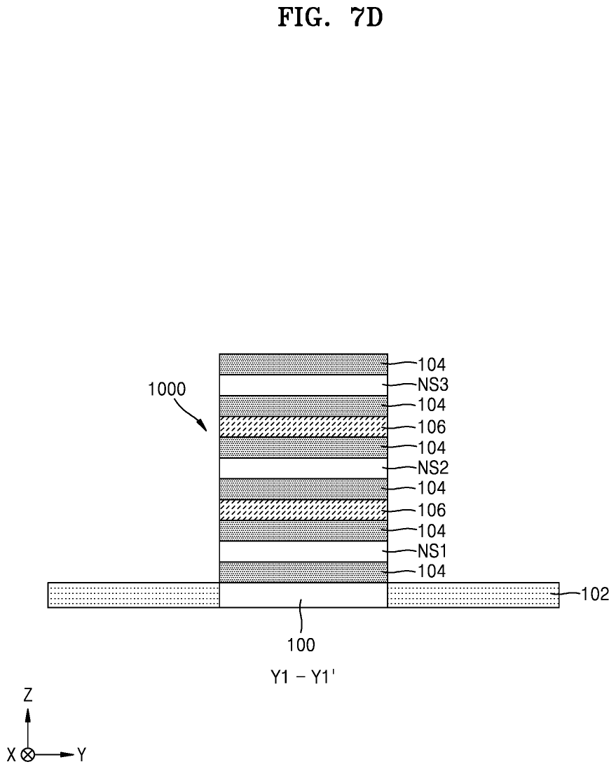

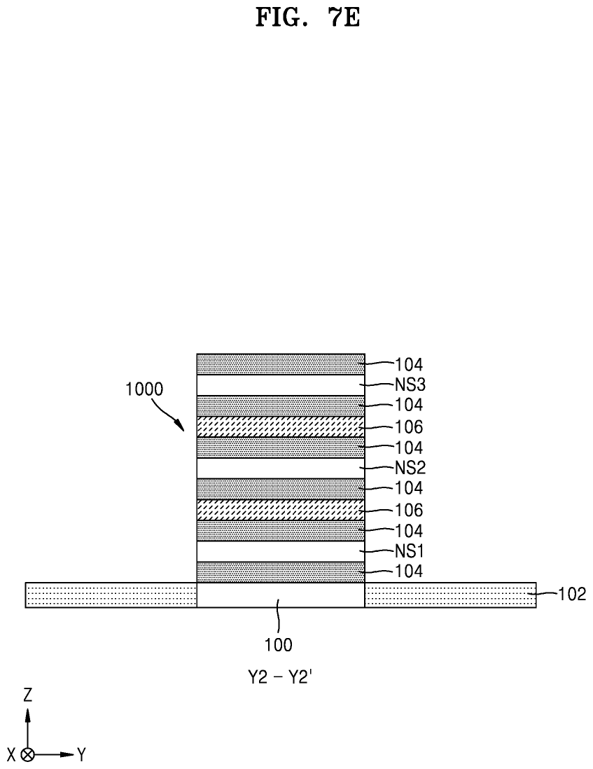

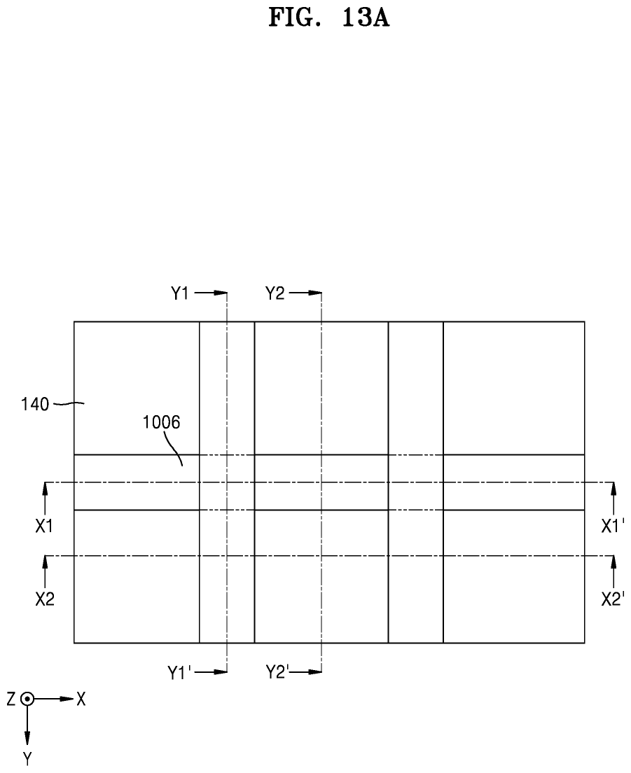

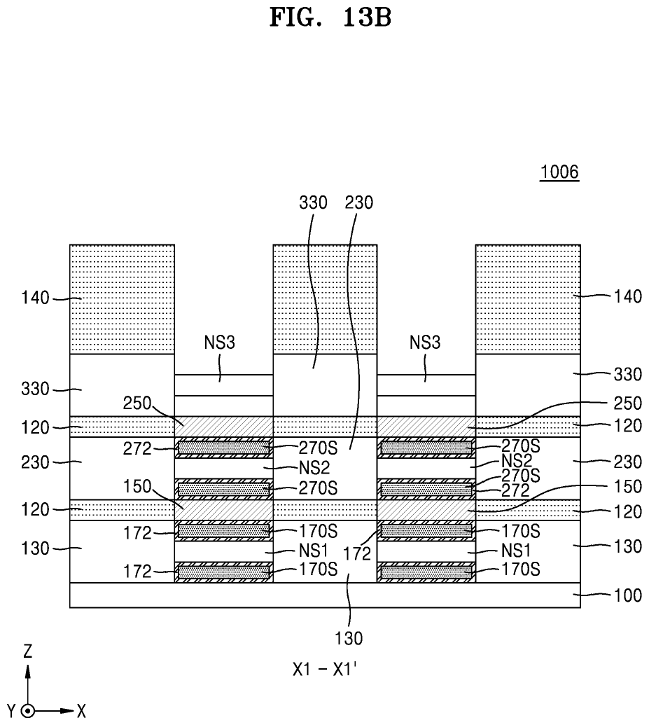

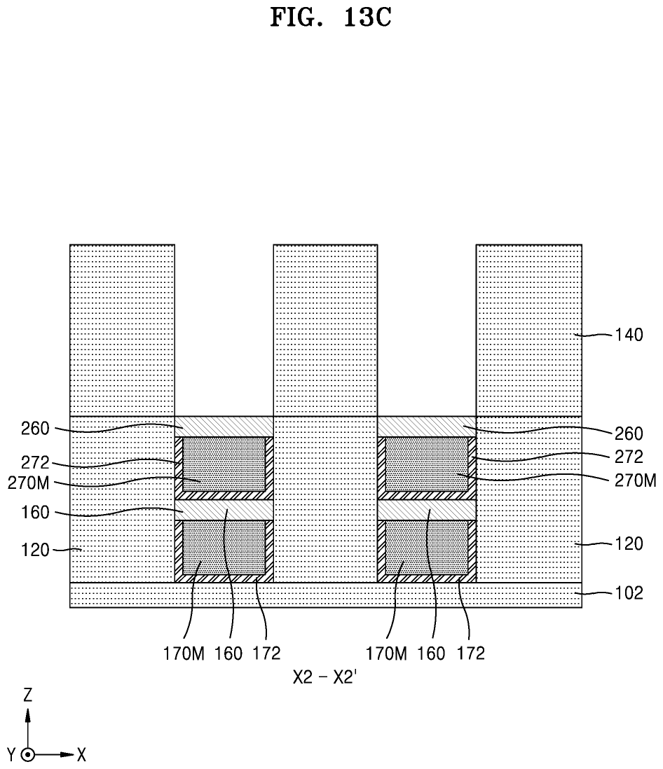

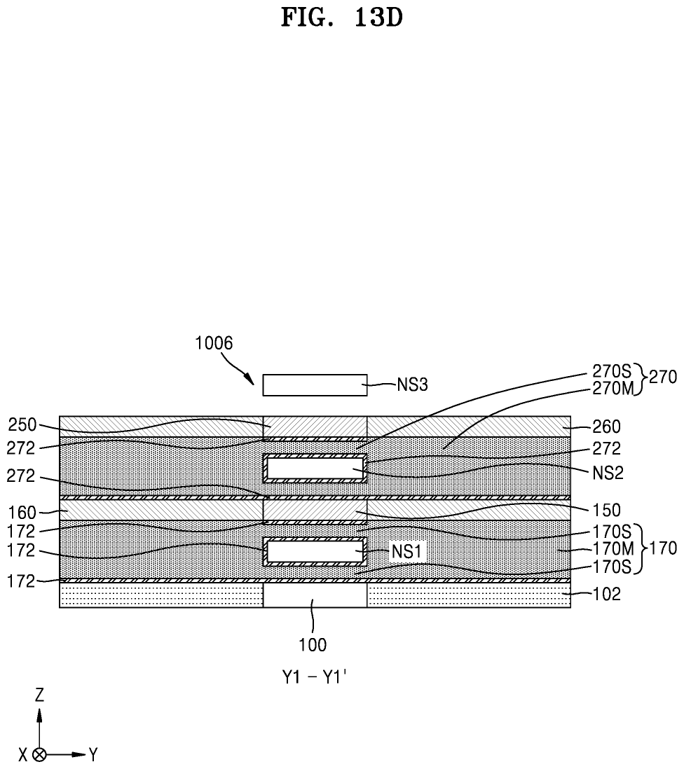

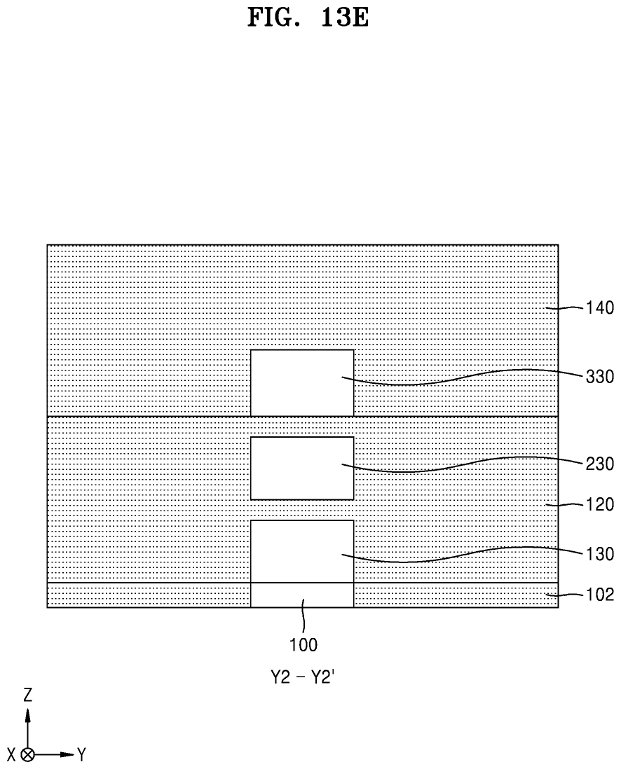

FIGS. 7A to 18E are plan views and cross-sectional views for describing intermediate processes in an example method of manufacturing the multi-stack semiconductor device 10 of FIG. 2A, according to one or more embodiments. Hereinafter, a method of manufacturing the multi-stack semiconductor device 10 will be described with reference to FIGS. 7A to 18E. Also, redundant descriptions with those given above with reference to FIGS. 1 to 6D will be omitted for conciseness.

First, referring to FIGS. 7A to 7E, a stack structure 1000 formed over the active area AP of the substrate 100 may be provided. The stack structure 1000 may extend in the first horizontal direction X. The stack structure 1000 may include a structure in which a first sacrificial semiconductor layer 104, a first nanosheet semiconductor layer NS1, a first sacrificial semiconductor layer 104, a second sacrificial semiconductor layer 106, a first sacrificial semiconductor layer 104, a second nanosheet semiconductor layer NS2, a first sacrificial semiconductor layer 104, a second sacrificial semiconductor layer 106, a first sacrificial semiconductor layer 104, a third nanosheet semiconductor layer NS3, and a first sacrificial semiconductor layer 104 are sequentially stacked over the active area AP in the vertical direction Z. However, the inventive concept is not limited thereto, and a plurality of first to third nanosheet semiconductor layers NS1, NS2, and NS3 may be provided, and the first sacrificial semiconductor layer 104 may be provided over and under each of the first to third nanosheet semiconductor layers NS1, NS2, and NS3.

According to embodiments, the first nanosheet semiconductor layer NS1, the second nanosheet semiconductor layer NS2, and the third nanosheet semiconductor layer NS3 may include a material the same as or similar to the component material of the substrate 100. According to one or more embodiments, the first to third nanosheet semiconductor layers NS1, NS2, and NS3 may include silicon. The first sacrificial semiconductor layer 104 may include a material having an etch selectivity with the first to third nanosheet semiconductor layers NS1, NS2, and NS3. According to embodiments, the first sacrificial semiconductor layer 104 may include silicon germanium (SiGe). The second sacrificial semiconductor layer 106 may include a material having an etch selectivity with the first to third nanosheet semiconductor layers NS1, NS2, and NS3 and the second sacrificial semiconductor layer 106. According to embodiments, the second sacrificial semiconductor layer 106 may include silicon germanium, and in this case, the concentration of germanium included in the second sacrificial semiconductor layer 106 may be higher than the concentration of germanium included in the first sacrificial semiconductor layer 104.

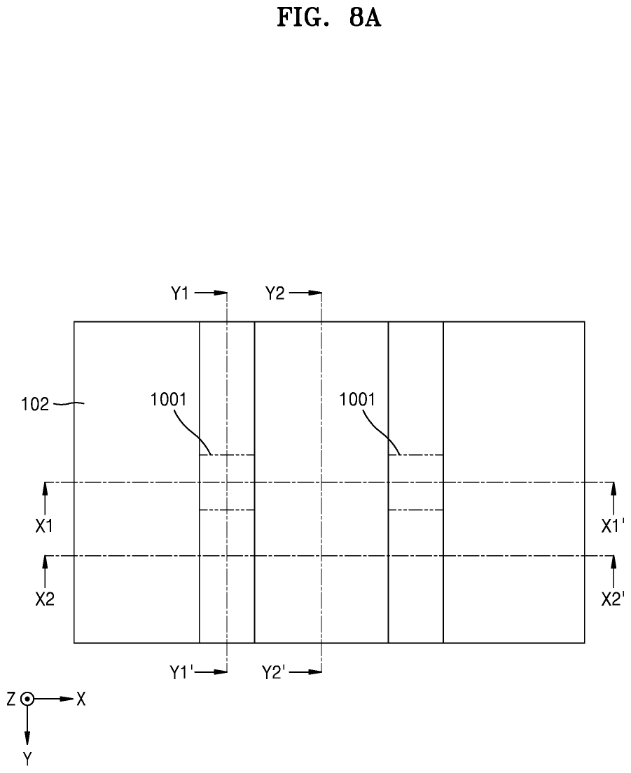

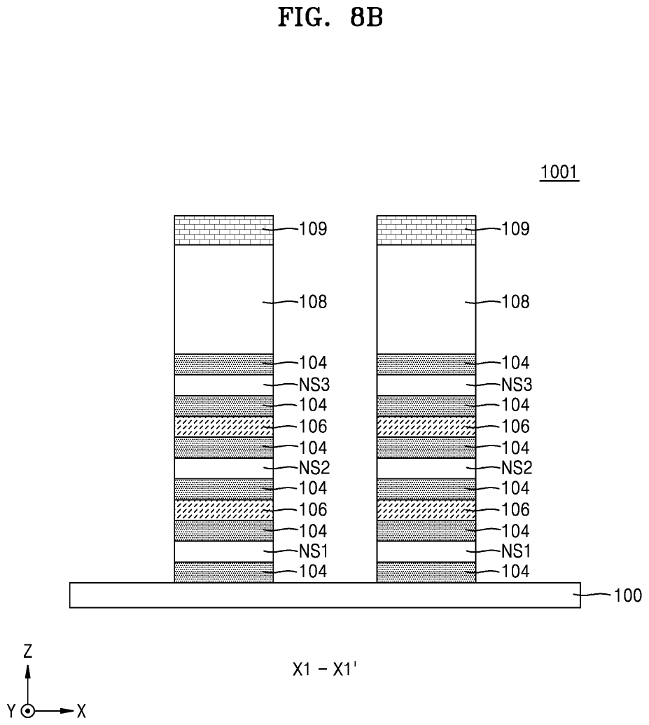

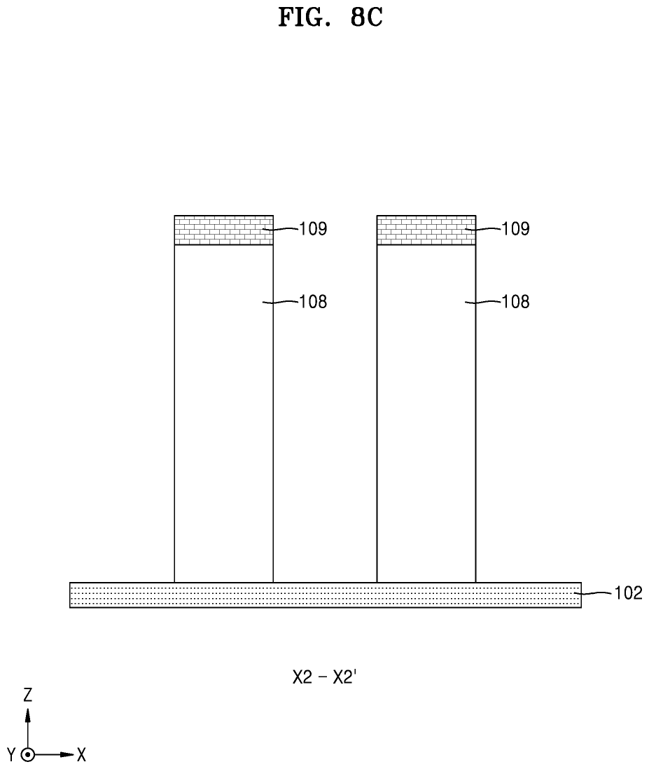

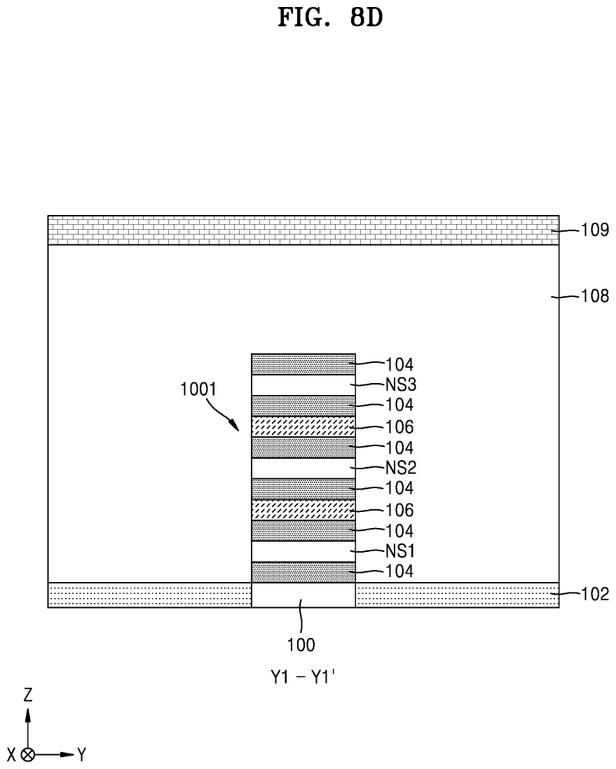

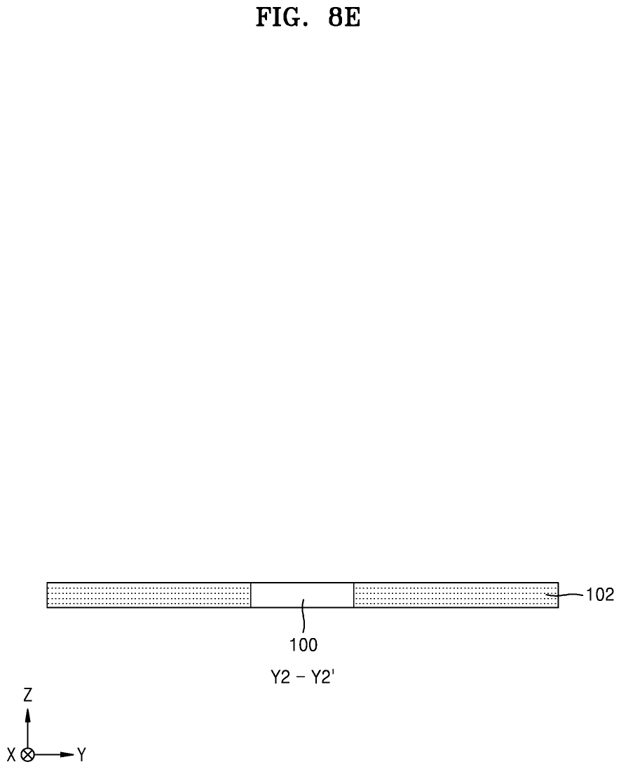

Referring to FIGS. 8A to 8E, a dummy gate 108 and a hard mask 109 extending in the second horizontal direction Y may be formed over the stack structure 1000, and a portion exposed from the hard mask 109 in the vertical direction Z may be etched to the upper surface of the substrate 100 and the device isolation layer 102 to provide a stack structure 1001. Accordingly, the stack structure 1001 may have a shape in which the first to third nanosheet semiconductor layers NS1, NS2, and NS3, the first sacrificial semiconductor layer 104, and the second sacrificial semiconductor layer 106 are separated in the first horizontal direction X. The dummy gate 108 may cover the upper surface of the stack structure 1001 and both side surfaces of the stack structure 1001 in the second horizontal direction Y.

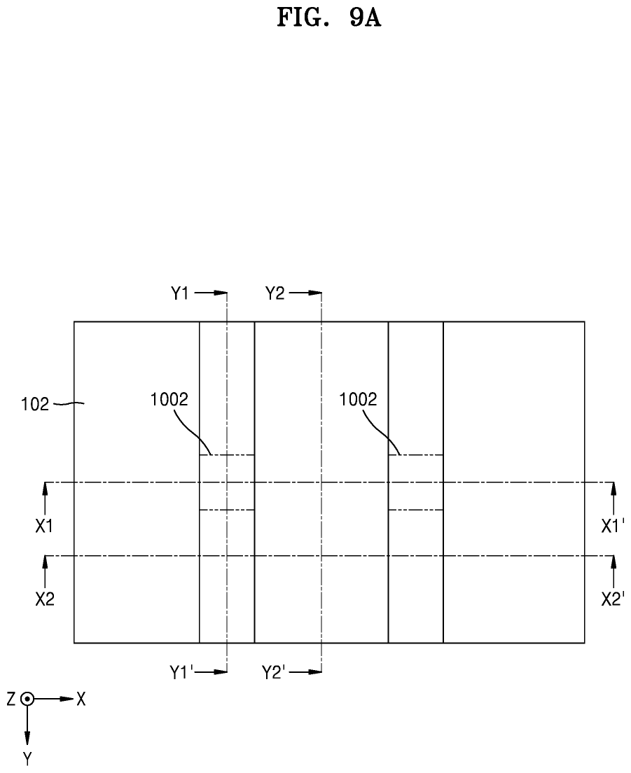

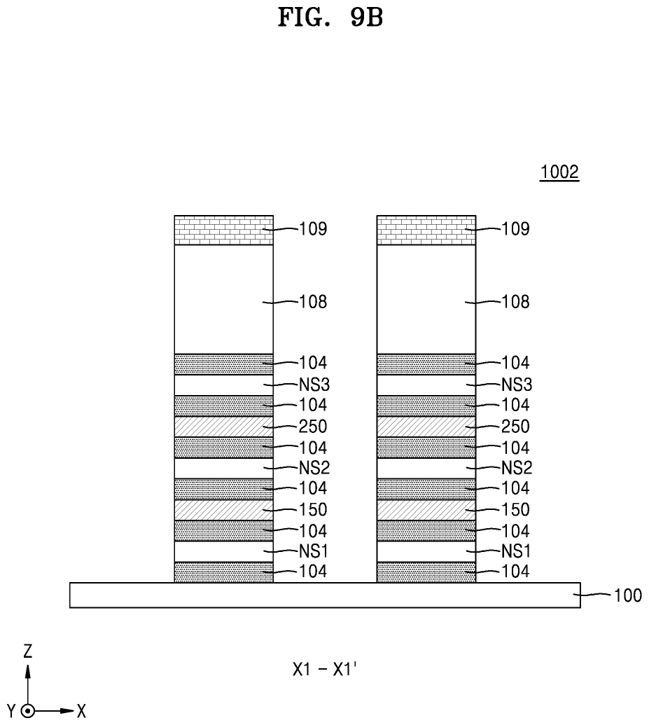

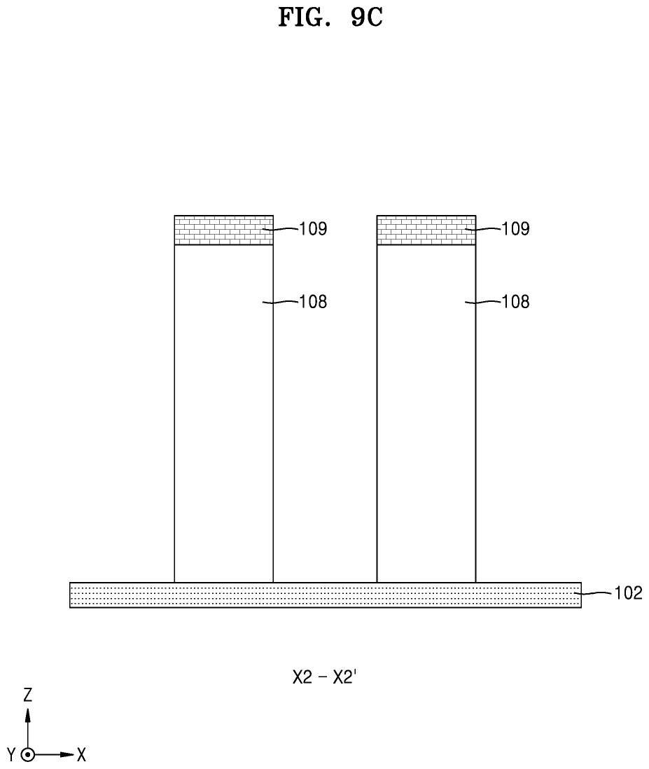

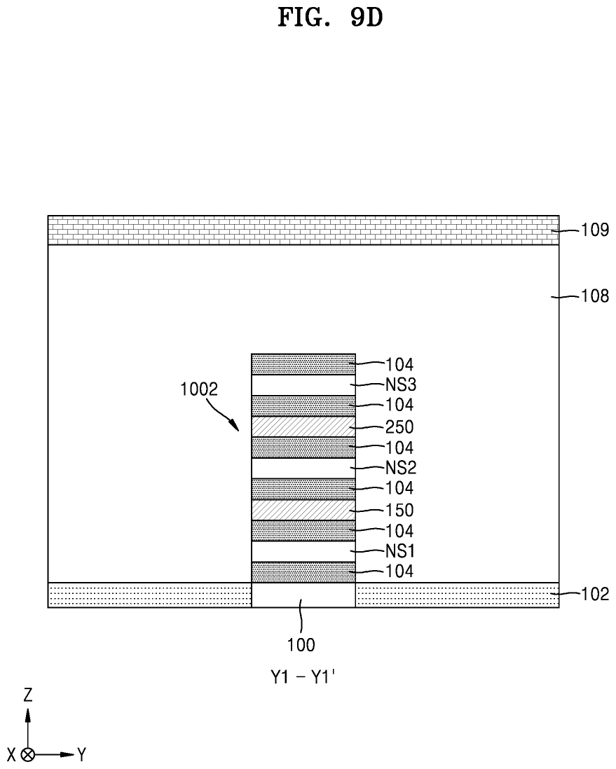

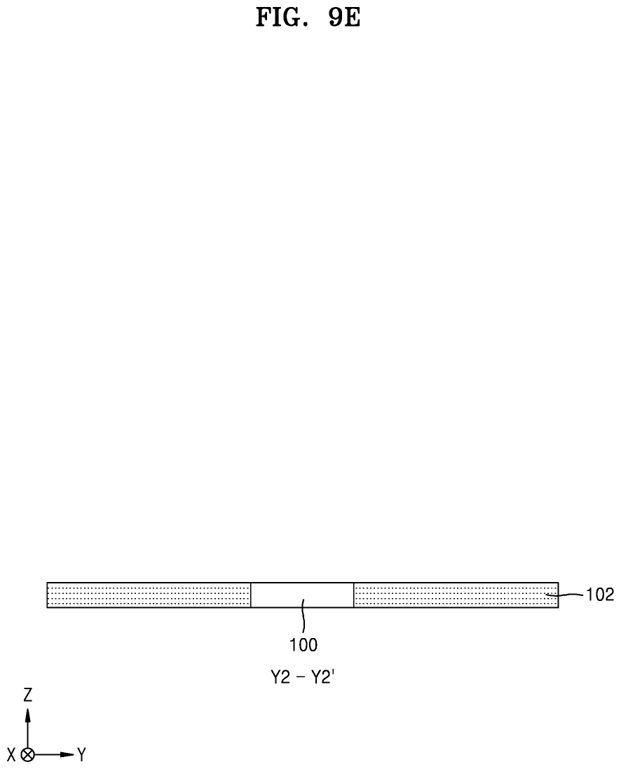

Referring to FIGS. 9A to 9E, the second sacrificial semiconductor layer 106 may be removed from the stack structure 1001 and replaced with the first sub-gate insulating layer 150 and the second sub-gate insulating layer 250 to form a stack structure 1002. The first sub-gate insulating layer 150 and the second sub-gate insulating layer 250 may be formed at the respective positions where the second sacrificial semiconductor layer 106 has been removed. The first sacrificial semiconductor layer 104 and the first to third nanosheet semiconductor layers NS1, NS2, and NS3 may not be removed due to the etch selectivity of the second sacrificial semiconductor layer 106.

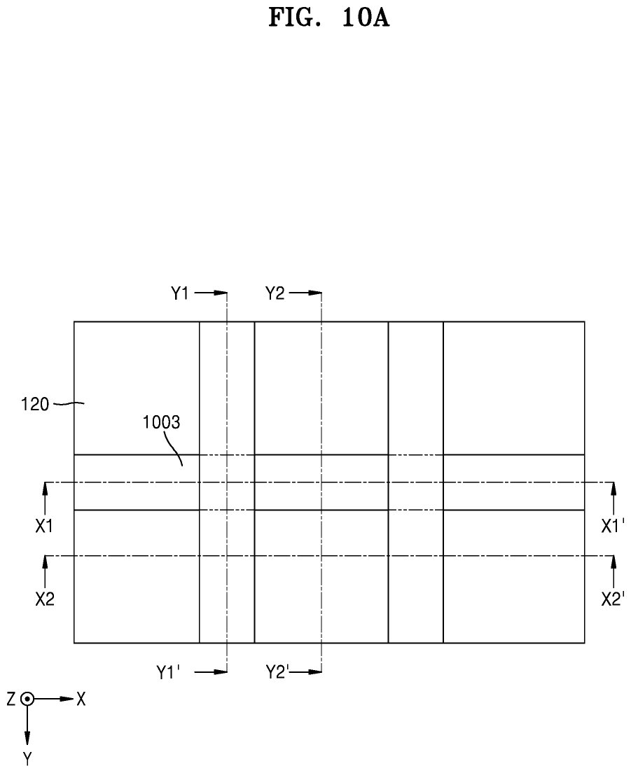

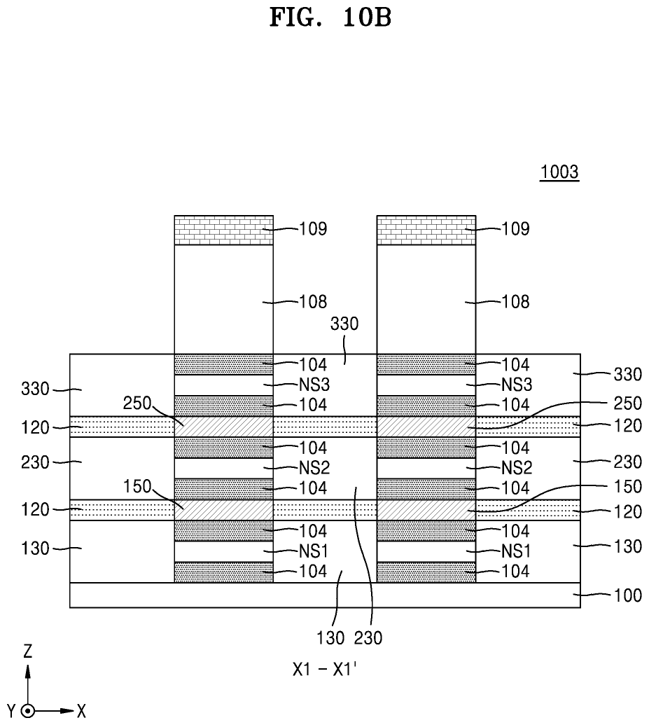

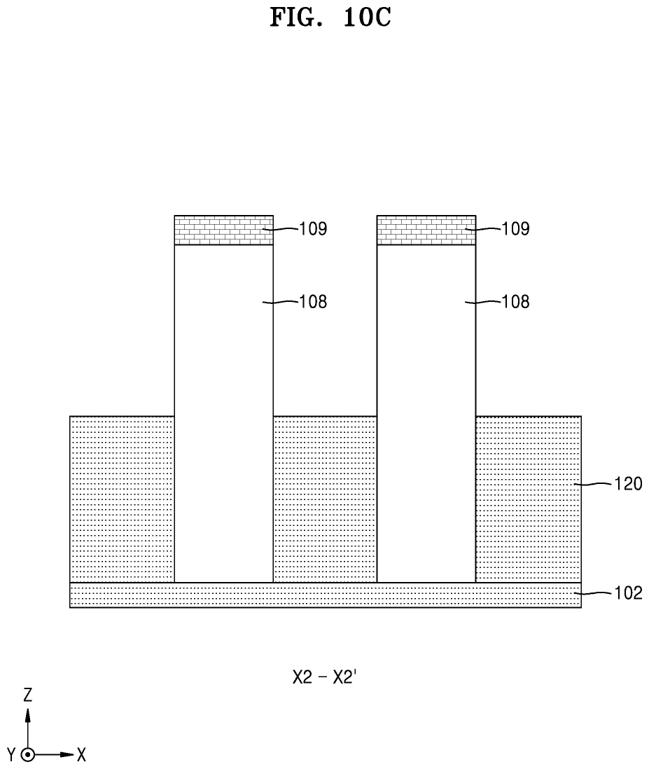

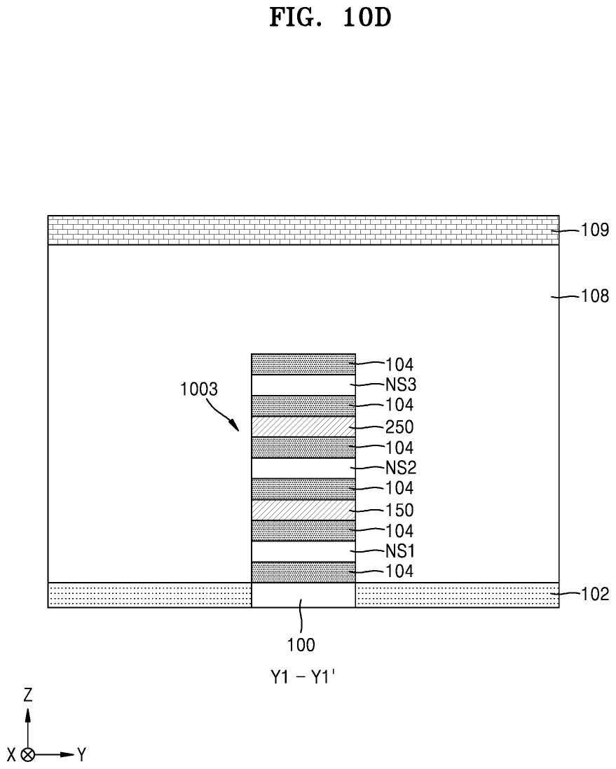

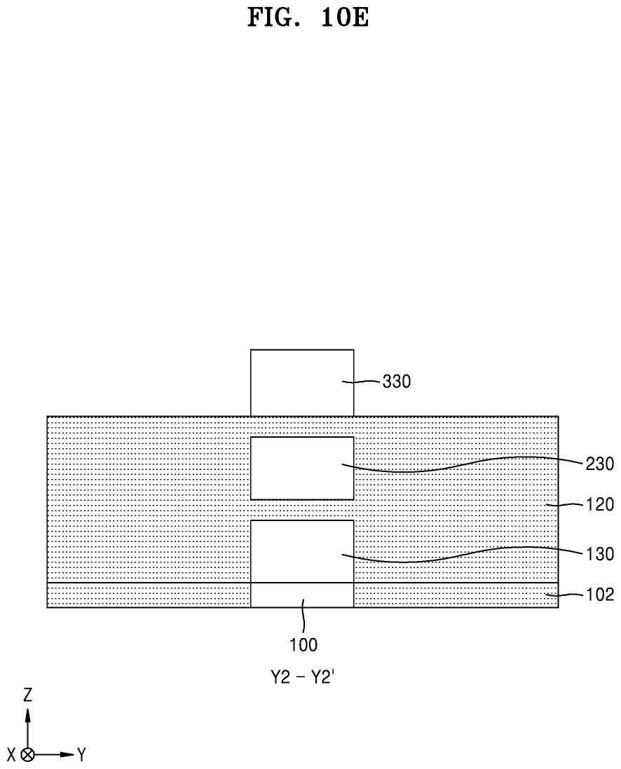

Referring to FIGS. 10A to 10E, epitaxial growth may be performed from the substrate 100 and the first to third nanosheet semiconductor layers NS1, NS2, and NS3 to form a first source/drain area 130, a second source/drain area 230, and a third source/drain area 330. According to embodiments, after the first source/drain area 130 is formed and a first insulating layer 120 covering the first source/drain area 130 is formed, the second source/drain area 230 may be formed and a first insulating layer 120 covering the second source/drain area 230 may be formed. The first insulating layer 120 may cover the upper surface of each of the first source/drain area 130 and the second source/drain area 230 and opposing side surfaces thereof in the second horizontal direction Y. Thereafter, the third source/drain area 330 may be formed over the upper surface of the first insulating layer 120 covering the upper surface of the second source/drain area 230 to provide a stack structure 1003.

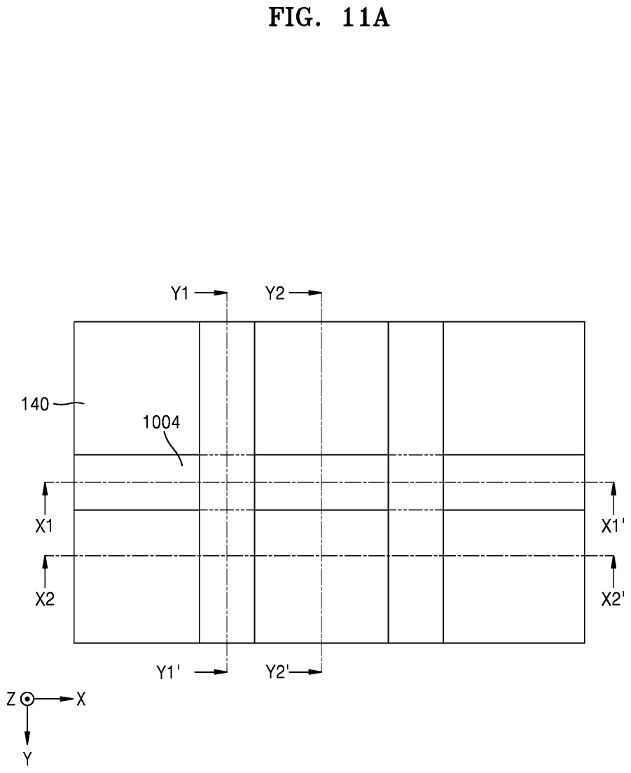

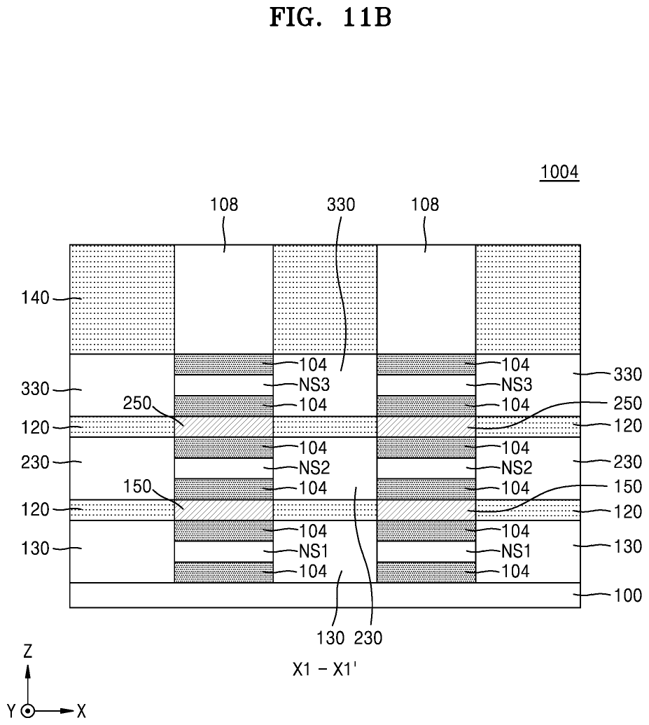

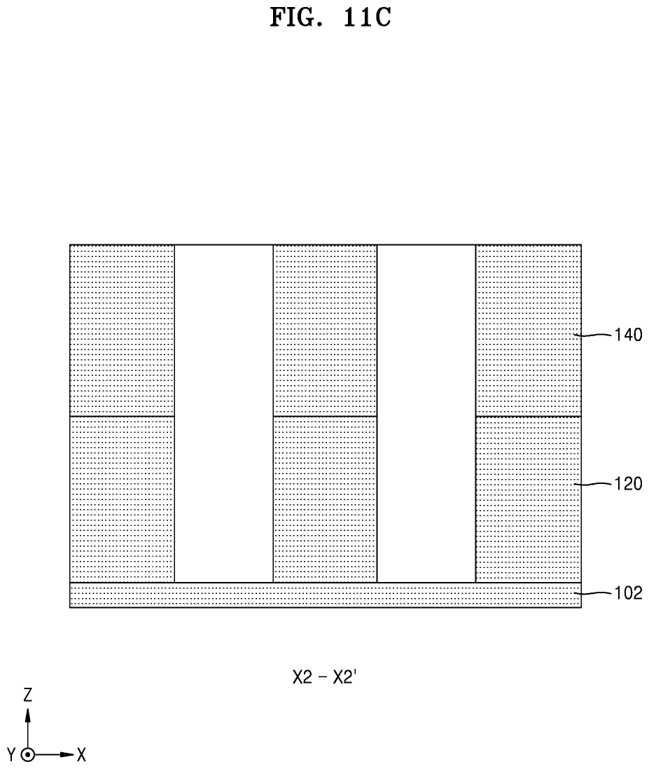

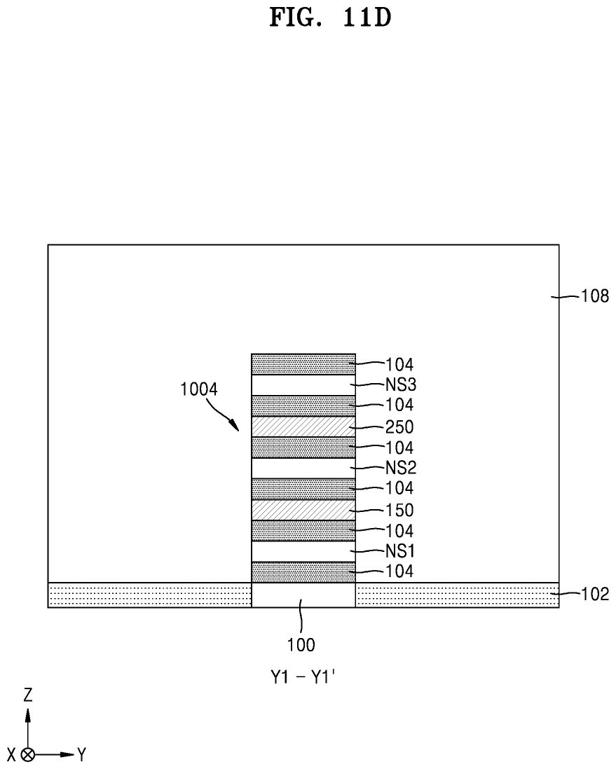

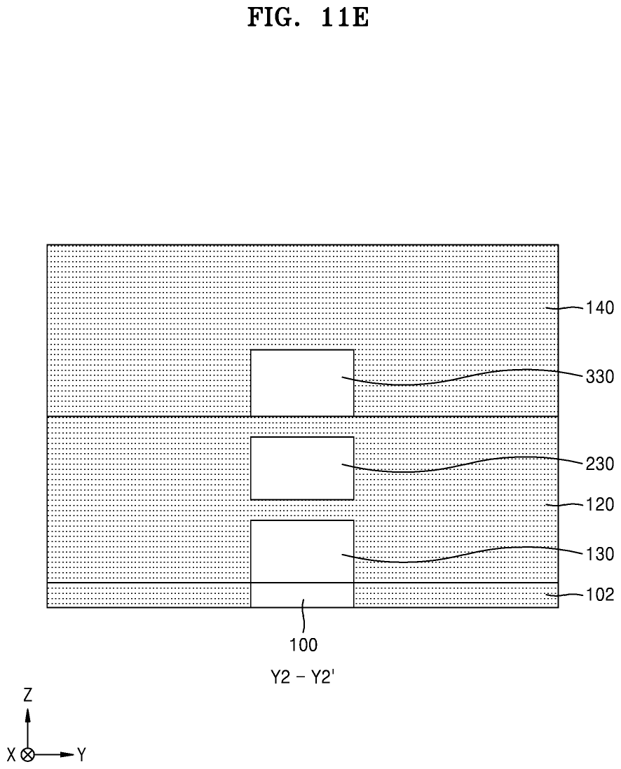

Referring to FIGS. 11A to 11E, the hard mask 109 may be removed from the stack structure 1003 and a second insulating layer 140 surrounding the side surface of the dummy gate 108 in the first horizontal direction X may be formed to provide a stack structure 1004. The second insulating layer 140 may be formed over the first insulating layer 120 and may cover the upper surface of the third source/drain area 330 and both side surfaces thereof in the second horizontal direction Y.

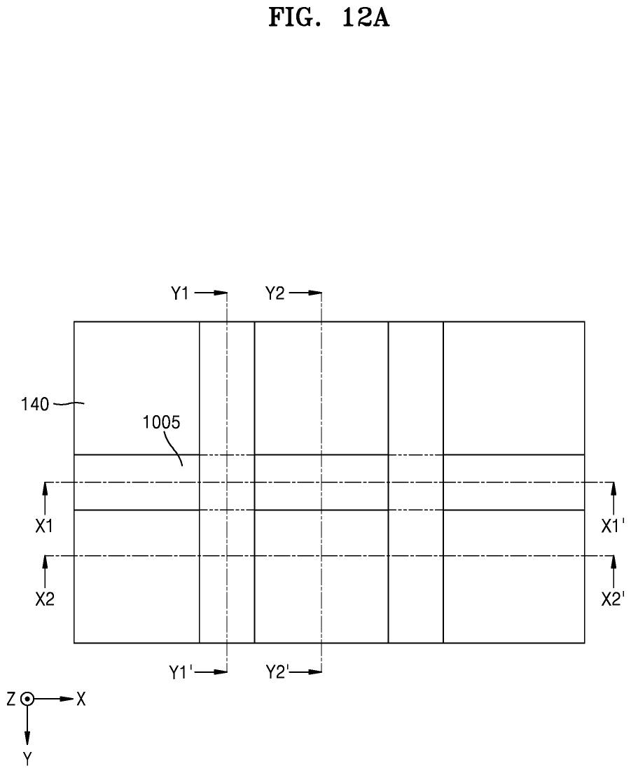

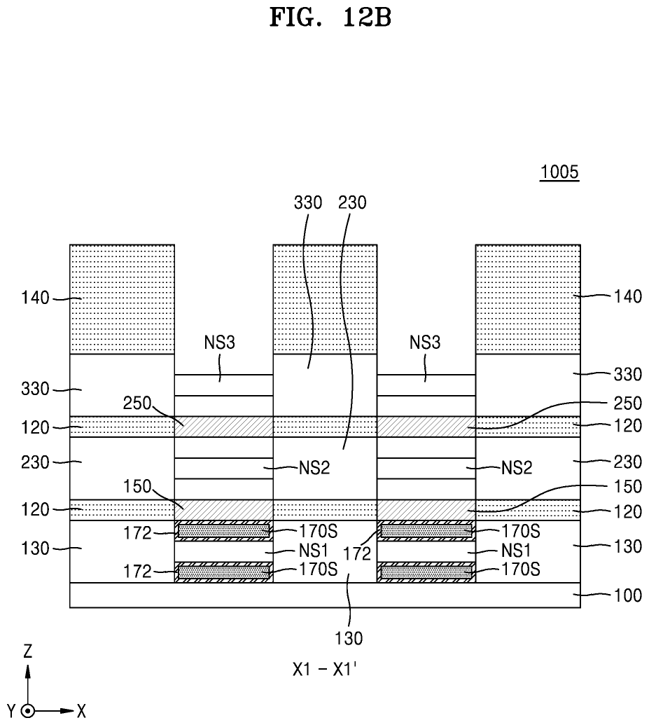

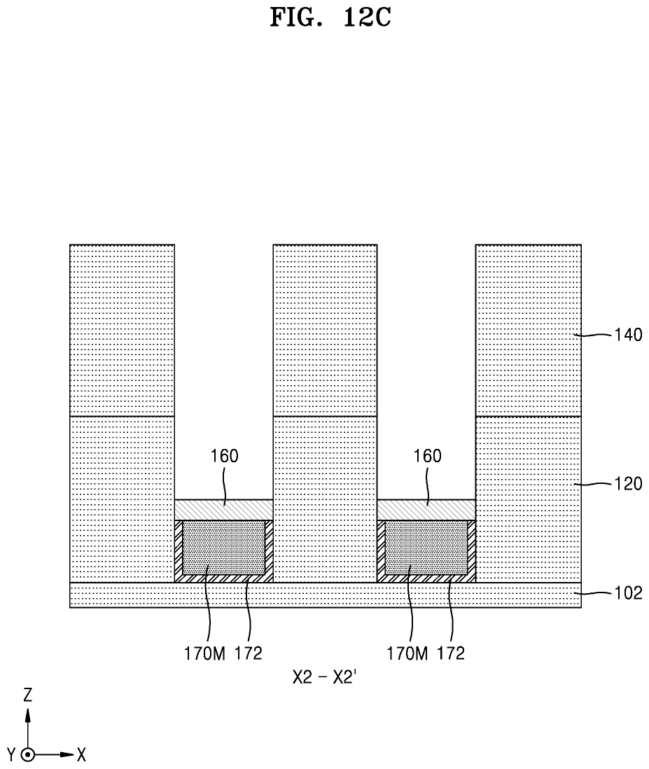

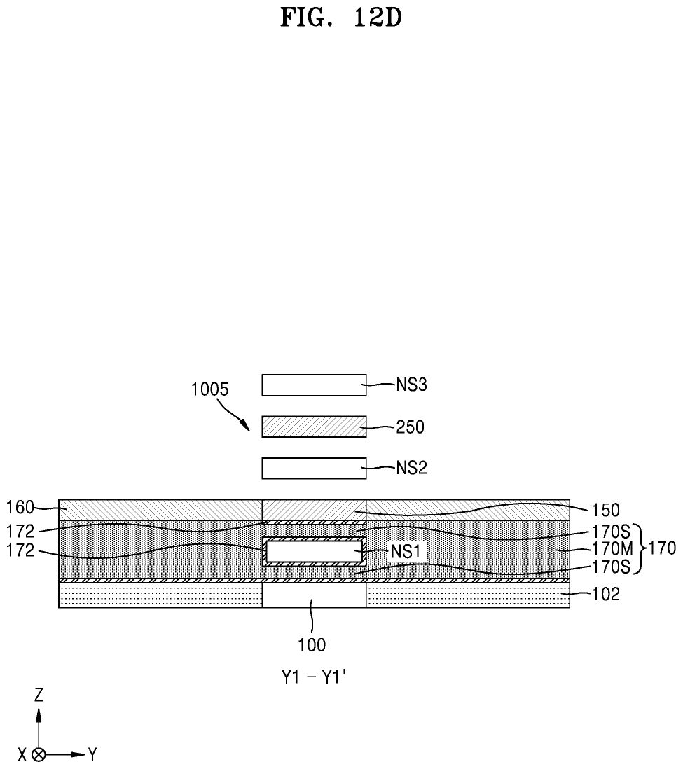

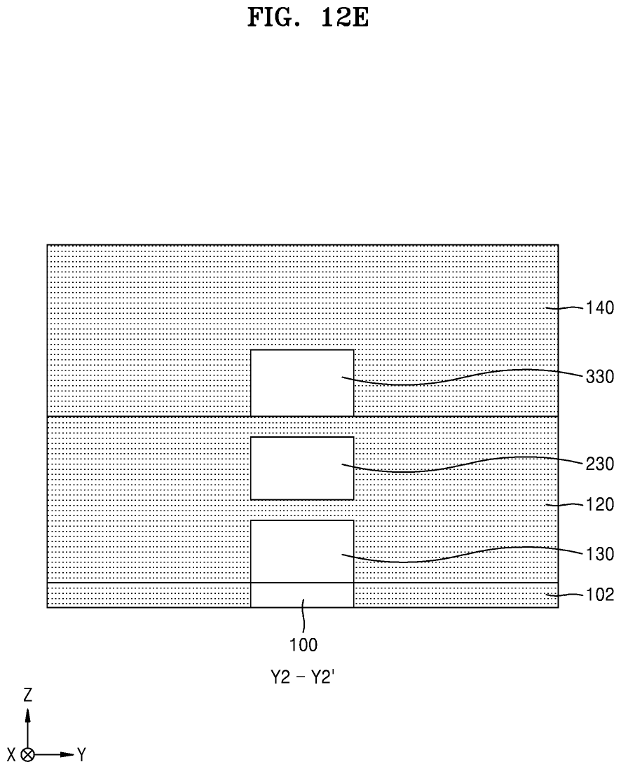

Referring to FIGS. 12A to 14E, the dummy gate 108 and the first sacrificial semiconductor layer 104 may be removed from the stack structure 1004, and a first gate line 170, a second gate line 270, and a third gate line 370 may be sequentially formed. As the first sacrificial semiconductor layer 104 is removed, a total of four surfaces, that is, the upper and lower surfaces of the first to third nanosheet semiconductor layers NS1, NS2, and NS3 of the stack structure 1005 and opposing side surfaces thereof in the second horizontal direction Y, may be exposed. Each of a first gate dielectric layer 172, a second gate dielectric layer 272, and a third gate dielectric layer 372 may be deposited on the exposed portions of the first to third nanosheet semiconductor layers NS1, NS2, and NS3. After the first gate dielectric layer 172 is deposited, the first gate line 170 may be formed. In this case, a first sub-gate 170S of the first gate line 170 may be formed between the substrate 100 and the first nanosheet semiconductor layer NS1 and between the first sub-gate insulating layer 150 and the first nanosheet semiconductor layer NS1, and a first main gate 170M may be formed over the device isolation layer 102. After the first gate line 170 is formed, a first main gate insulating layer 160 covering the upper surface of the first main gate 170M may be formed. After the first main gate insulating layer 160 is formed, a second gate dielectric layer 272 may be deposited and a second gate line 270 may be formed. A second sub-gate 270S of the second gate line 270 may be formed between the first sub-gate insulating layer 150 and the second nanosheet semiconductor layer NS2 and between the second sub-gate insulating layer and the second nanosheet semiconductor layer NS2, and a second main gate 270M may be formed on the upper surface of the first main gate insulating layer 160. After the second gate line 270 is formed, a second main gate insulating layer 260 covering the upper surface of the second main gate 270M may be formed. After the second main gate insulating layer 260 is formed, a third gate dielectric layer 372 may be deposited and a third gate line 370 may be formed. A third sub-gate 370S may be formed between the second sub-gate insulating layer 250 and the third nanosheet semiconductor layer NS3 and on the upper surface of the third nanosheet semiconductor layer NS3, and a third main gate 370M may be formed on the upper surface of the second main gate insulating layer 260.

After the third gate line 370 is formed, a third insulating layer 360 covering the upper surface of the third gate line 370 may be formed. The third insulating layer 360 may cover the upper surface of the third gate line 370 and may extend in the second horizontal direction Y.

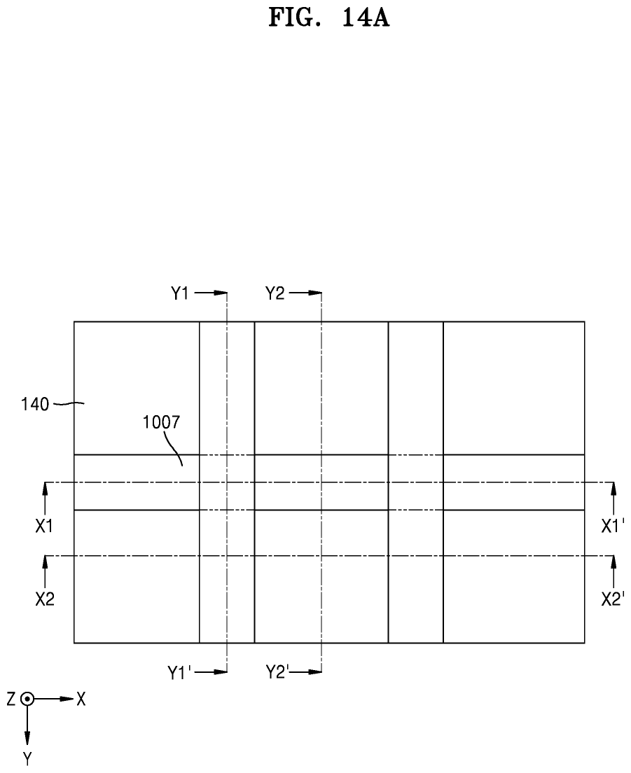

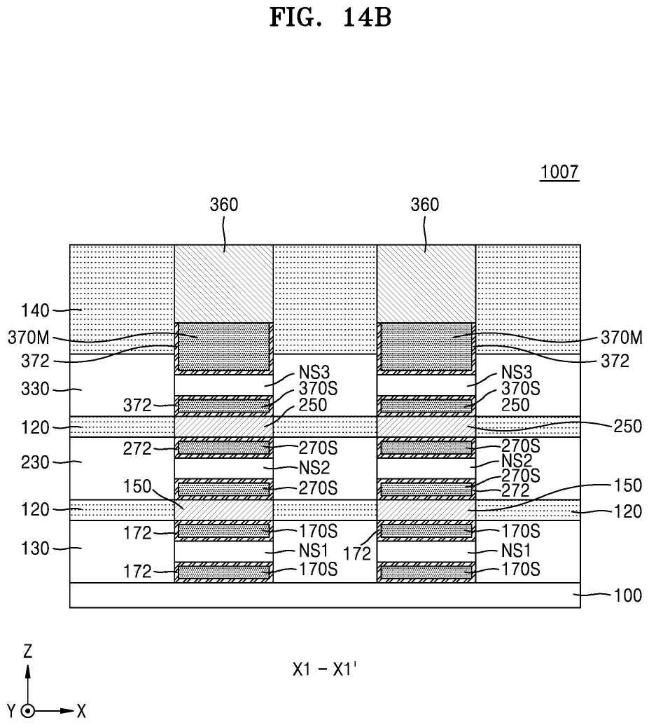

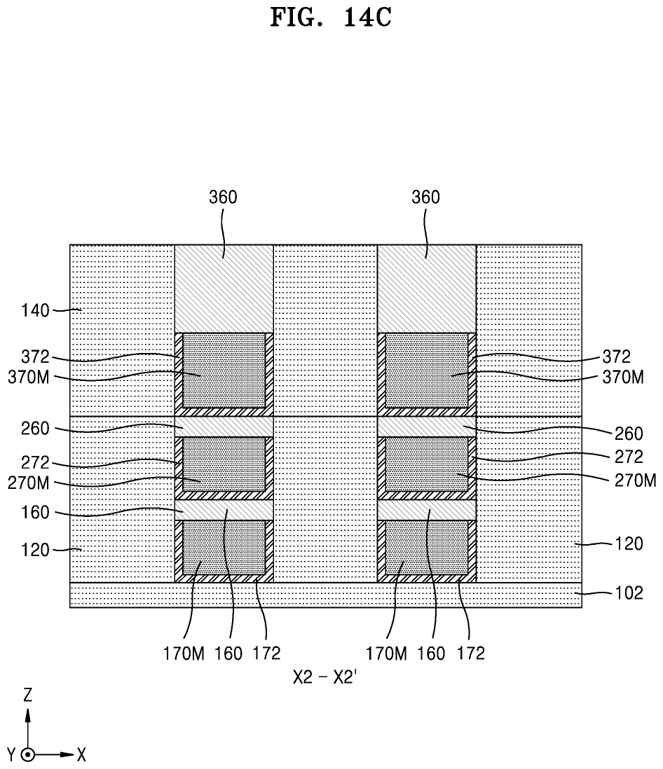

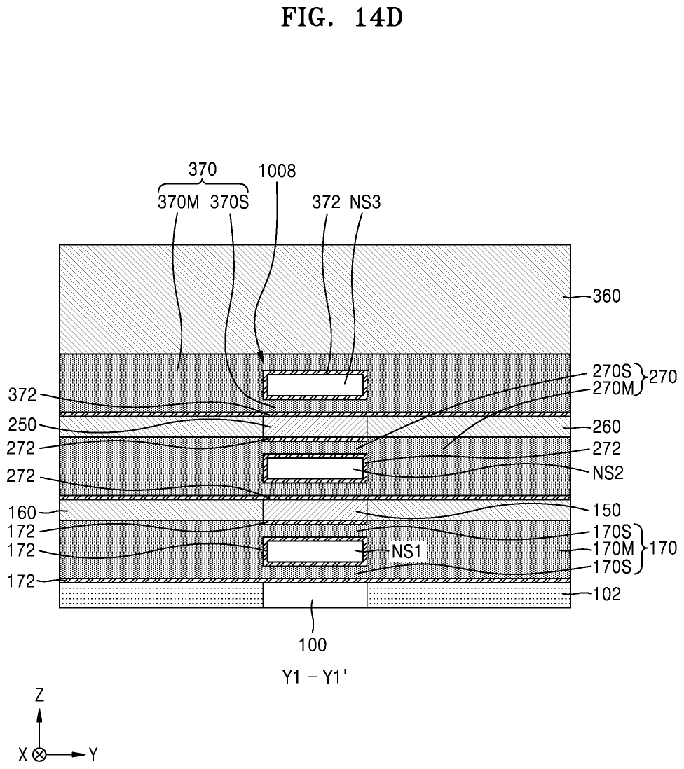

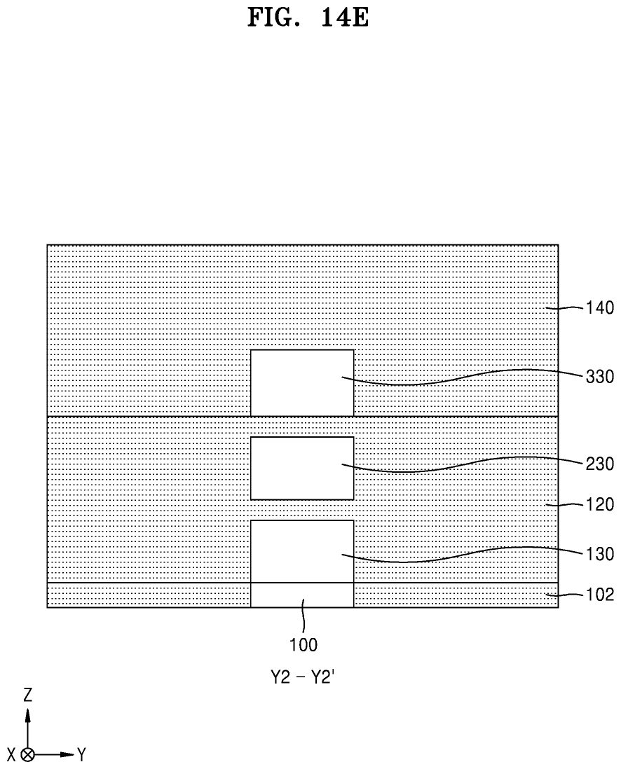

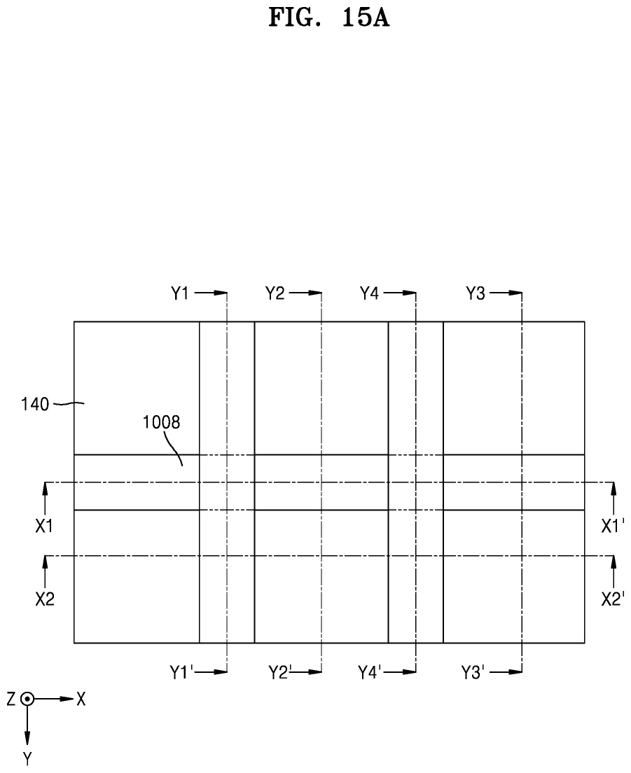

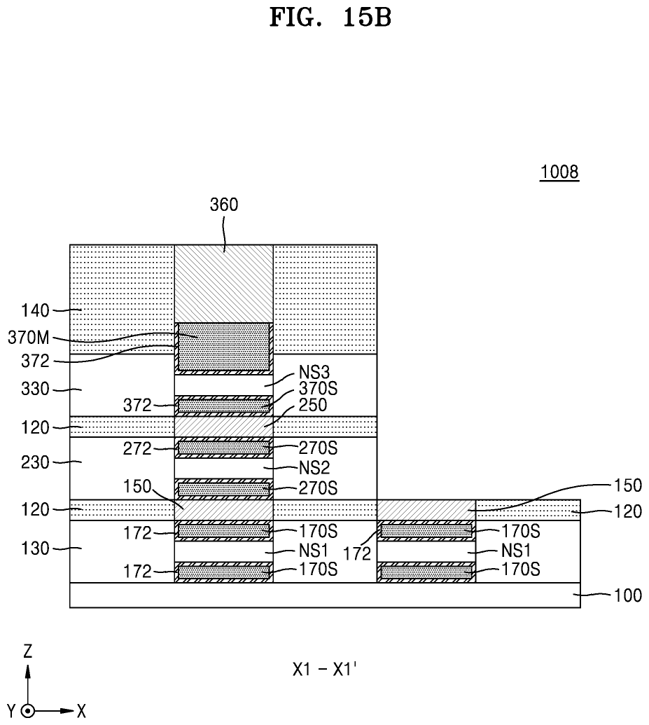

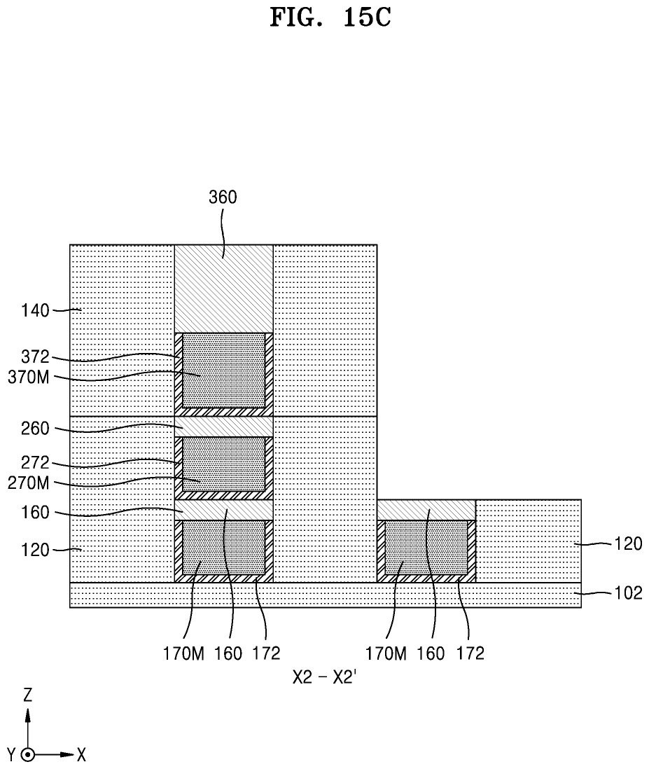

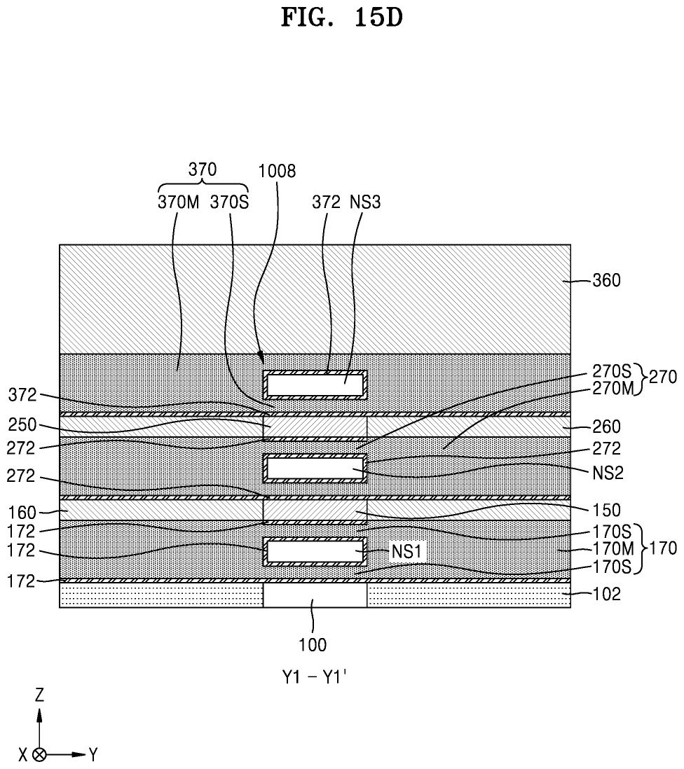

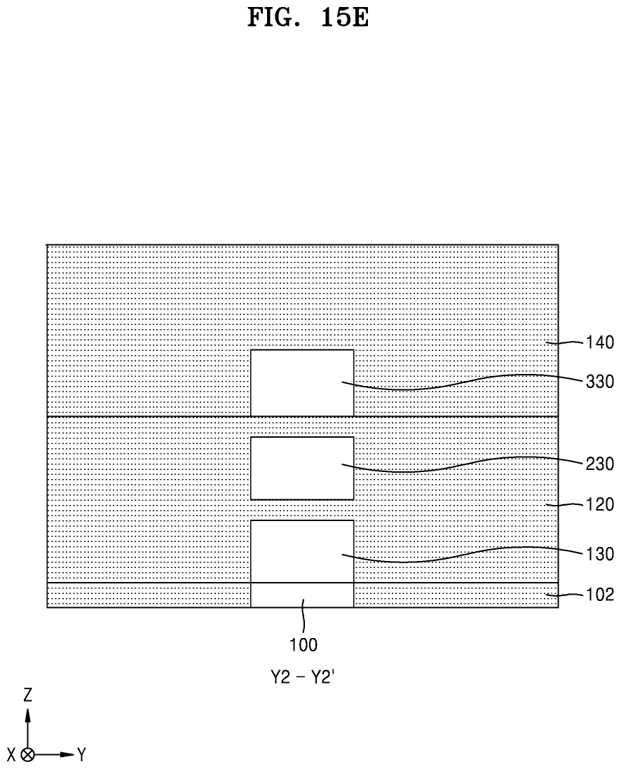

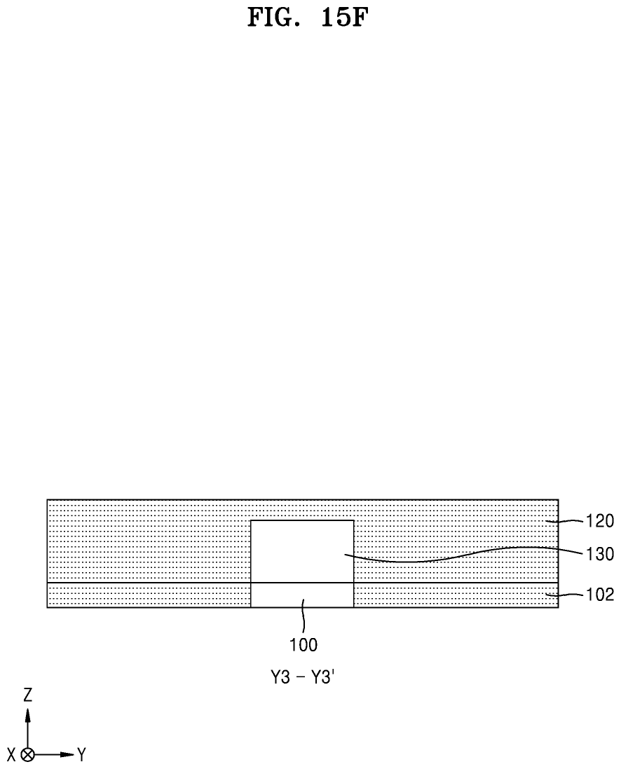

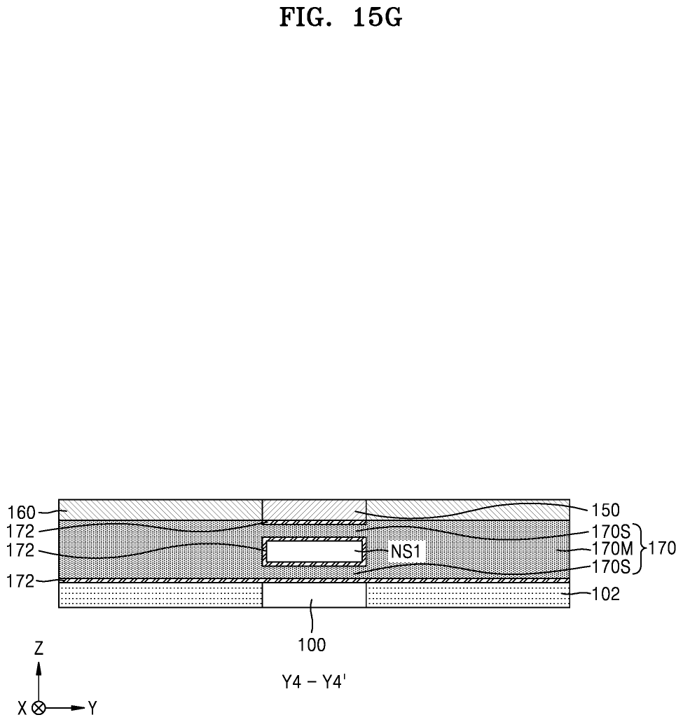

Referring to FIGS. 15A to 15G, a portion of a stack structure 1007 (see FIG. 14B) may be etched in the vertical direction Z from the upper surface of the stack structure 1007 to the first sub-gate insulating layer 150 to provide a stack structure 1008. According to embodiments, the stack structure 1008 may include three first source/drain areas 130, two second source/drain areas 230, and two third source/drain areas 330. By the etching, the upper surface of the first sub-gate insulating layer 150 located on the upper surface of the fourth transistor TR4 (see FIG. 2A) among the first sub-gate insulating layers 150 may be exposed upward in the vertical direction Z. The upper surface of the first insulating layer 120 covering the first transistor TR1 (see FIG. 2A) and the second transistor TR2 (see FIG. 2A) may be located at a higher vertical level than the upper surface of the first insulating layer 120 covering the fourth transistor TR4. The upper surface of the first main gate insulating layer 160 covering the first main gate 170M of the fourth transistor TR4 may be exposed upward in the vertical direction Z.

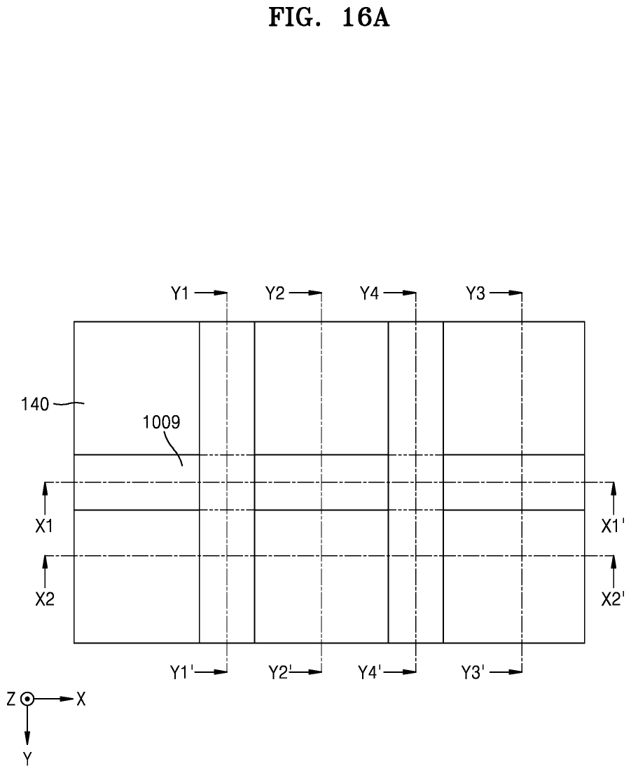

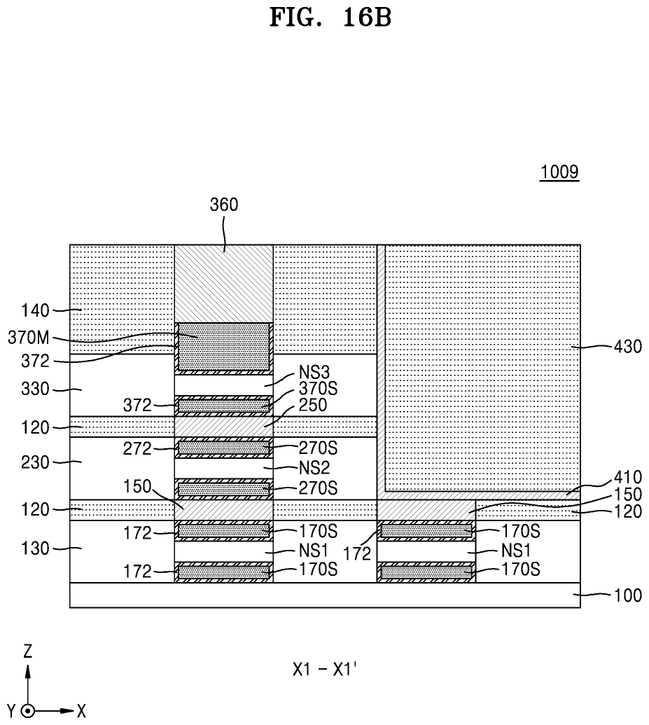

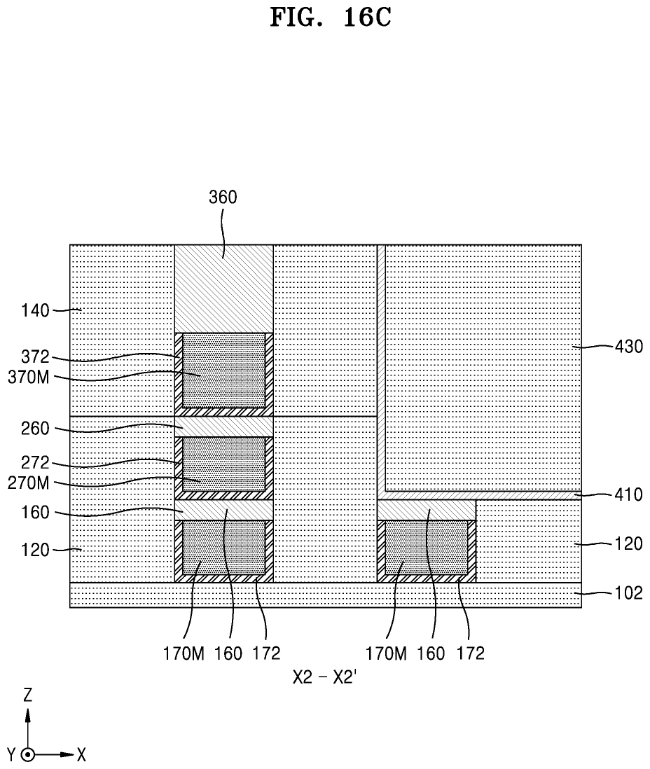

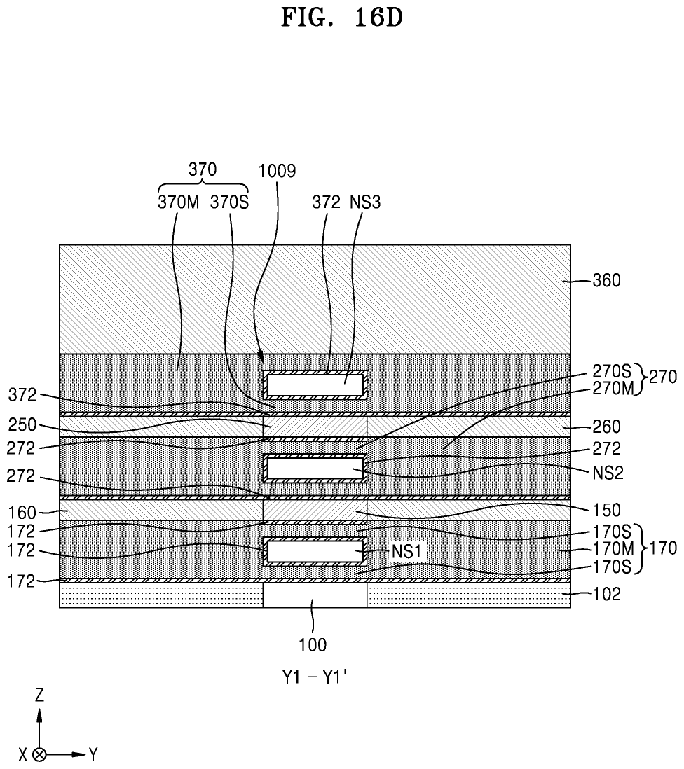

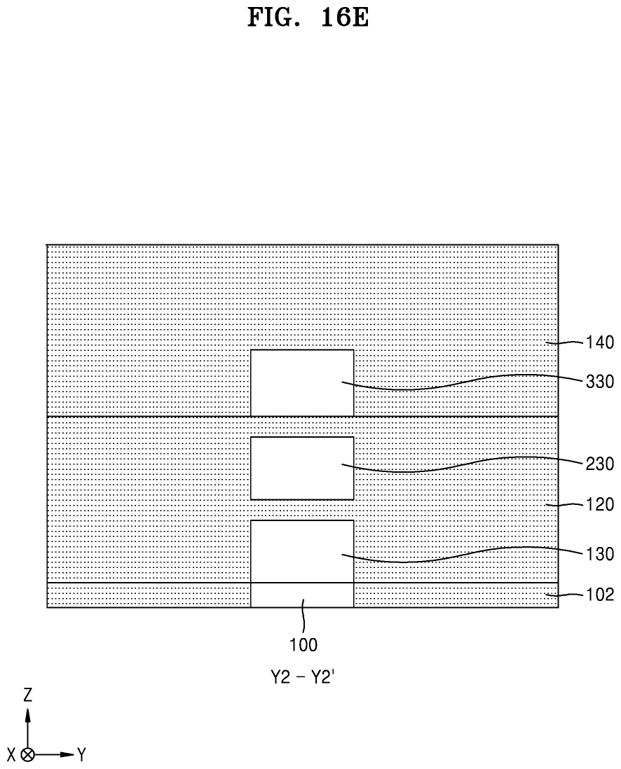

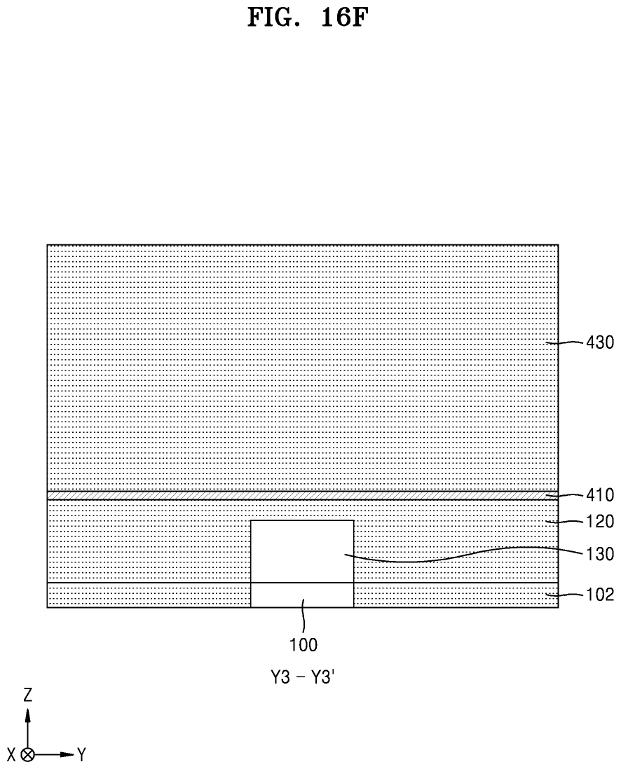

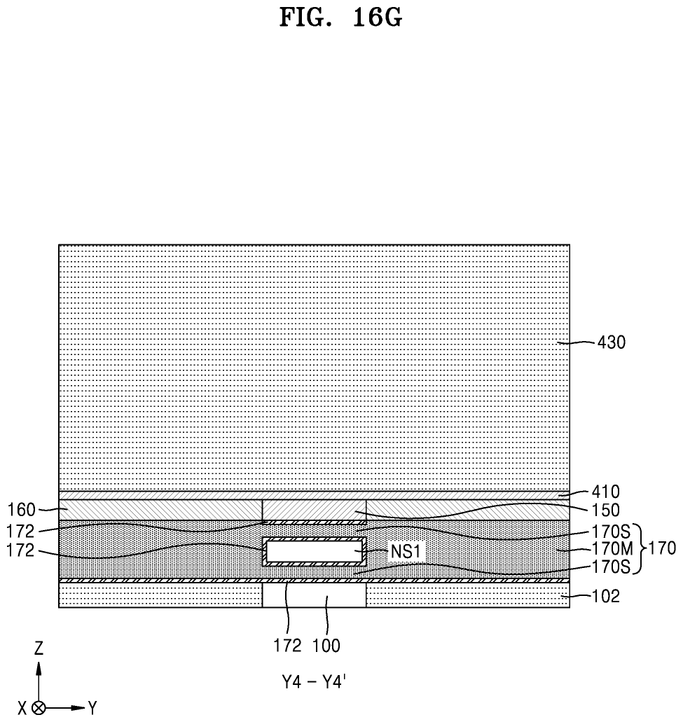

Referring to FIGS. 16A to 16G, a fourth insulating layer 410 and a fifth insulating layer 430 filling the etched portion of the stack structure 1008 may be formed to provide a stack structure 1009. The term “filling” (or “fill,” or “fills,” or like terms), as may be used herein, is intended to refer broadly to either completely filling a defined space (e.g., the etched portion of the stack structure 1008) or partially filling the defined space; that is, the defined space need not be entirely filled but may, for example, be partially filled or have voids or other spaces throughout. In some embodiments, only the fifth insulating layer 430 may be formed without the fourth insulating layer 410. The fourth insulating layer 410 may be deposited on an externally exposed portion of the etched area of the stack structure 1008. Particularly, the fourth insulating layer 410 may be formed on the upper surface of the first sub-gate insulating layer 150 of the fourth transistor TR4 and the upper surface of the first insulating layer 120 located on the upper surface of the first source/drain area 130 of the fourth transistor TR4 and may be formed on the side surface of each of the second source/drain area 230 and the third source/drain area 330, the side surface of the first insulating layer 120 located between the second source/drain area 230 and the third source/drain area 330, and the side surface of the second insulating layer 140.

A fifth insulating layer 430 may be formed to cover the fourth insulating layer 410. The upper surface of the fifth insulating layer 430 may be located at substantially the same vertical level, relative to an upper surface of the device isolation layer 102, as the upper surface of the third insulating layer 360; that is, the upper surface of the fifth insulating layer 430 may be coplanar with the upper surface of the third insulating layer 360 in the vertical direction Z. The fifth insulating layer 430 may overlap each of the second gate line 270 and the third gate line 370 in the first horizontal direction X.

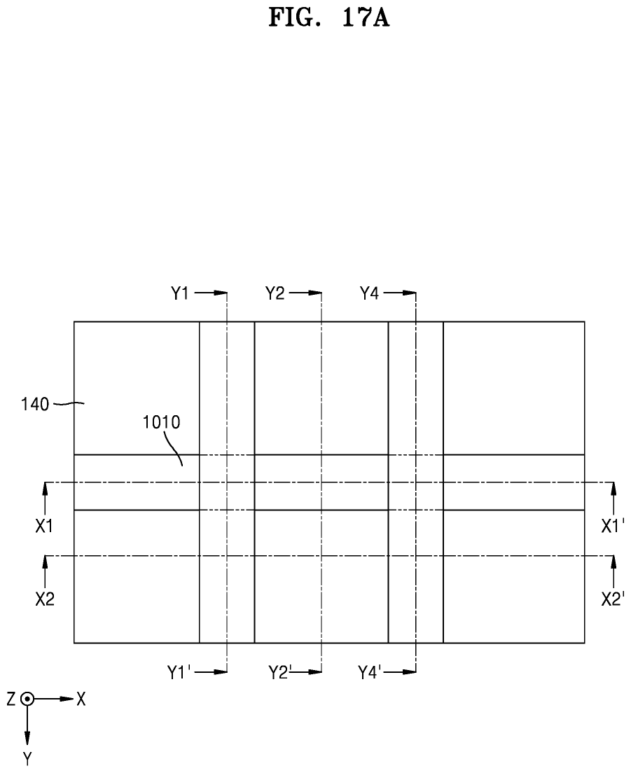

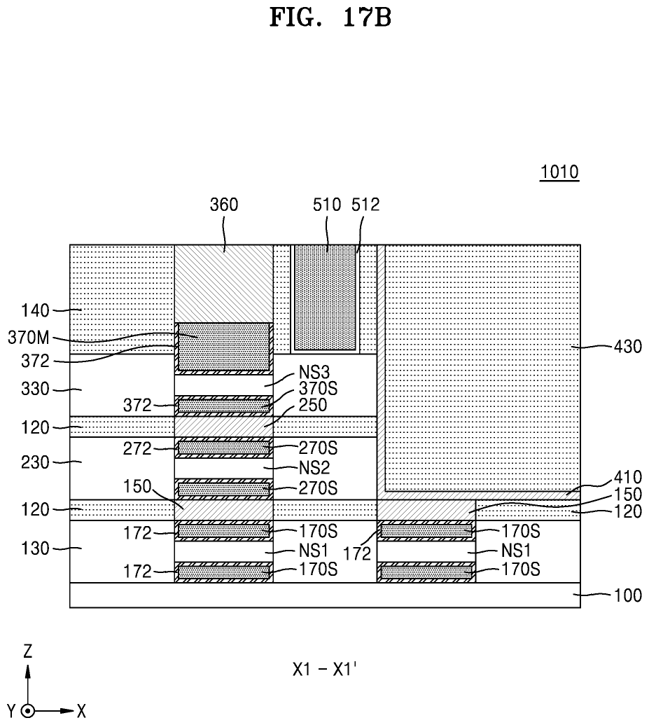

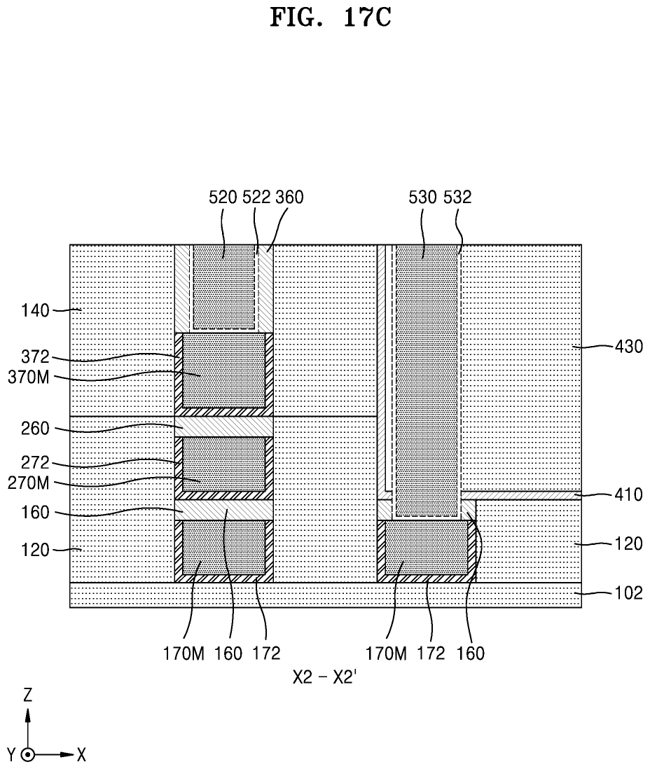

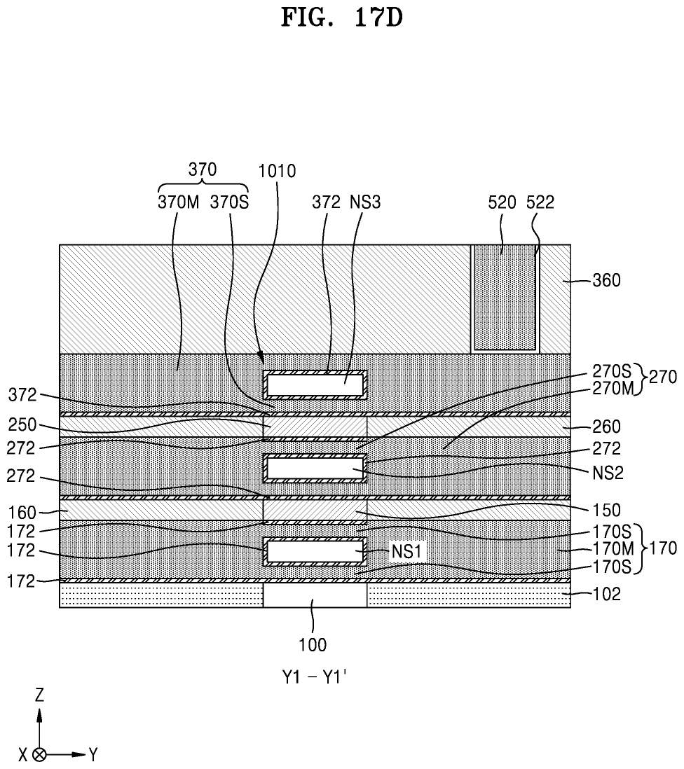

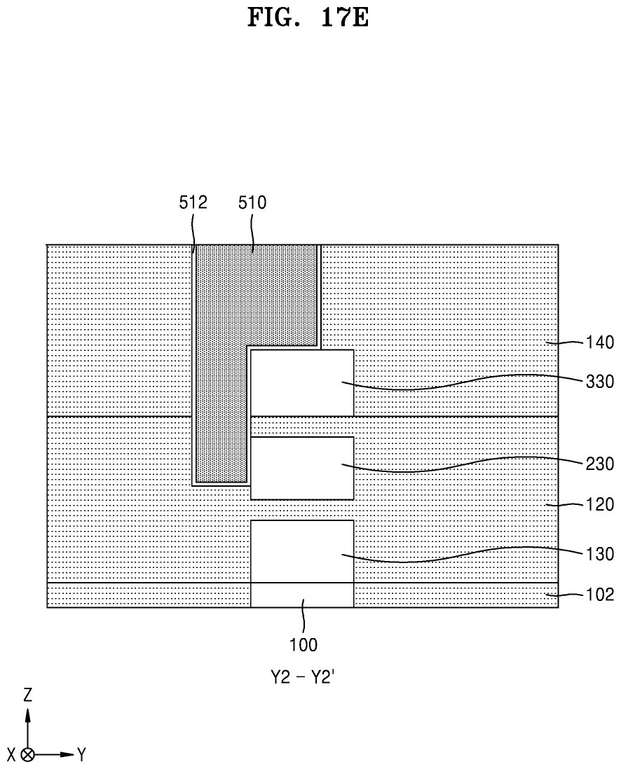

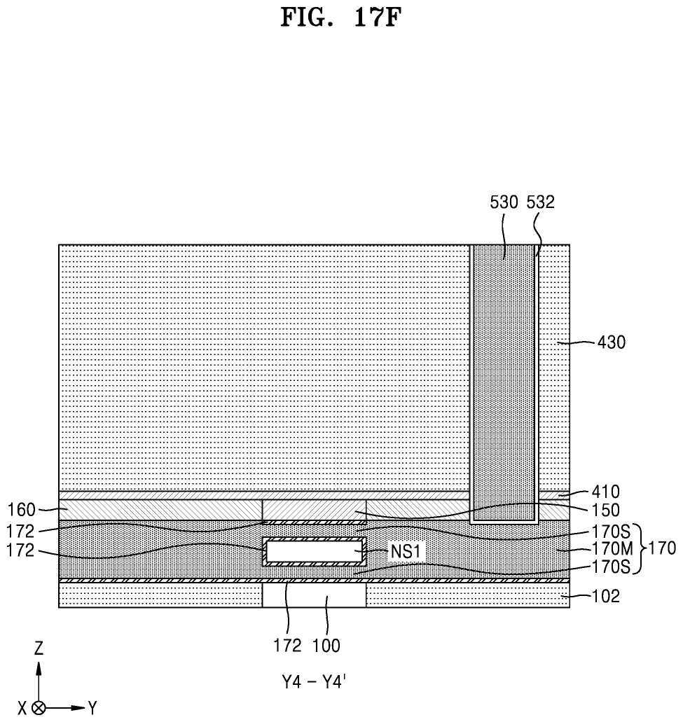

Referring to FIGS. 17A to 17F, a stack structure 1010 in which a first upper source/drain contact 510, a first upper gate contact 520, and a second upper gate contact 530 are formed may be provided. The first upper source/drain contact 510 may be formed to extend into the second insulating layer 140 and the third source/drain area 330 in the vertical direction Z. The first upper source/drain contact 510 may be configured to contact at least side surfaces of the third source/drain area 330 and the second source/drain area 230. According to some embodiments, the first upper source/drain contact 510 may contact the side surface of the second source/drain area 230 and may contact the upper and side surfaces of the third source/drain area 330. However, the inventive concept is not limited thereto, and the first upper source/drain contact 510 may contact only the side surface of the second source/drain area 230 and the side surface of the third source/drain area 330. The first upper gate contact 520 may be connected to the third gate line 370 through the third insulating layer 360, and the second upper gate contact 530 may be connected to the first gate line 170 through the fourth insulating layer 410 and the fifth insulating layer 430. In this case, the second upper gate contact 530 may be connected to the first gate line 170 by further passing through any one of the first sub-gate insulating layer 150 and the first main gate insulating layer 160.

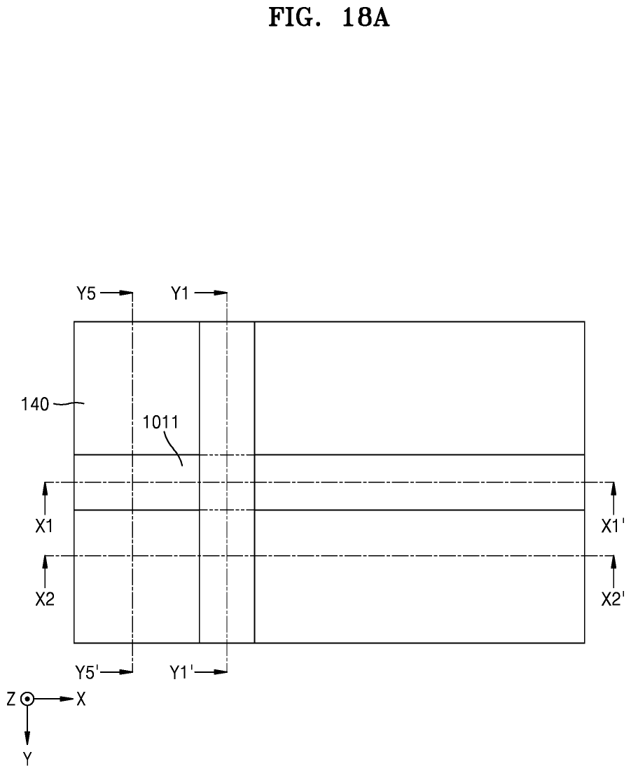

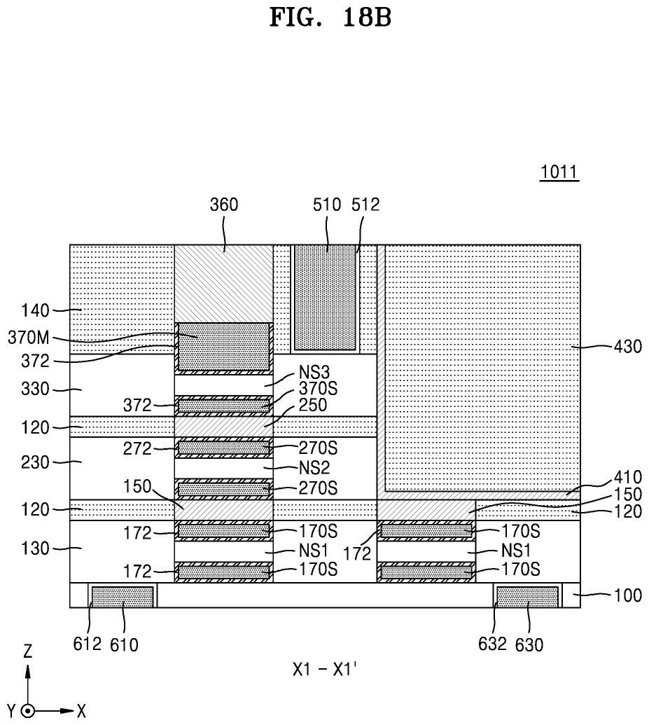

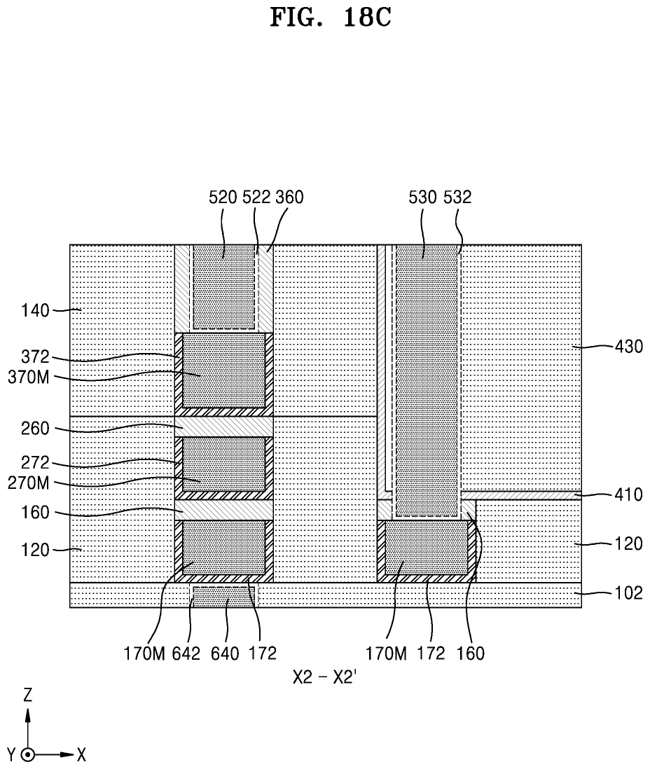

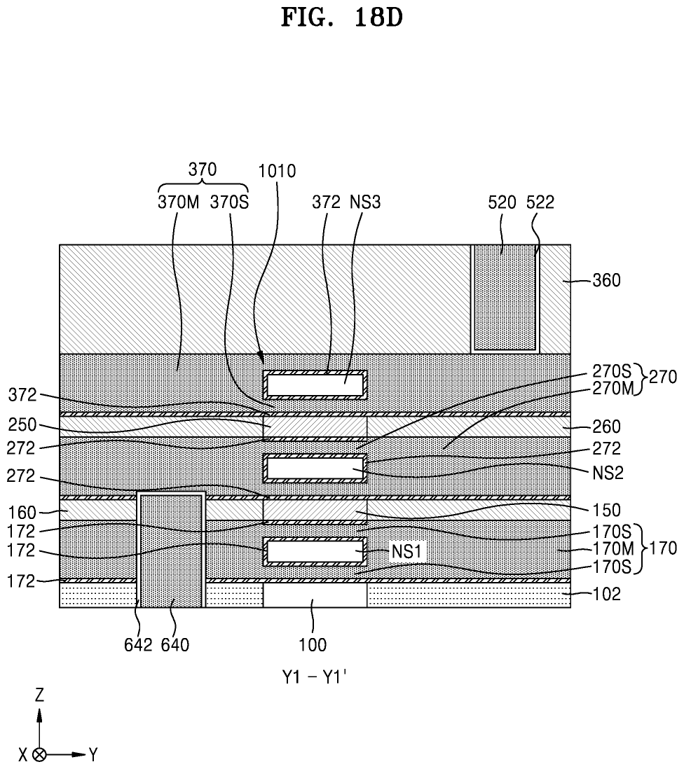

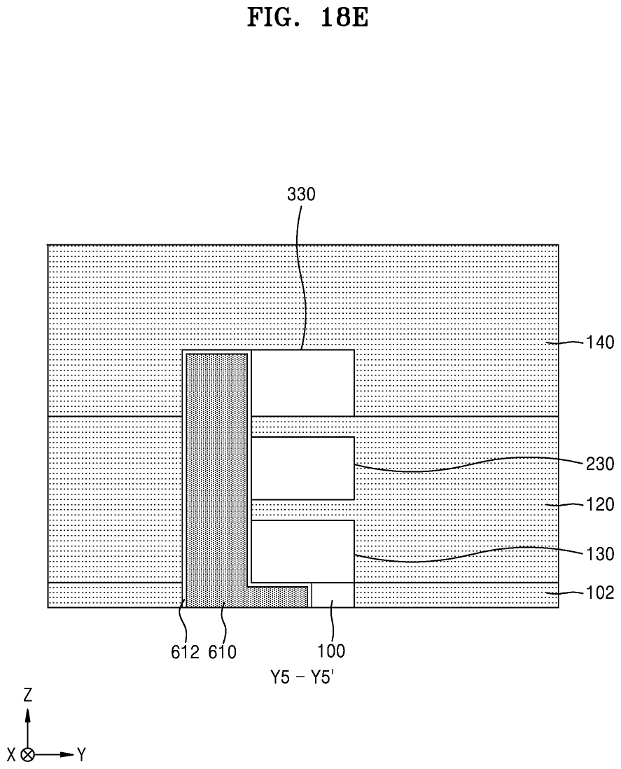

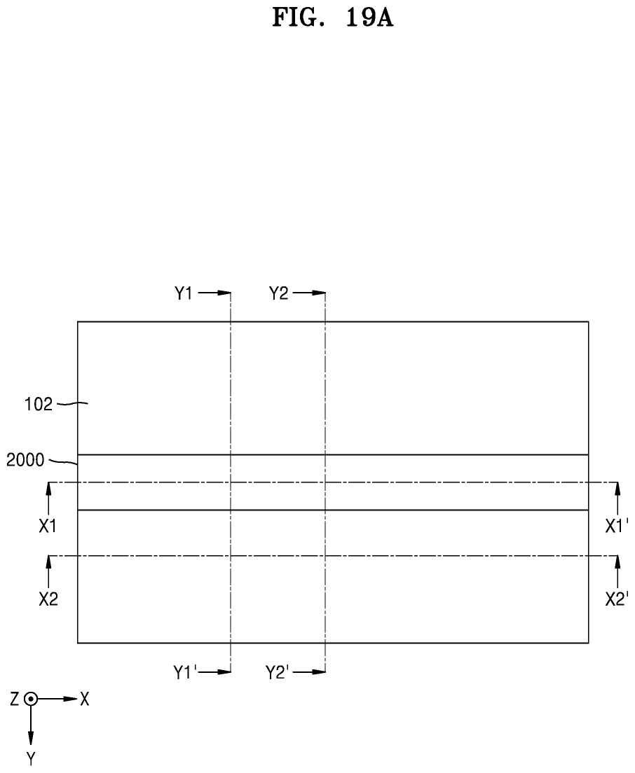

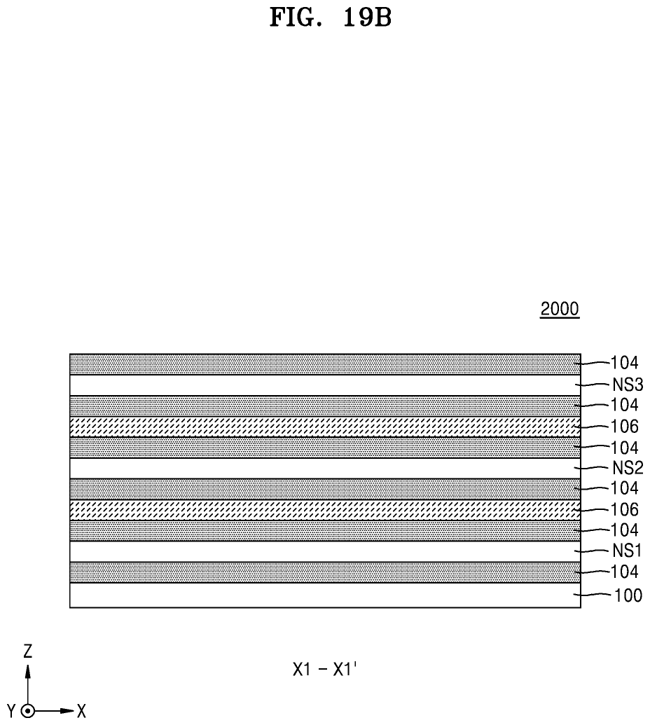

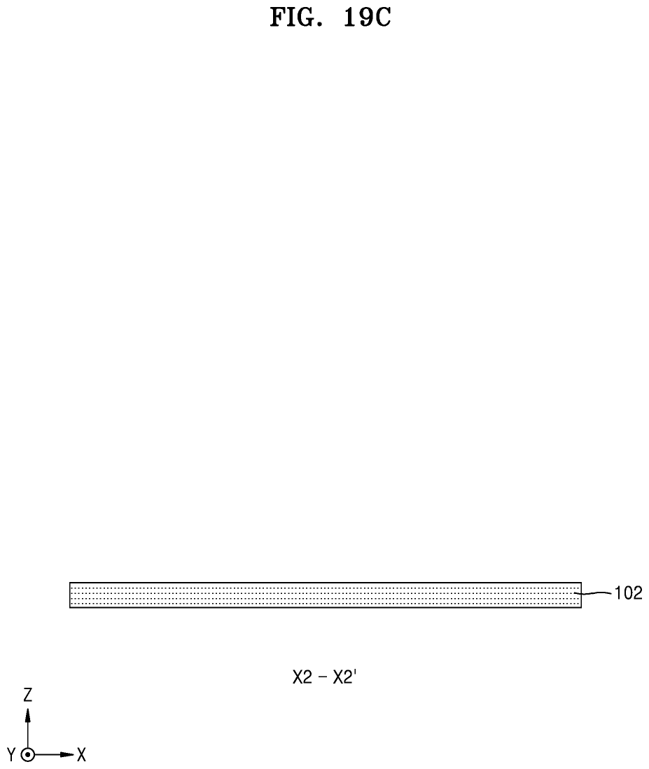

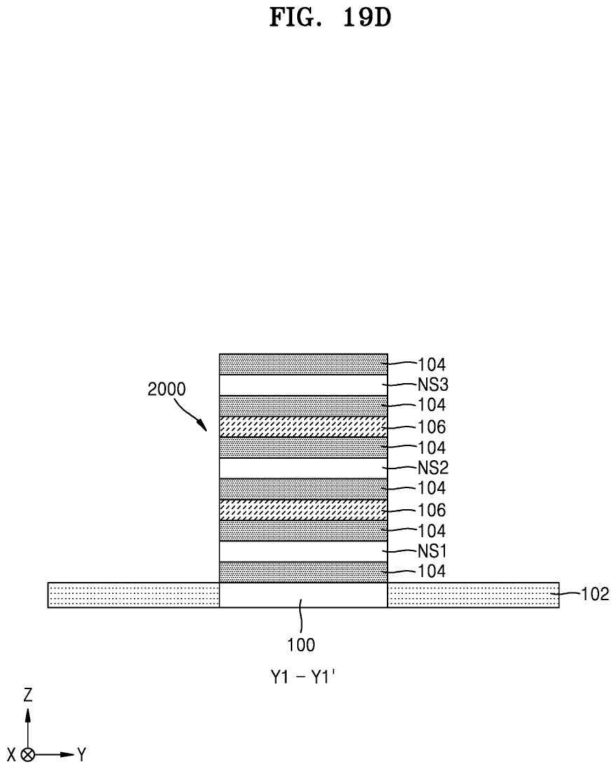

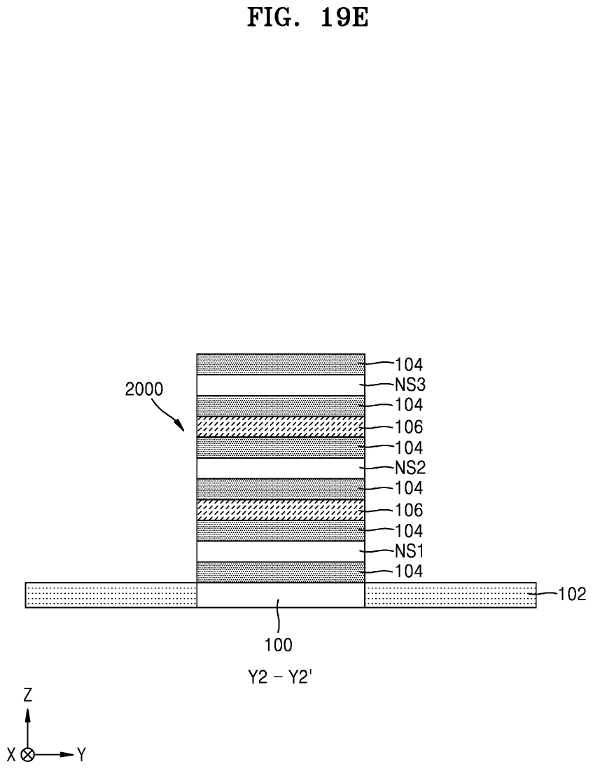

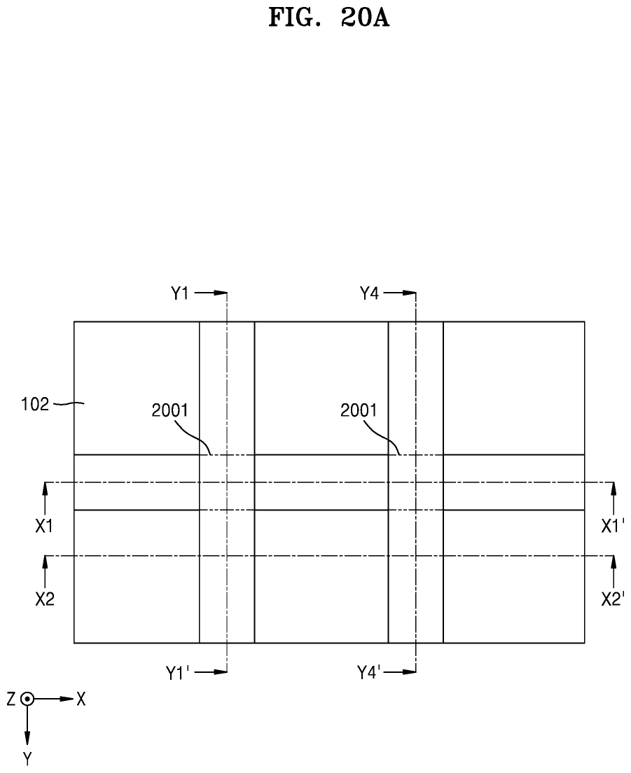

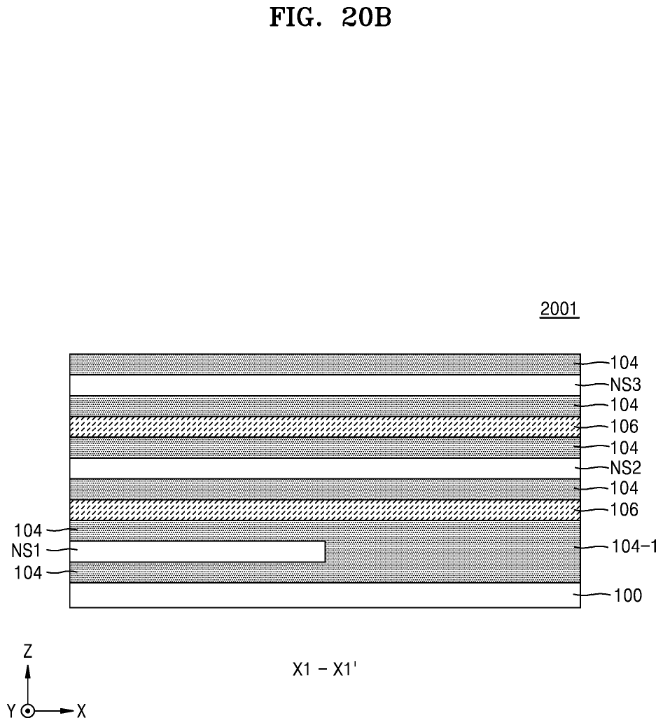

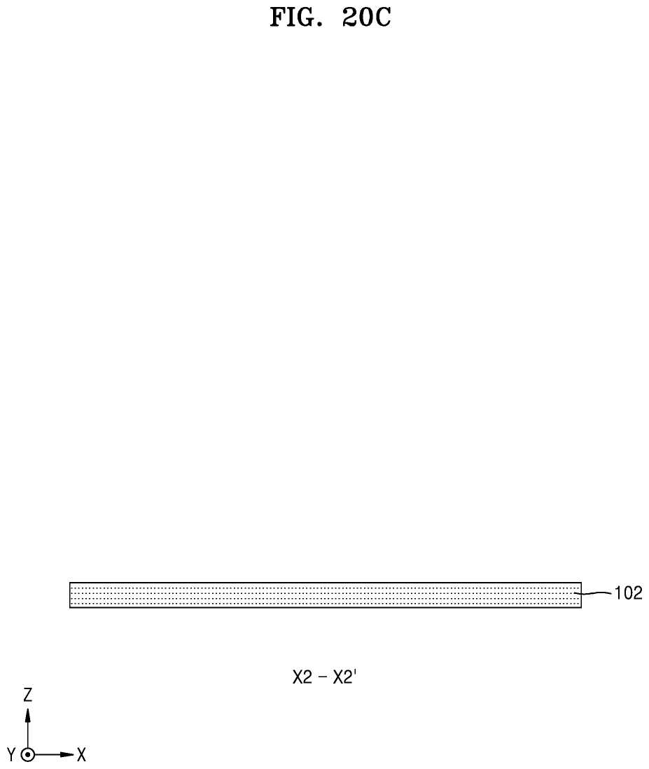

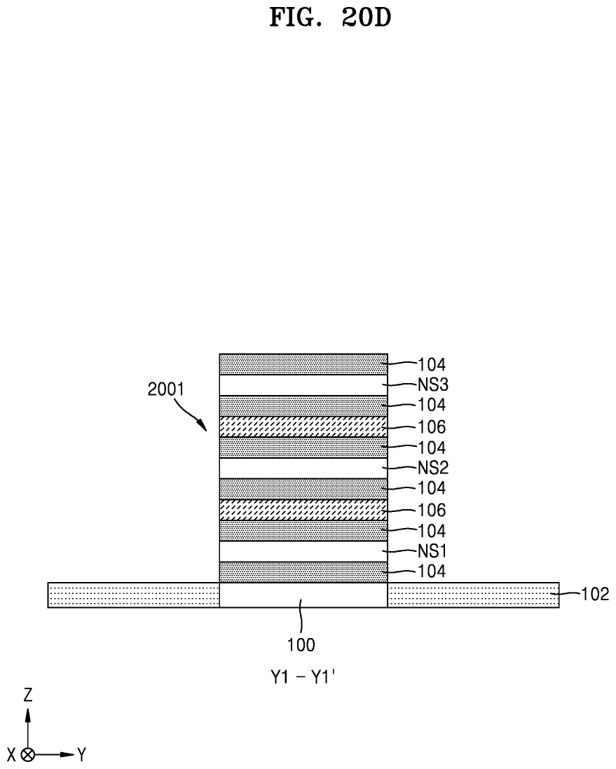

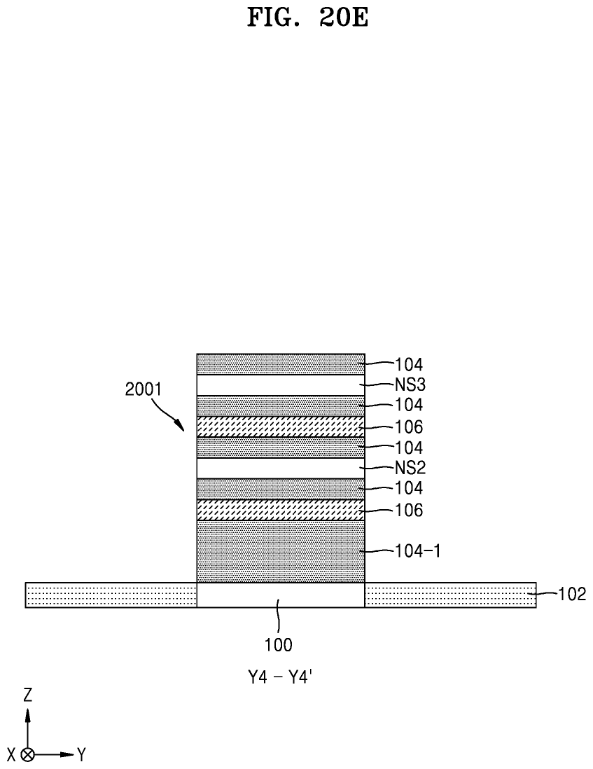

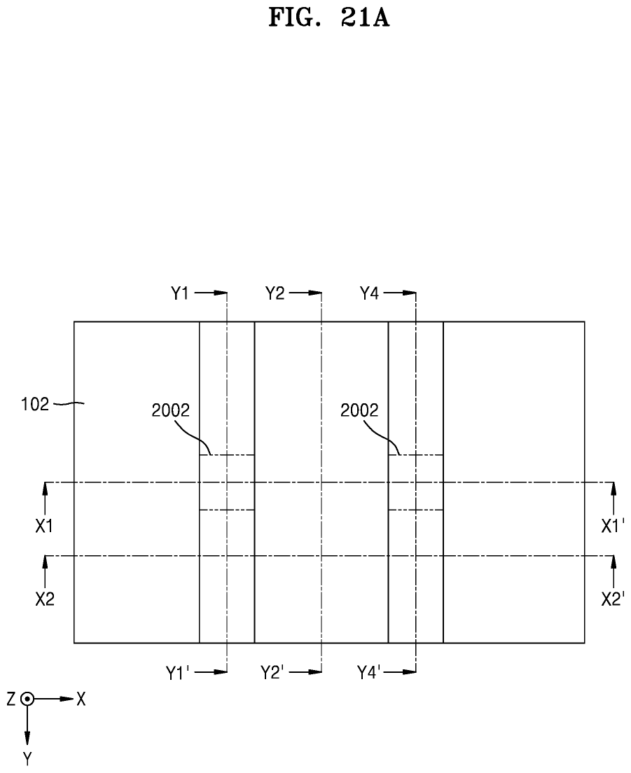

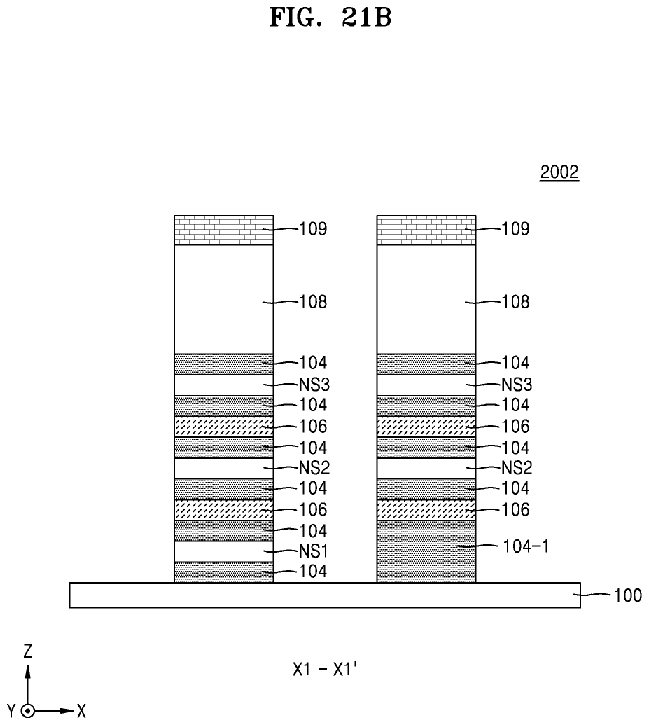

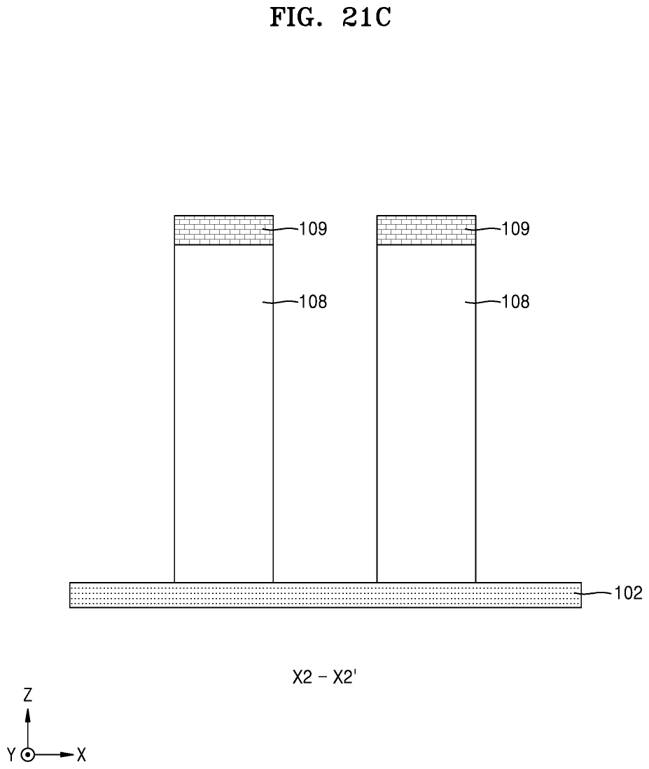

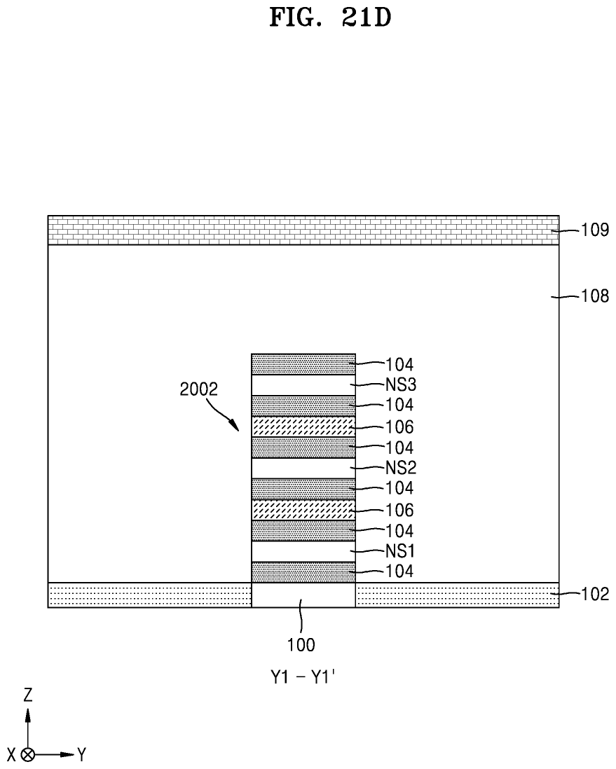

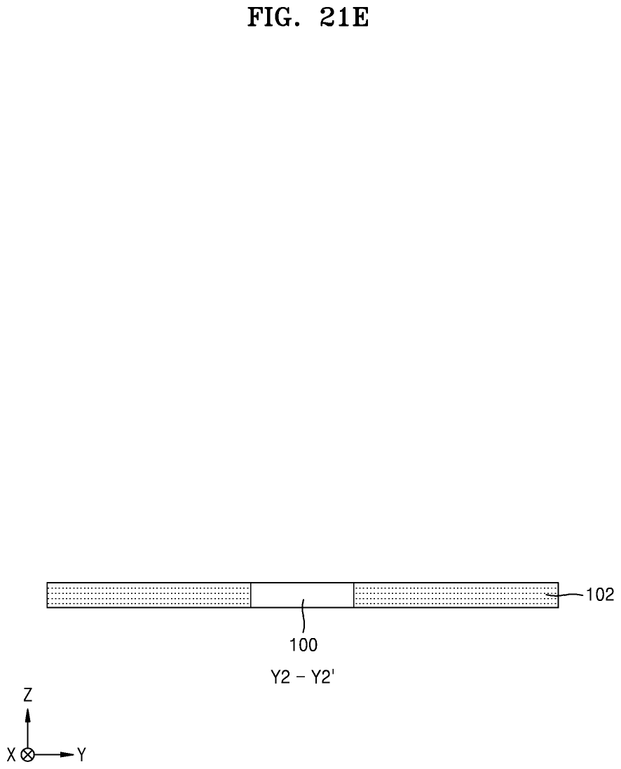

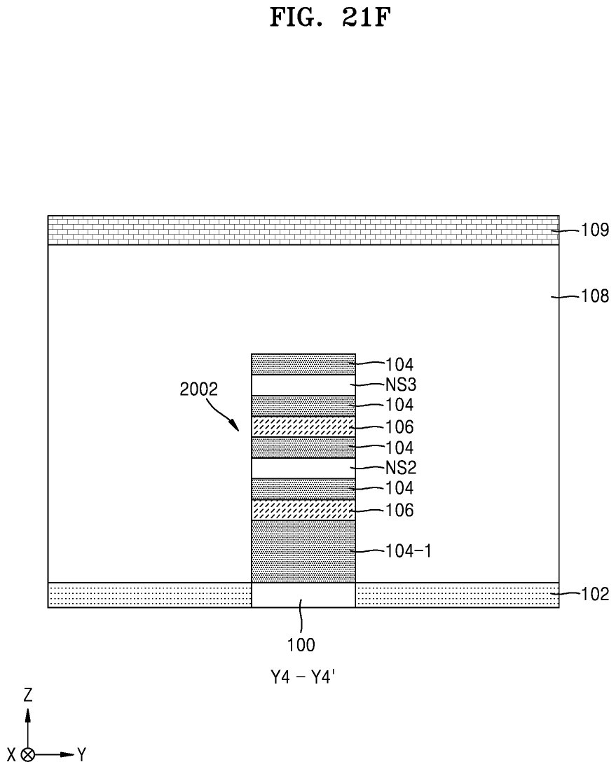

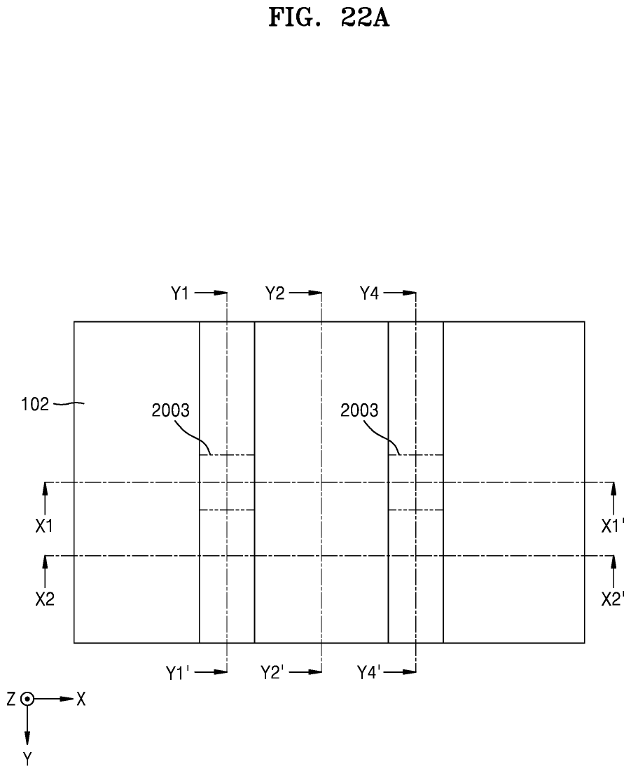

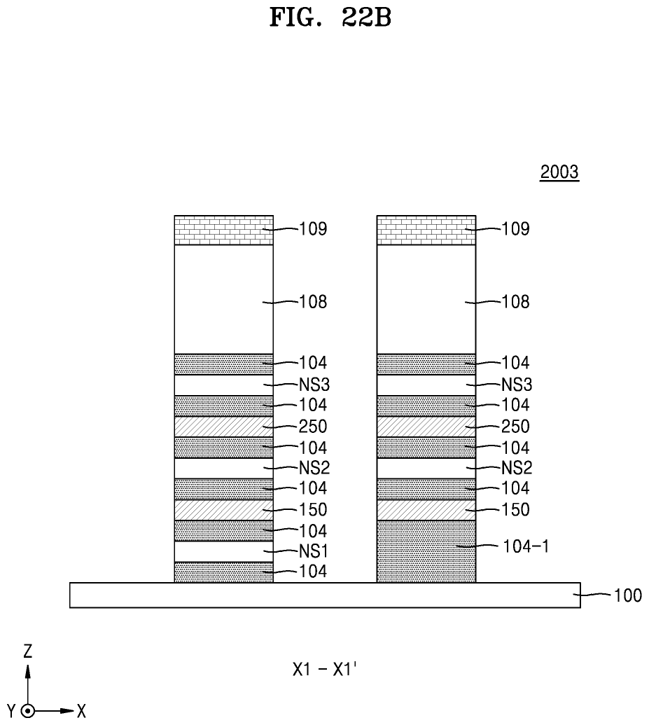

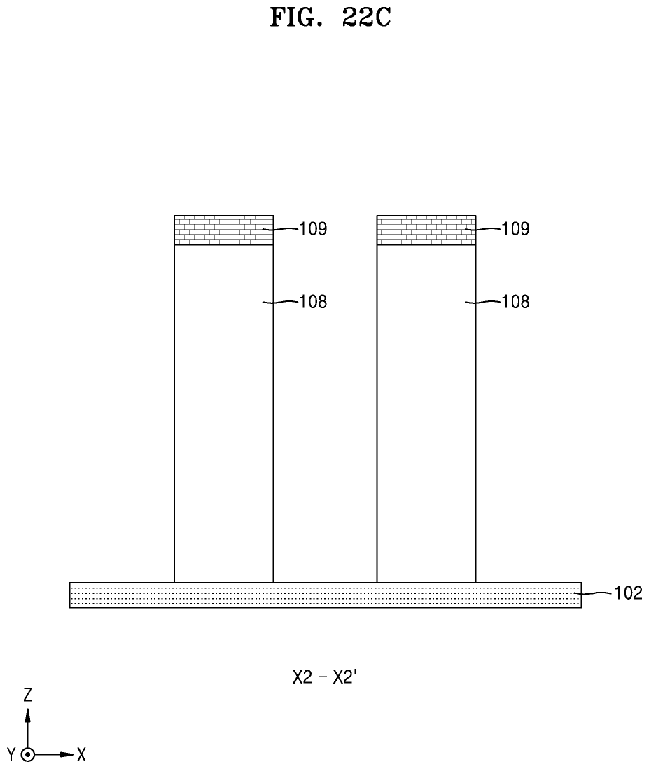

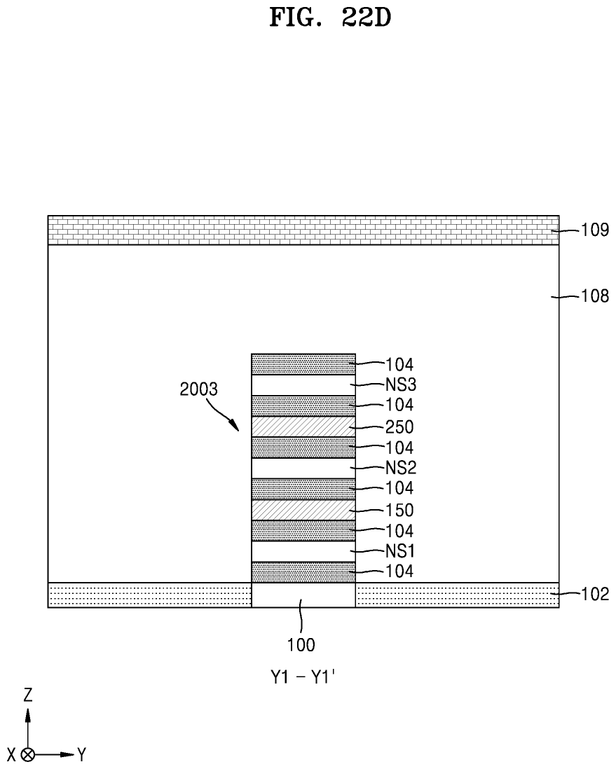

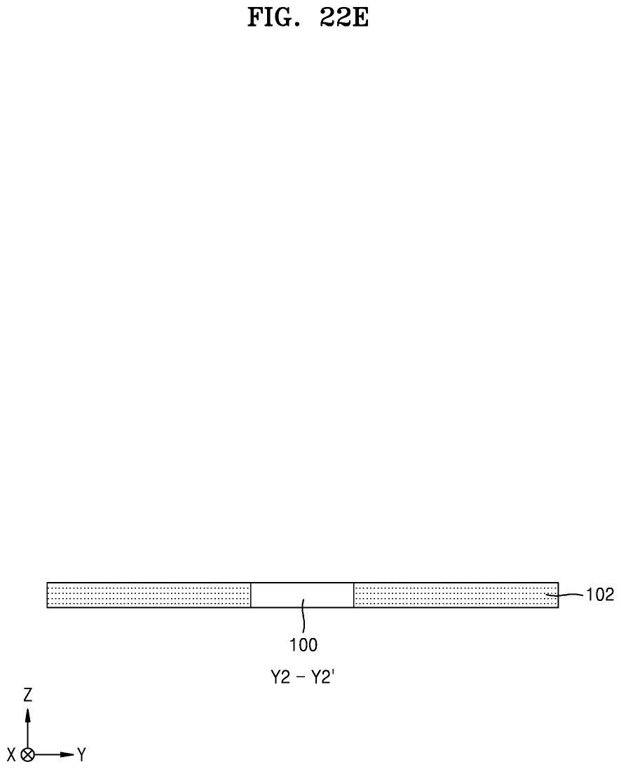

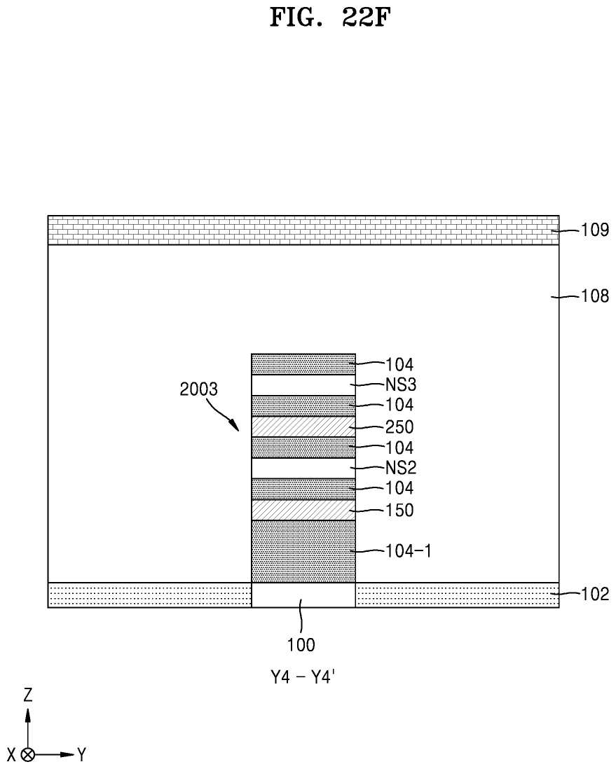

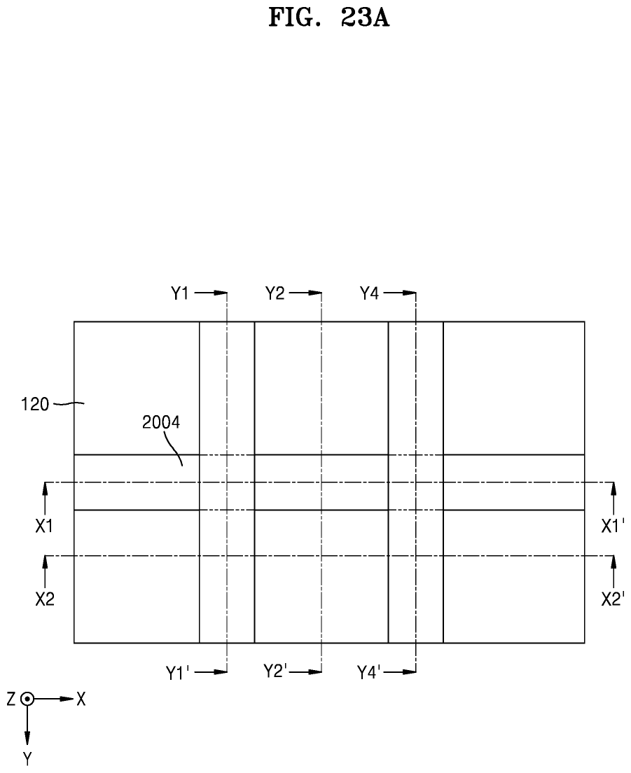

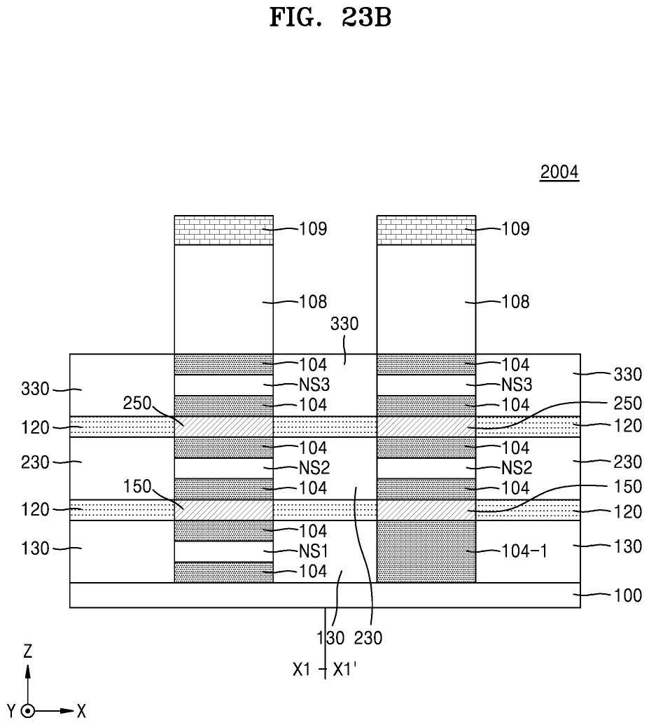

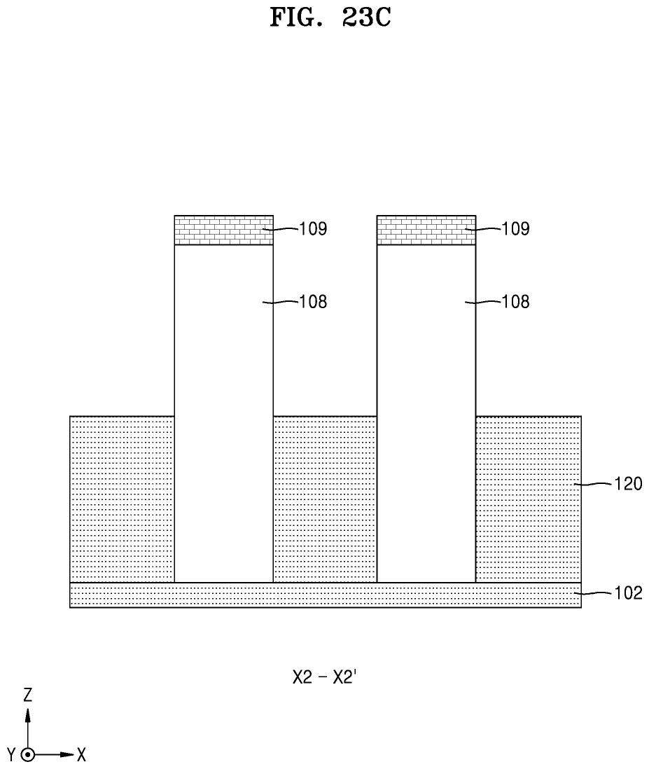

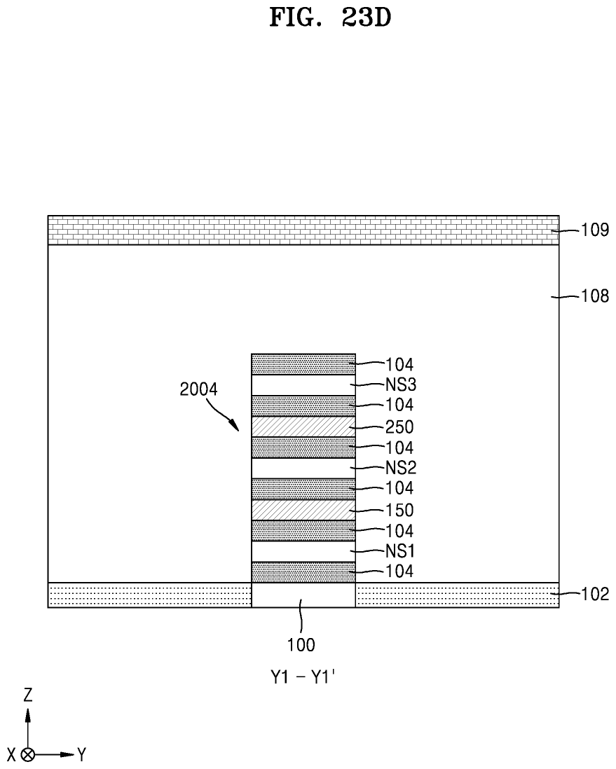

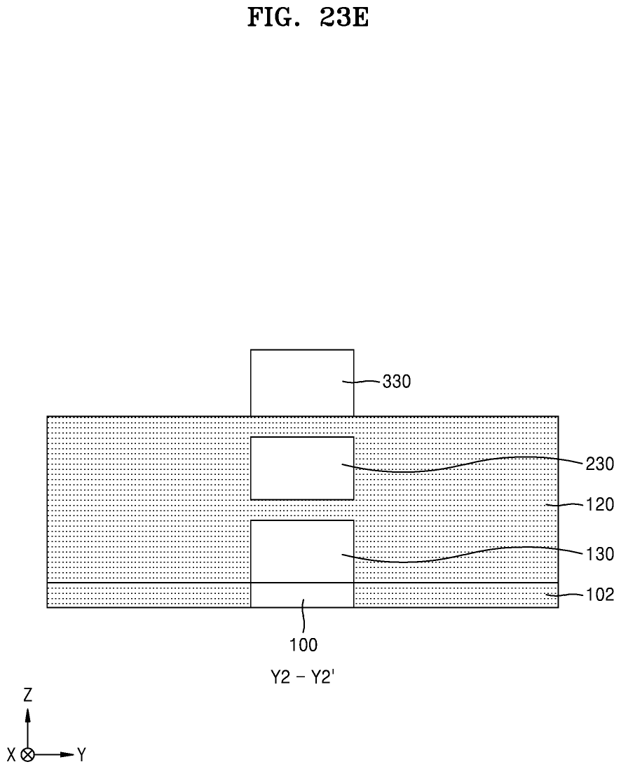

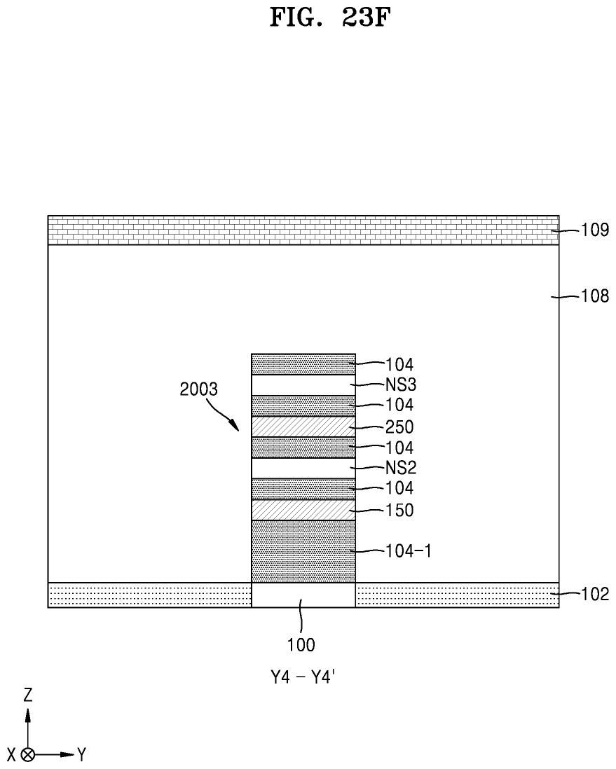

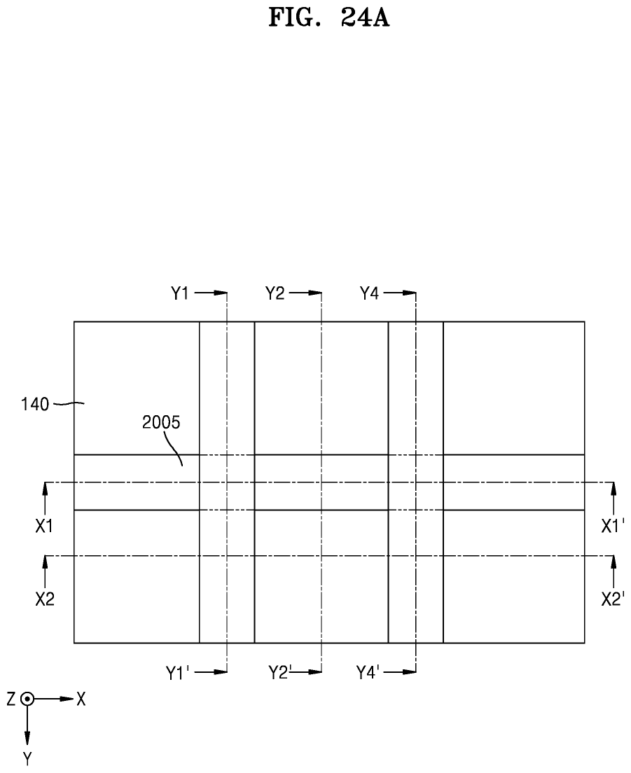

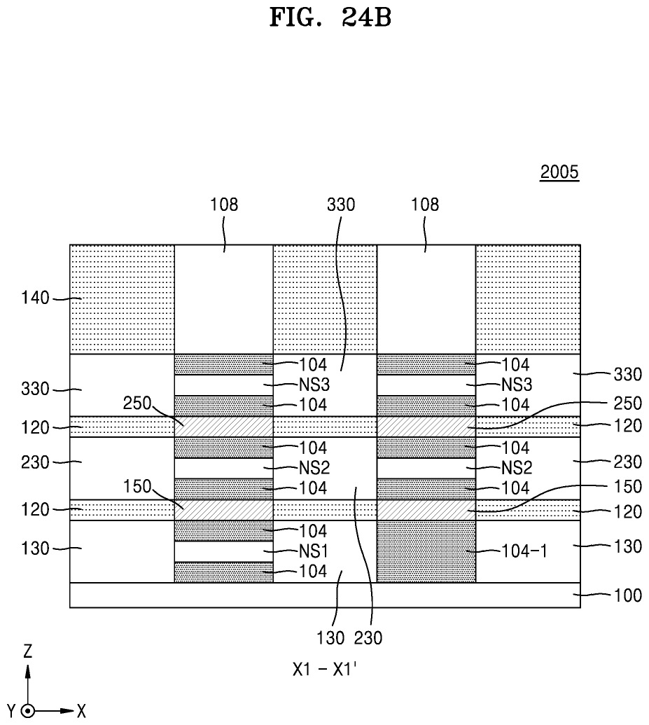

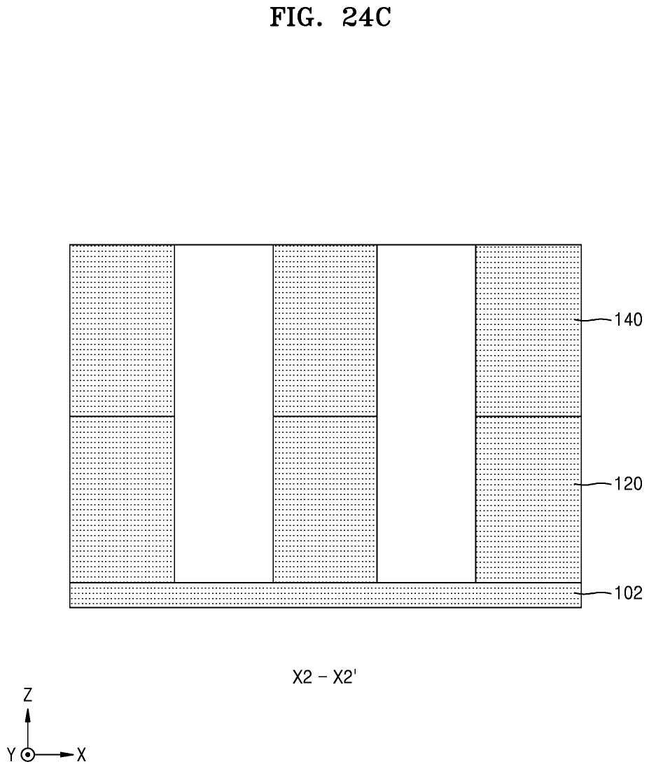

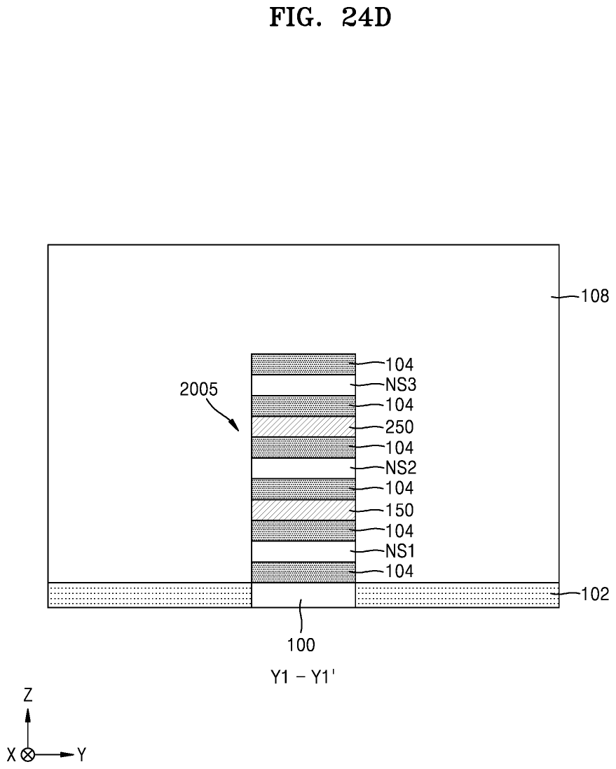

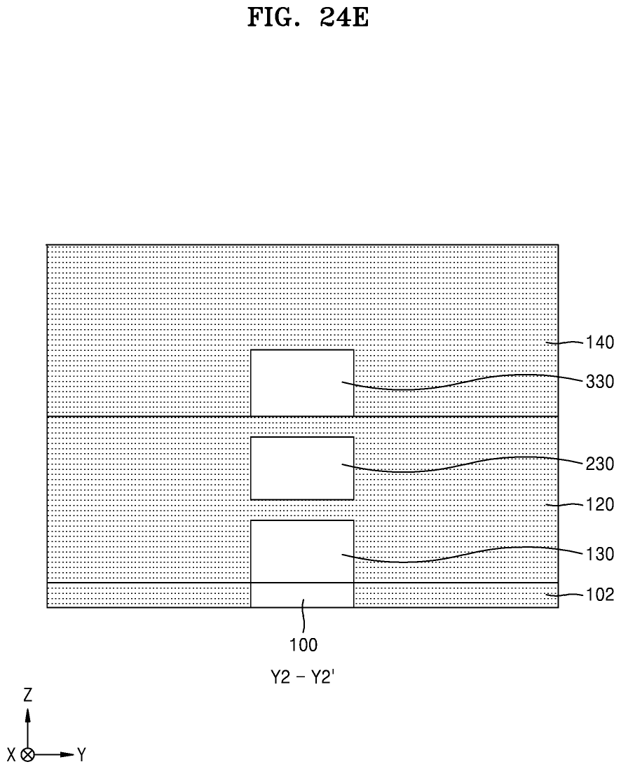

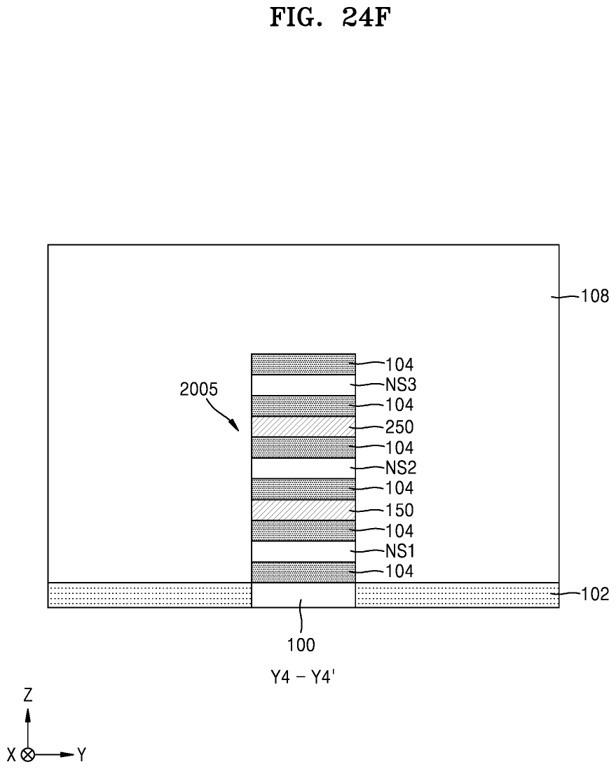

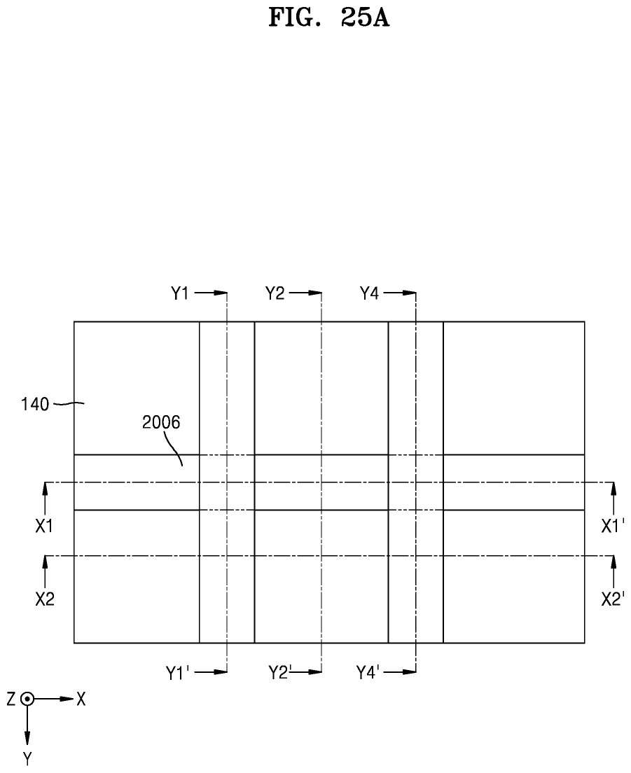

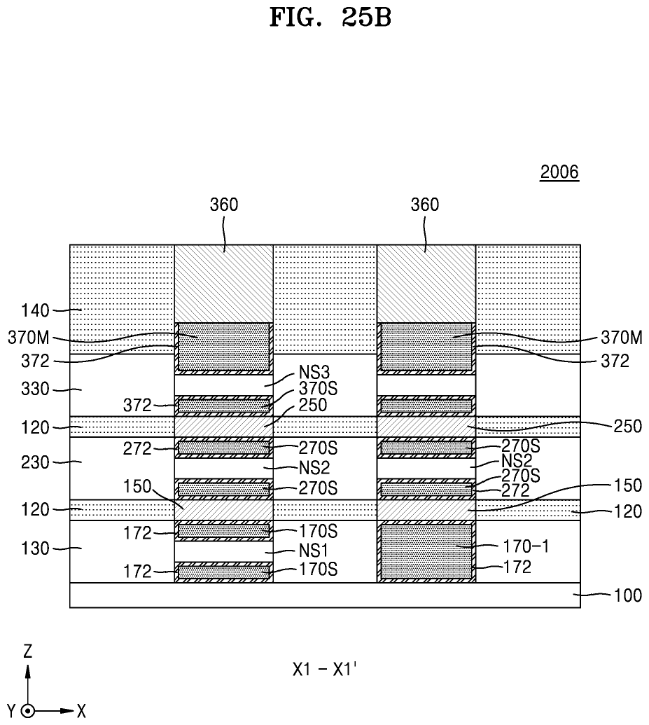

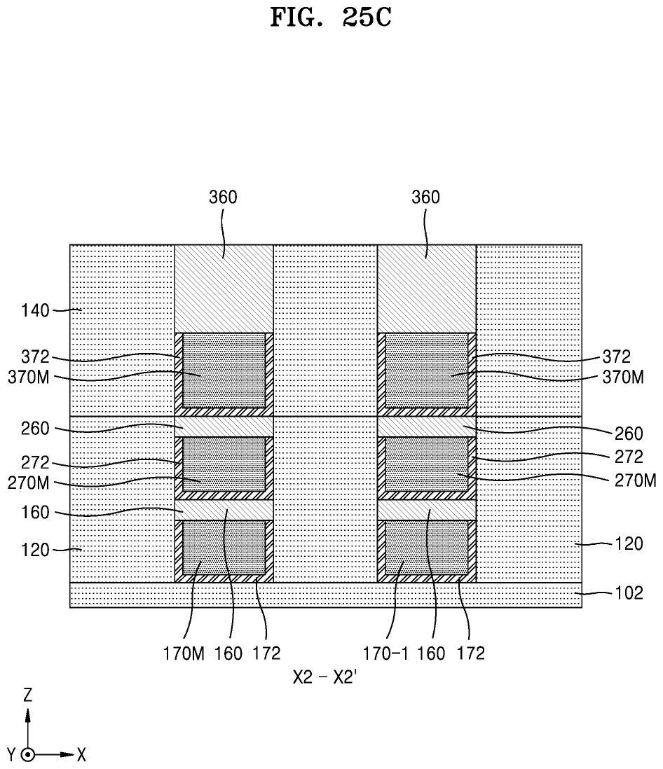

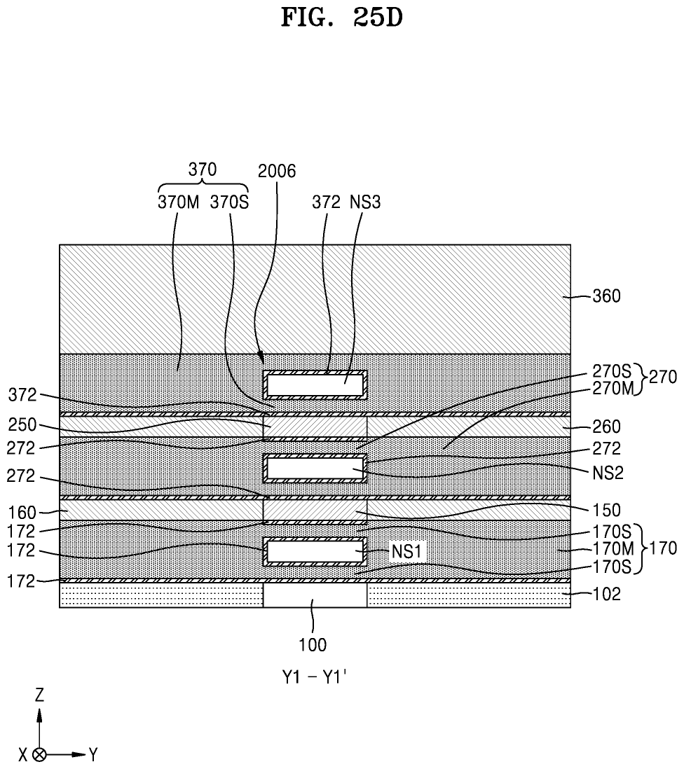

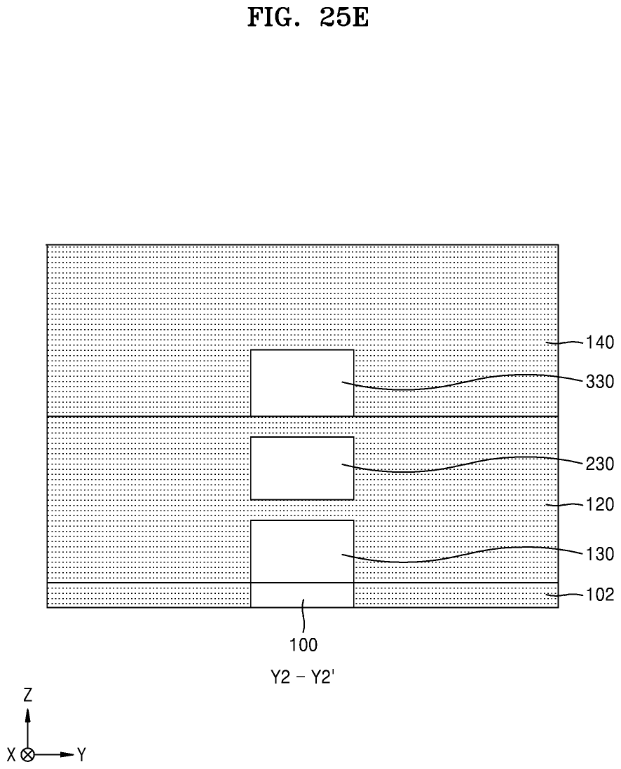

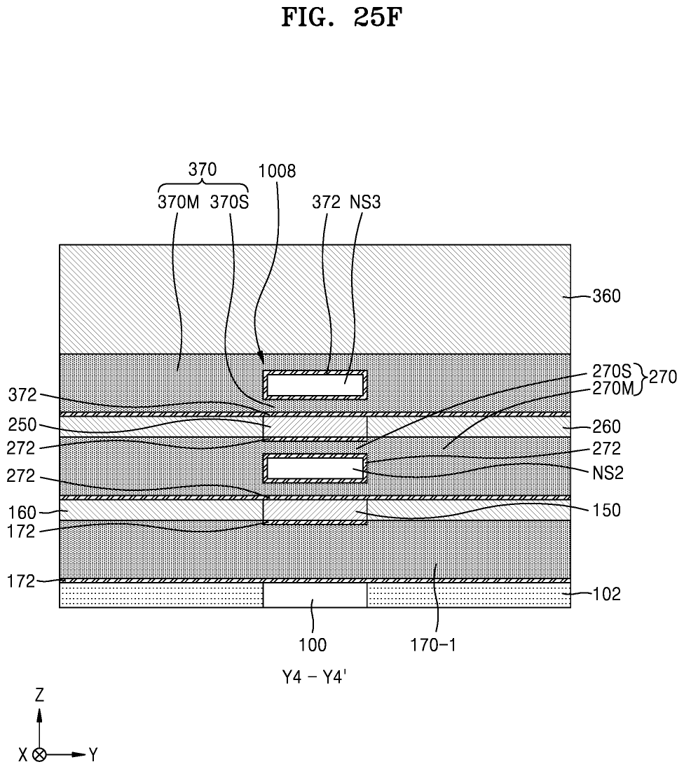

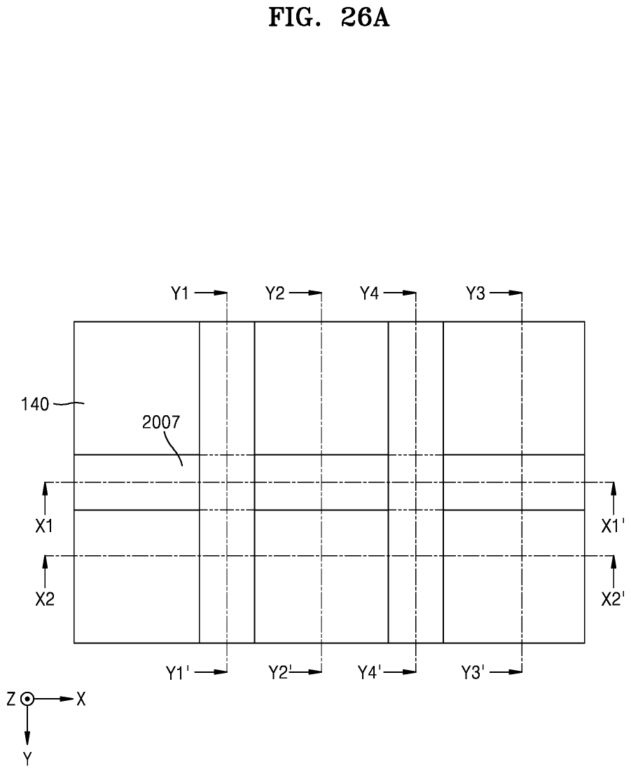

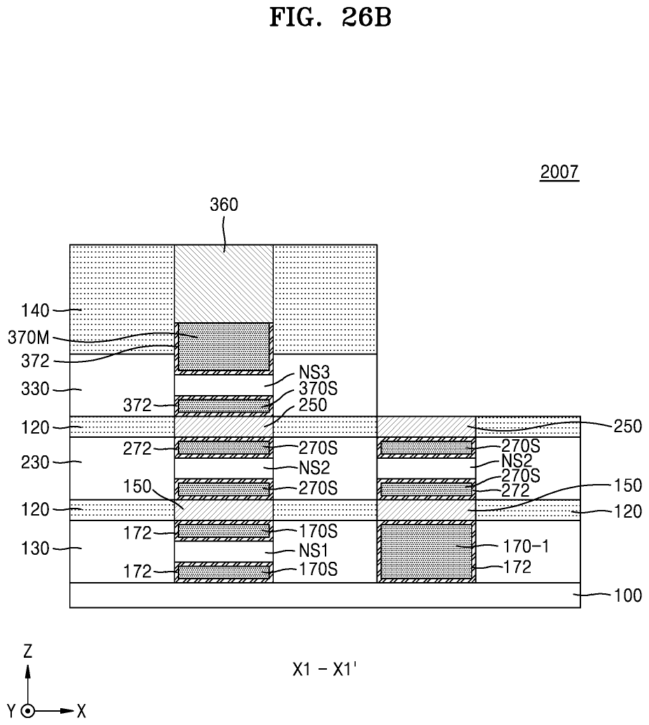

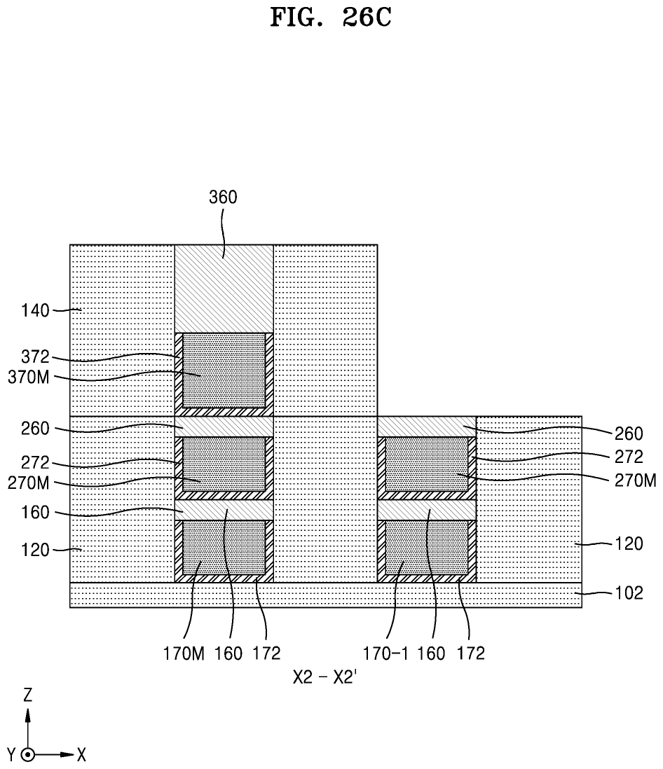

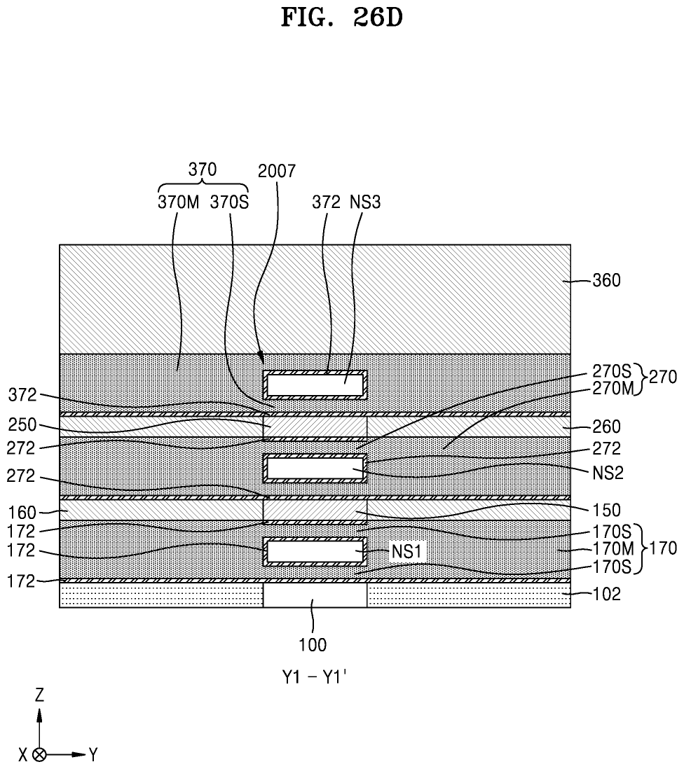

Referring to FIGS. 18A to 18E, a stack structure 1011 in which a first lower source/drain contact 610, a second lower source/drain contact 630, and a first lower gate contact 640 are formed may be provided.

According to one or more embodiments, the first lower source/drain contact 610 may be configured to extend vertically (i.e., in the Z direction) into the device isolation layer 102, the first insulating layer 120, and the second insulating layer 140 to contact at least the side surface of each of the first source/drain area 130, the second source/drain area 230, and the third source/drain area 330. According to some embodiments, the first lower source/drain contact 610 may also contact the lower surface of the first source/drain area 130 by further extending at least partially into the substrate 100.

By passing into the substrate 100, the second lower source/drain contact 630 may be connected to the first source/drain area 130 overlapping the fifth insulating layer 430 in the vertical direction Z. By passing through the device isolation layer 102, the first main gate 170M, and the first main gate insulating layer 160 in the vertical direction Z, the first lower gate contact 640 may be connected to each of the first gate line 170 and the second gate line 270 overlapping the third insulating layer 360 in the vertical direction Z.

FIGS. 19A to 30H are plan views and cross-sectional views for describing intermediate processes in an example method of manufacturing the multi-stack semiconductor device 11 of FIG. 2B. Hereinafter, a method of manufacturing the multi-stack semiconductor device 11 will be described with reference to FIGS. 19A to 30H. Also, redundant descriptions with those given above with reference to FIGS. 1 to 18E will be omitted for conciseness.

First, referring to FIGS. 19A to 19E, a stack structure 2000 formed over the active area AP of the substrate 100 may be provided. The stack structure 2000 may extend in the first horizontal direction X. The stack structure 2000 may include a structure in which a first sacrificial semiconductor layer 104, first to third nanosheet semiconductor layers NS1, NS2, and NS3, and a second sacrificial semiconductor layer 106 are stacked in the vertical direction Z over the active area AP. Because the stack structure 2000 is substantially the same as or similar to the stack structure 1000 described above with reference to FIGS. 7A to 7E, redundant descriptions thereof will be omitted for conciseness.

Referring to FIGS. 20A to 20E, a portion of the stack structure 2000 may be etched from the upper surface of the stack structure 2000 to the first nanosheet semiconductor layer NS1. Substantially half of the first nanosheet semiconductor layer NS1 extending in the first horizontal direction X may be removed by the etching. Thereafter, a first sacrificial semiconductor layer 104-1 may be formed in a portion where the first nanosheet semiconductor layer NS1 has been removed, and a second sacrificial semiconductor layer 106, a first sacrificial semiconductor layer 104, and second and third nanosheet semiconductor layers NS2 and NS3 may be again stacked to provide a stack structure 2001. The first sacrificial semiconductor layer 104-1 may have a greater thickness in the vertical direction Z than the first sacrificial semiconductor layer 104 on upper and lower surfaces of the first nanosheet semiconductor layer NS1.

A portion of the cross-section of the first stack structure 2001 taken along the Y-Z plane may include the first nanosheet semiconductor layer NS1 (see FIG. 20D), and the other portion may not include the first nanosheet semiconductor layer NS1 (see FIG. 20E).

Referring to FIGS. 21A to 21F, a dummy gate 108 and a hard mask 109 extending in the second horizontal direction Y may be formed over the stack structure 2001, and a portion exposed from the hard mask 109 in the vertical direction Z may be etched to the upper surface of the substrate 100 and the device isolation layer 102 to provide a stack structure 2002. The stack structure 2002 may be divided in the first horizontal direction X. According to embodiments, the stack structure 2002 located on the left may include the first nanosheet semiconductor layer NS1, and the stack structure 2002 located on the right may include the first sacrificial semiconductor layer 104-1 without including the first nanosheet semiconductor layer NS1. The dummy gate 108 may cover the upper surface of the stack structure 1001 and both side surfaces of the stack structure 1001 in the second horizontal direction Y.

Referring to FIGS. 22A to 22F, the second sacrificial semiconductor layer 106 may be removed from the stack structure 2002 and replaced with the first sub-gate insulating layer 150 and the second sub-gate insulating layer 250 to form a stack structure 2003.

Referring to FIGS. 23A to 23F, epitaxial growth may be performed from the substrate 100 and the first to third nanosheet semiconductor layers NS1, NS2, and NS3 to form a first source/drain area 130, a second source/drain area 230, and a third source/drain area 330. According to one or more embodiments, after the first source/drain area 130 is formed and a first insulating layer 120 covering the first source/drain area 130 is formed, the second source/drain area 230 may be formed and a first insulating layer 120 covering the second source/drain area 230 may be formed. The first insulating layer 120 may cover the upper surface of each of the first source/drain area 130 and the second source/drain area 230 and opposing side surfaces thereof in the second horizontal direction Y. Thereafter, the third source/drain area 330 may be formed over the upper surface of the first insulating layer 120 covering the upper surface of the second source/drain area 230 to provide a stack structure 2004.

Referring to FIGS. 24A to 24F, the hard mask 109 may be removed from the stack structure 2004 and a second insulating layer 140 surrounding the side surface of the dummy gate 108 in the first horizontal direction X may be formed to provide a stack structure 2005.

Referring to FIGS. 25A to 25F, the dummy gate 108 and the first sacrificial semiconductor layers 104 and 104-1 may be removed from the stack structure 2005 (see FIG. 24B), and a first gate line 170, a second gate line 270, a third gate line 370, and a fourth gate line 170-1 may be sequentially formed. A first gate line 170 may be formed at the position where the first sacrificial semiconductor layer 104 has been removed, and a fourth gate line 170-1 may be formed at the position where the first sacrificial semiconductor layer 104-1 has been removed. Because the fourth gate line 170-1 does not surround the first nanosheet semiconductor layer NS1, it may not be divided into a sub-gate and a main gate. After the first gate line 170 and the fourth gate line 170-1 are formed, the second gate line 270 may be formed and then the third gate line 370 may be formed. After the third gate line 370 is formed, a third insulating layer 360 covering the upper surface of the third gate line 370 may be formed to provide a stack structure 2006.

Referring to FIGS. 26A to 26G, a portion of the stack structure 2006 (see FIG. 25B) may be etched in the vertical direction Z from the upper surface of the stack structure 2006 (see FIG. 25B) to the second sub-gate insulating layer 250 to provide a stack structure 2007. According to one or more embodiments, the stack structure 2007 may include three first source/drain areas 130, three second source/drain areas 230, and two third source/drain areas 330. By the etching, the upper surface of the second sub-gate insulating layer 250 located on the upper surface of the fourth transistor TR4 (see FIG. 2B) among the second sub-gate insulating layers 250 may be exposed upward in the vertical direction Z. The upper surface of the second main gate insulating layer 260 covering the second main gate 270M of the fourth transistor TR4 may be exposed upward in the vertical direction Z.

Referring to FIGS. 27A to 27G, a fourth insulating layer 410 and a fifth insulating layer 430 filling the etched portion of the stack structure 2007 may be formed to provide a stack structure 2008. In some embodiments, only the fifth insulating layer 430 may be formed without the fourth insulating layer 410. According to embodiments, the fifth insulating layer 430 may overlap the third nanosheet semiconductor layer NS3 in the first horizontal direction X.

Referring to FIGS. 28A to 28G, a stack structure 2009 in which a first upper source/drain contact 511, a first upper gate contact 520, a second upper gate contact 531, and a second upper source/drain contact 540 are formed may be provided. The first upper source/drain contact 511 may be formed to pass through the second insulating layer 140 in the vertical direction Z. The first upper source/drain contact 511 may contact the third source/drain area 330.

The first upper gate contact 520 may contact the third gate line 370 by extending into the third insulating layer 360 in the vertical direction Z, and the second upper gate contact 531 may contact the second gate line 270 by extending into the fourth insulating layer 410 and the fifth insulating layer 430 in the vertical direction Z. In this case, the second upper gate contact 531 may contact the second gate line 270 by further extending into any one of the second sub-gate insulating layer 250 and the second main gate insulating layer 260 in the vertical direction Z.

Referring to FIGS. 29A to 29H, a stack structure 2010 in which a first lower source/drain contact 610, a third lower source/drain contact 620, and a first lower gate contact 640 are formed may be provided. The third lower source/drain contact 620 may be connected to the first source/drain area 130 through the substrate 100 and the device isolation layer 102. In this case, the first source/drain area 130 connected to the third lower source/drain contact 620 may be the first source/drain area 130 located between the first gate line 170 and the fourth gate line 170-1.

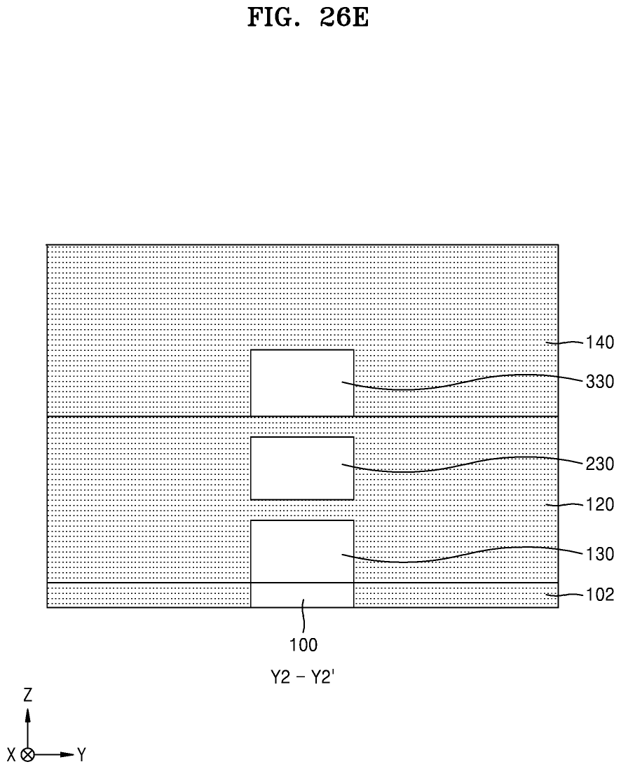

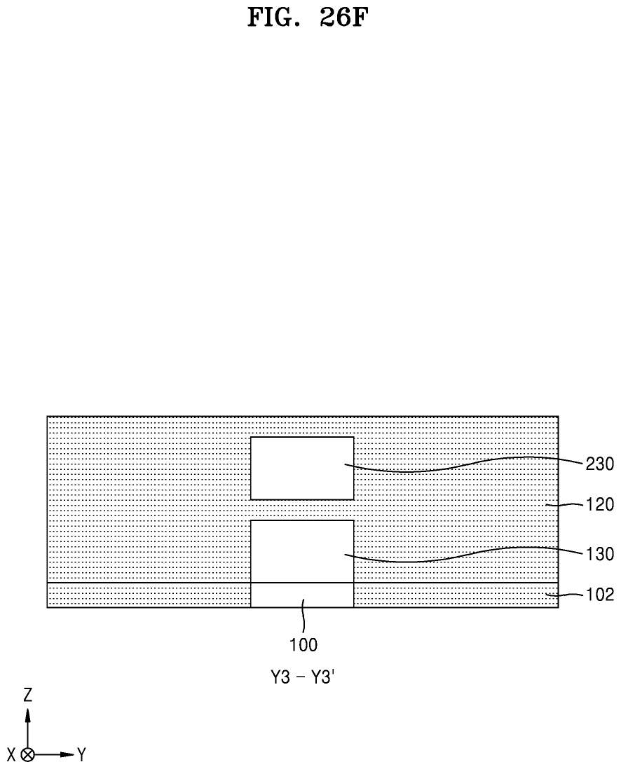

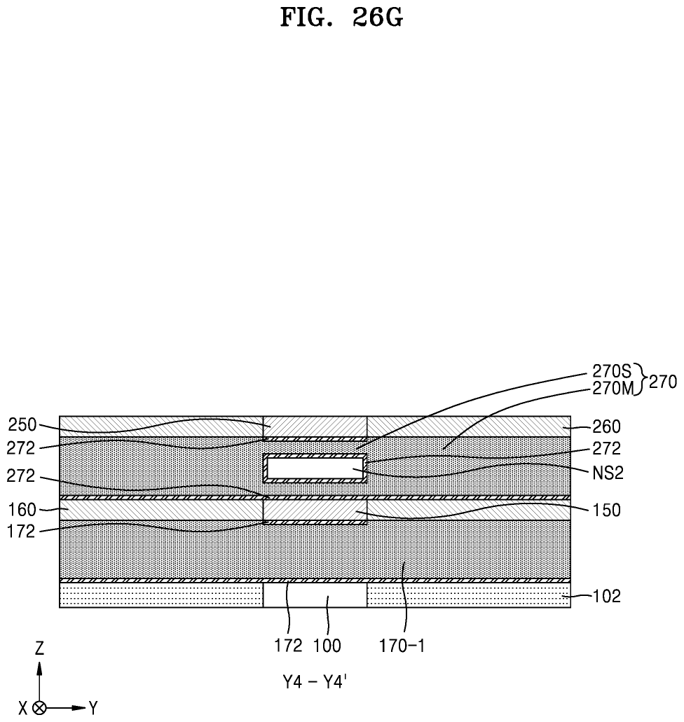

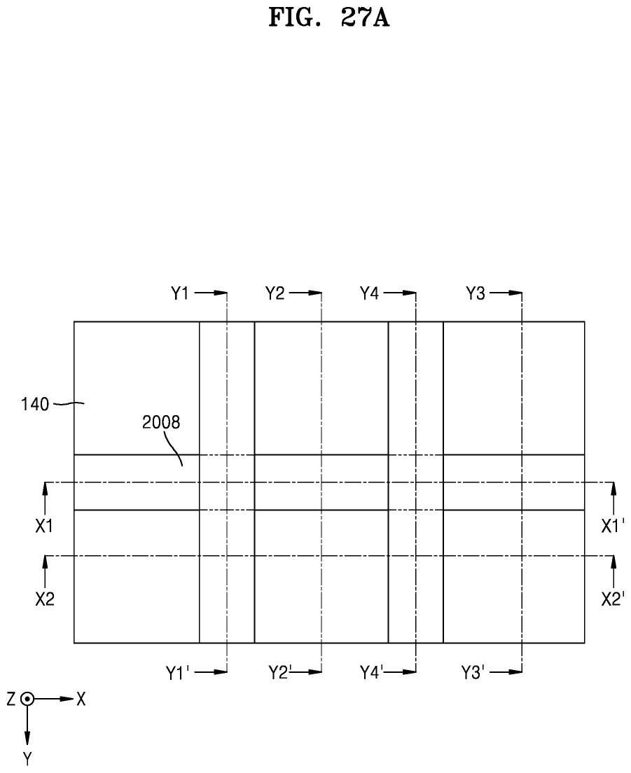

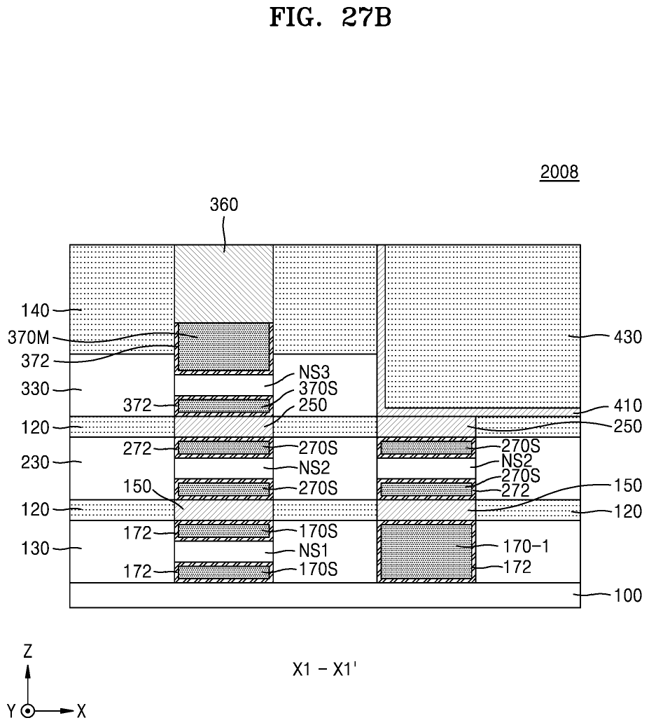

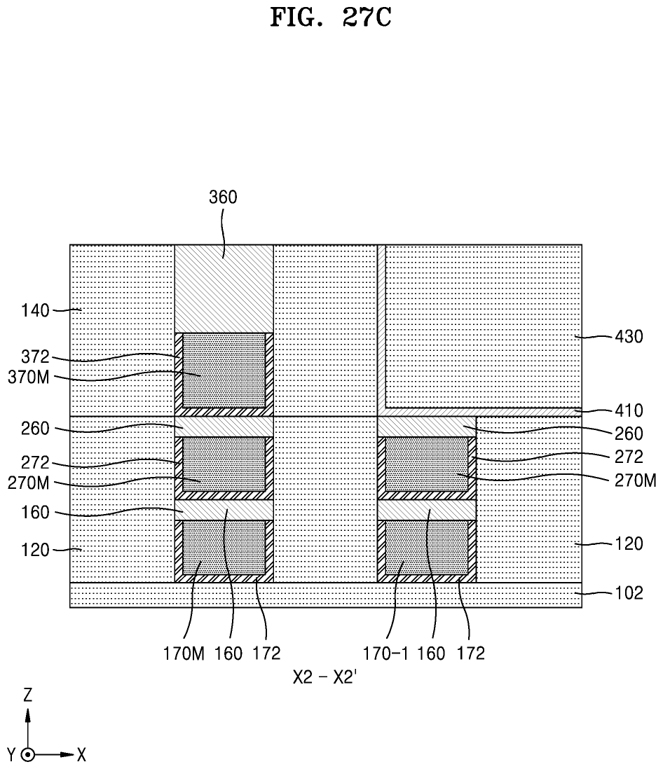

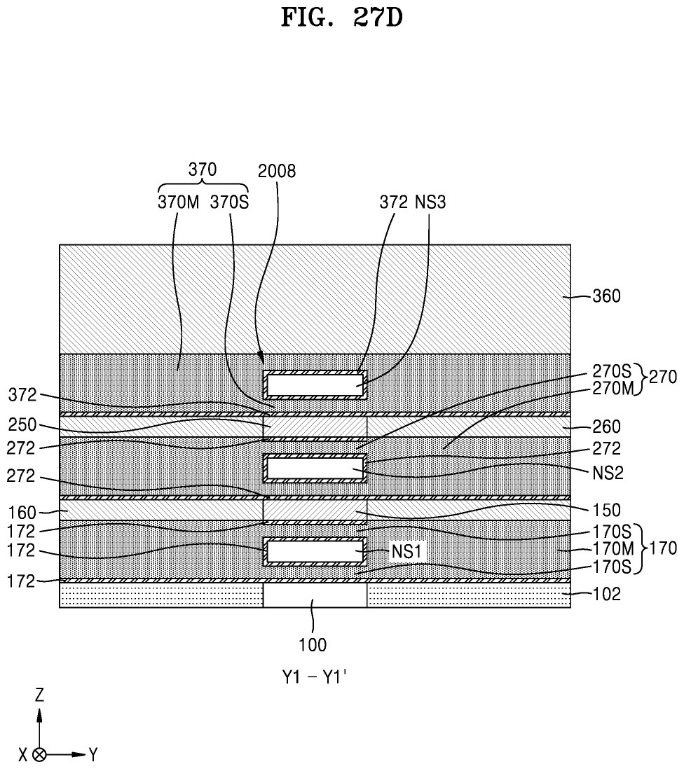

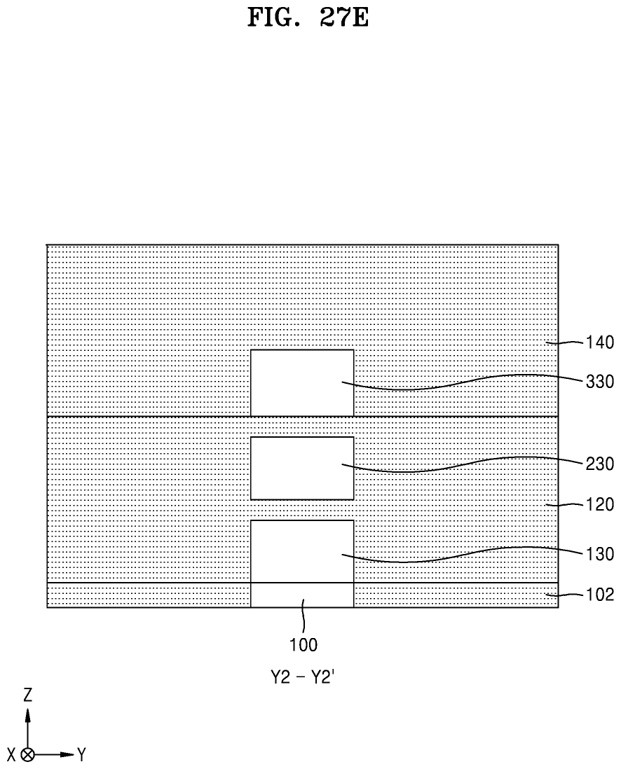

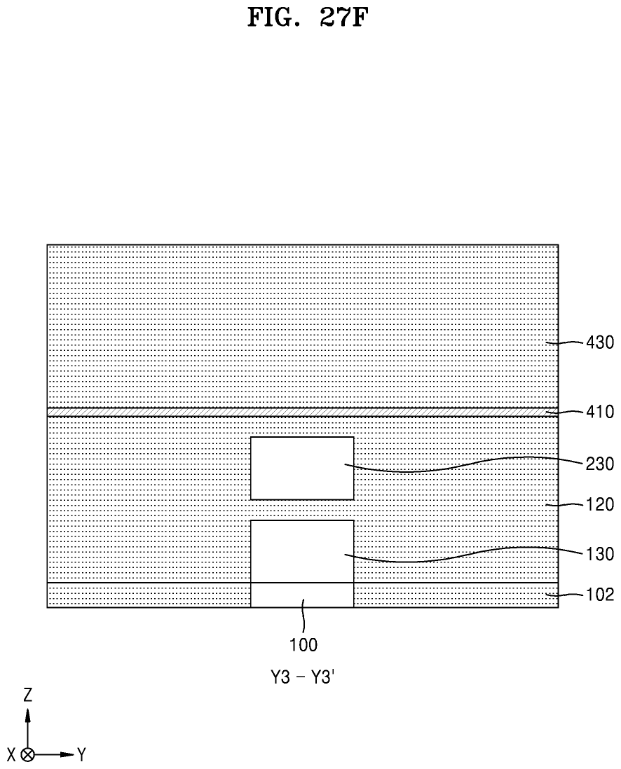

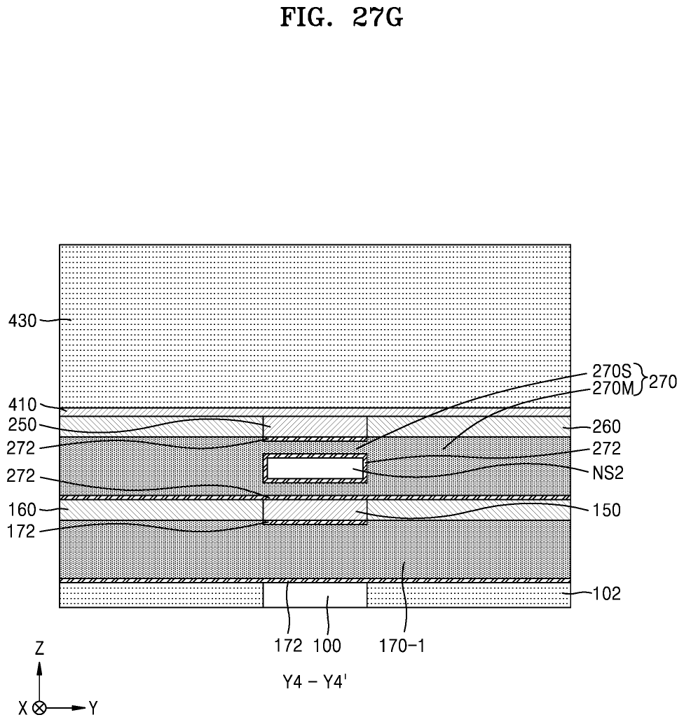

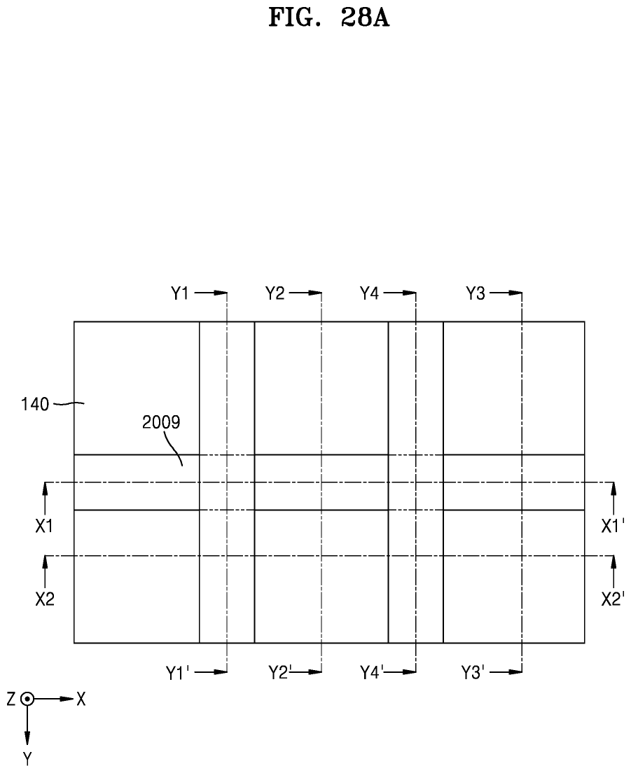

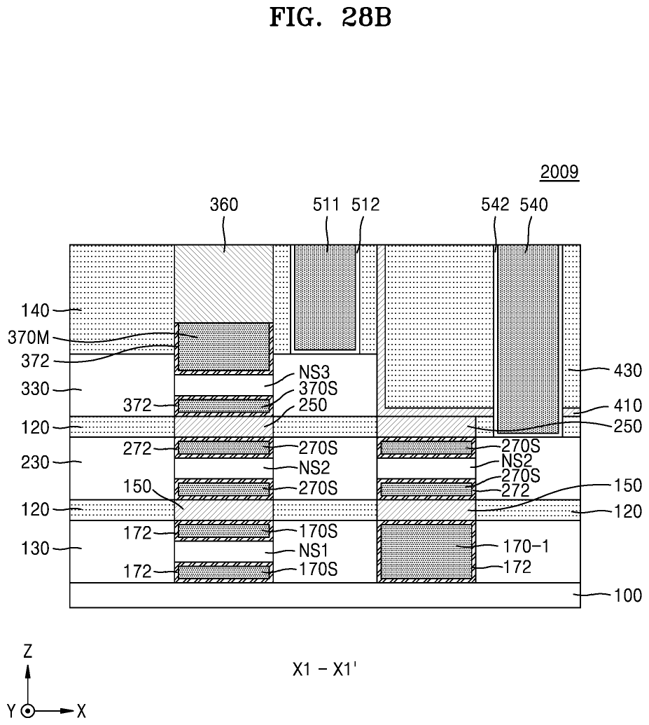

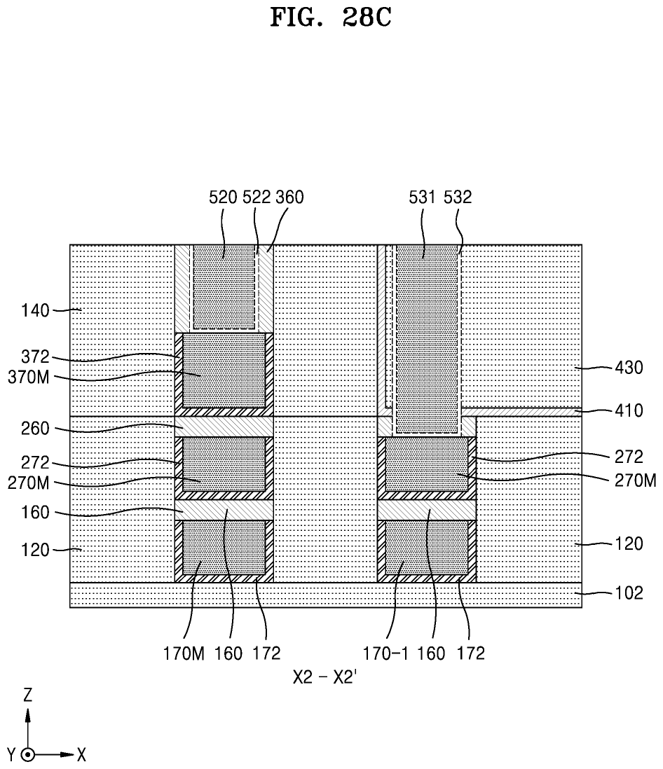

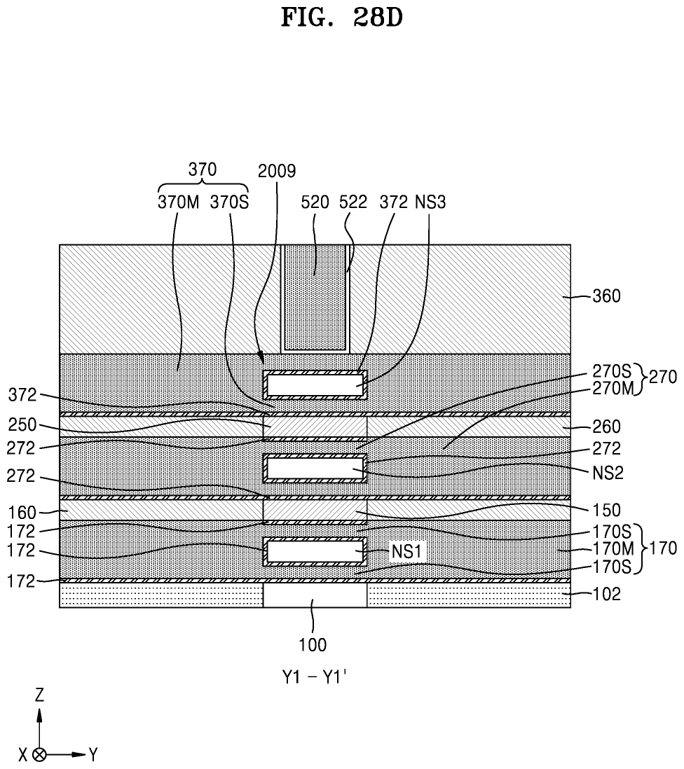

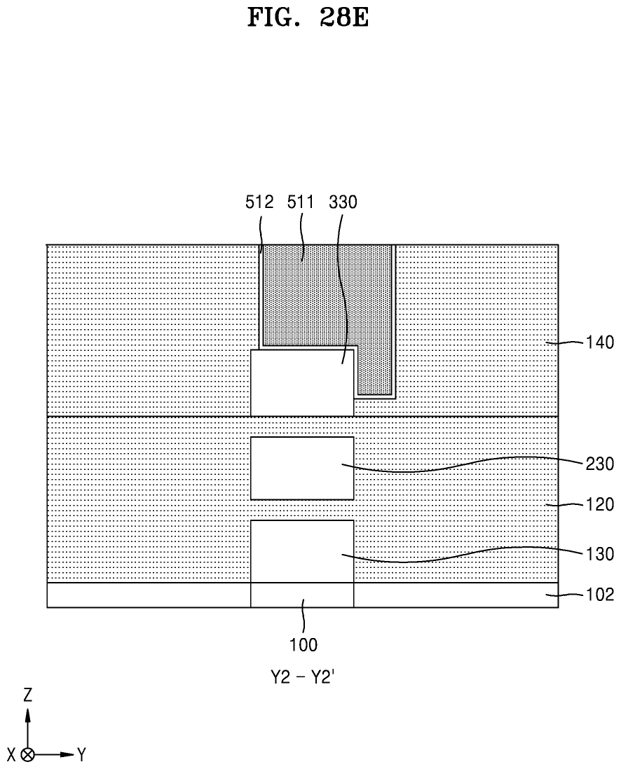

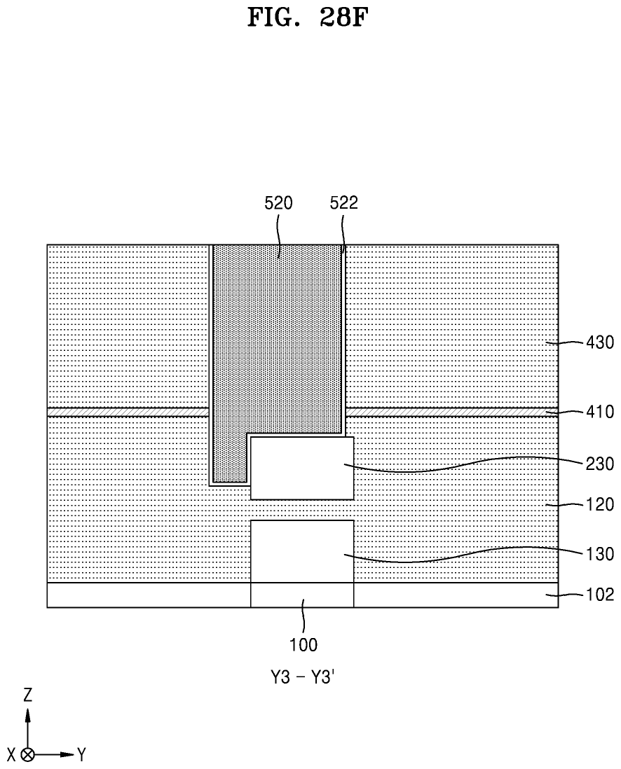

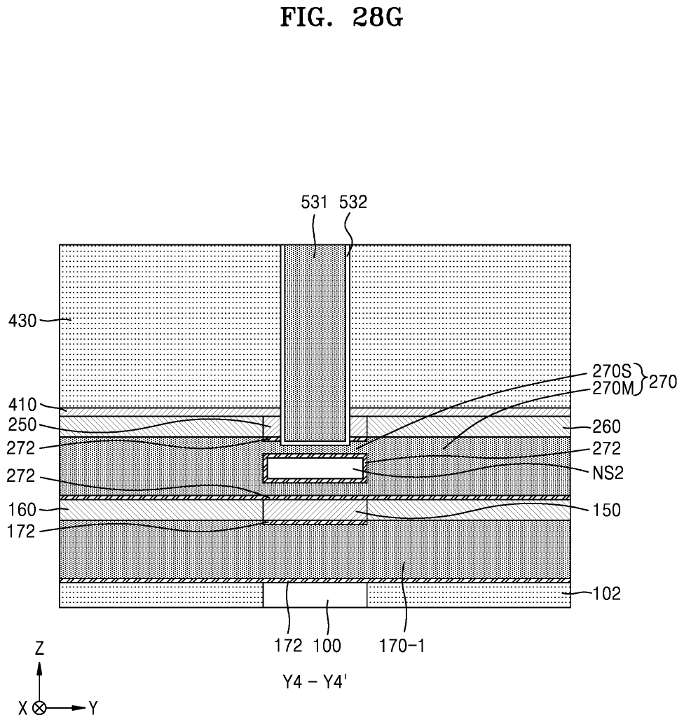

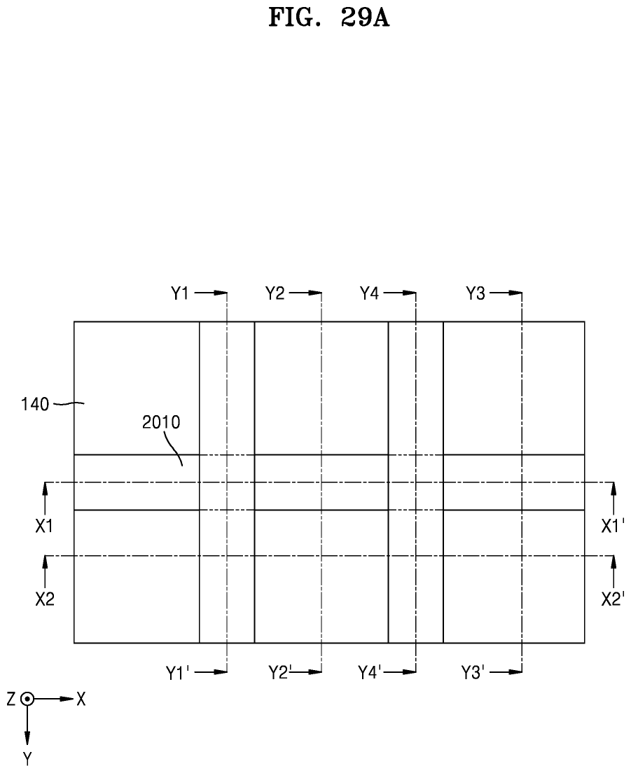

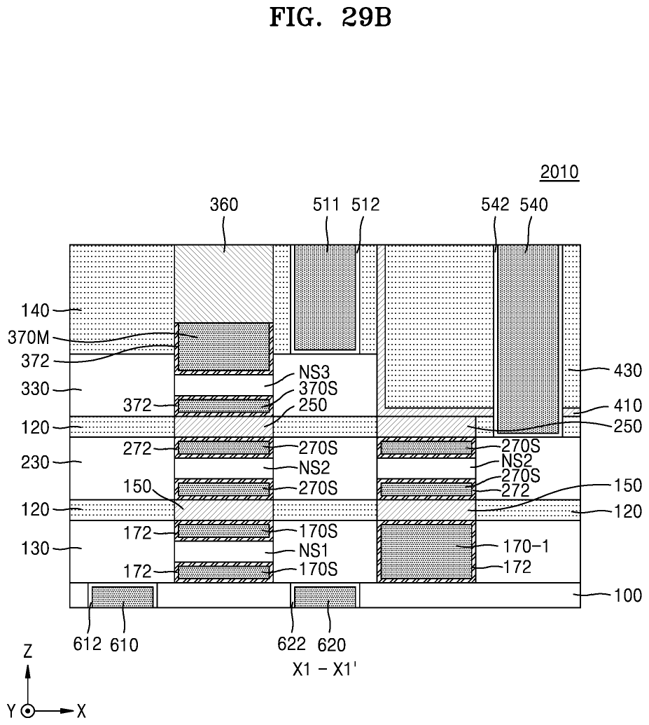

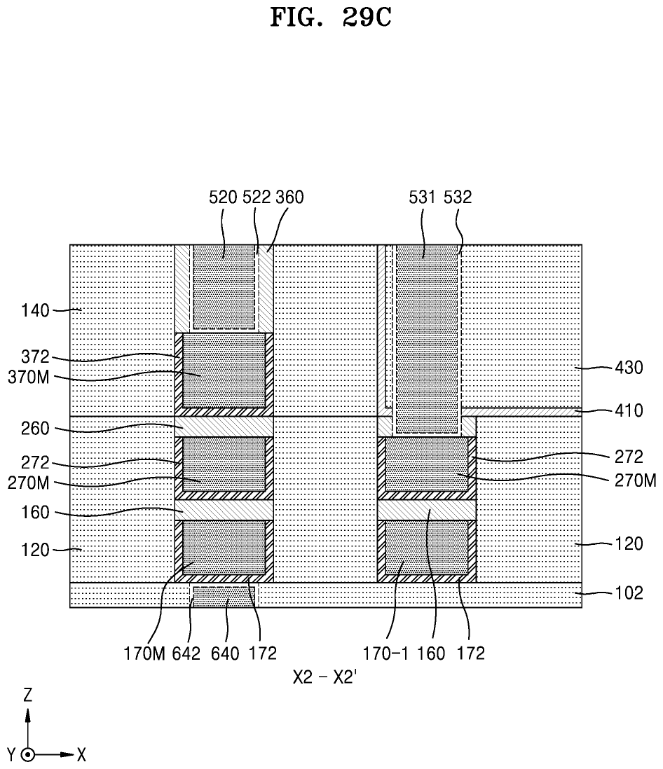

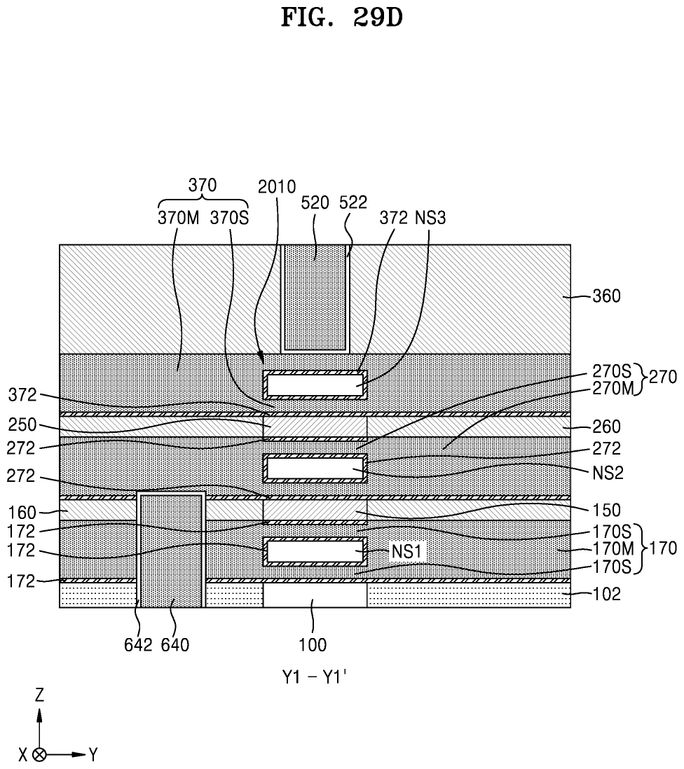

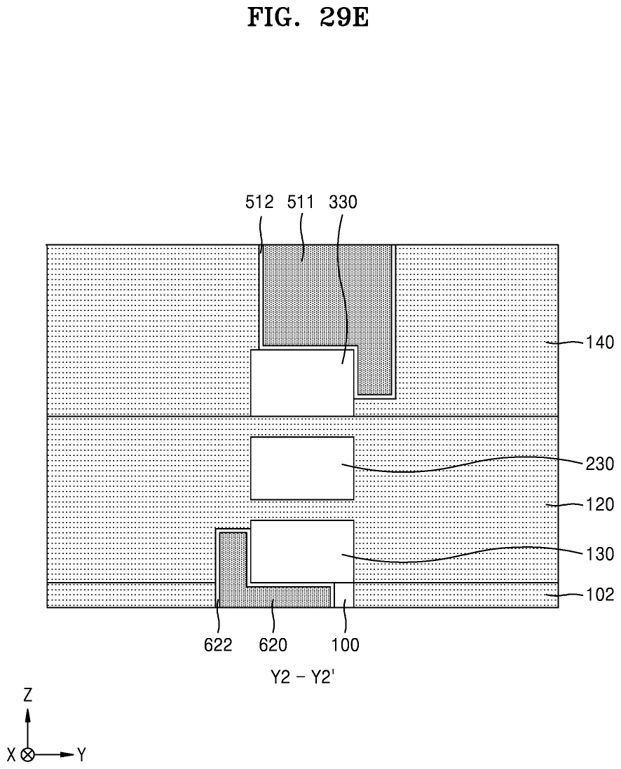

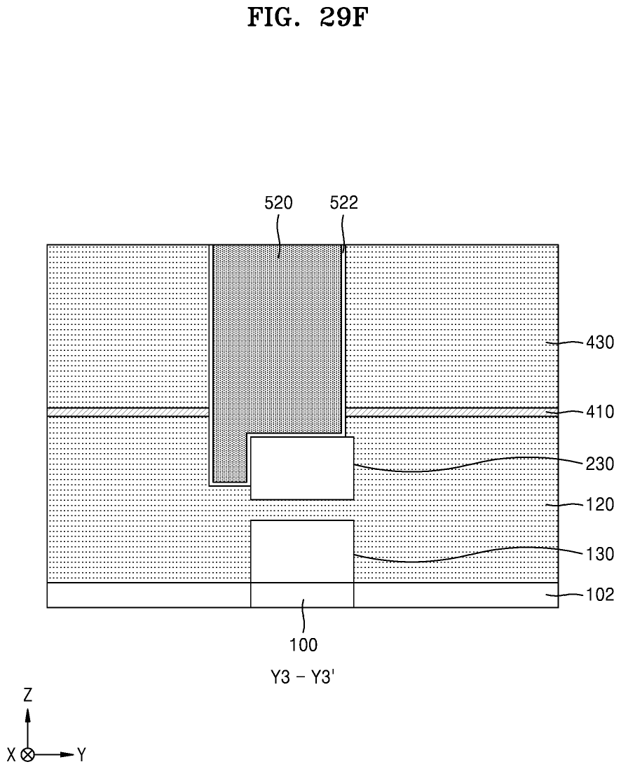

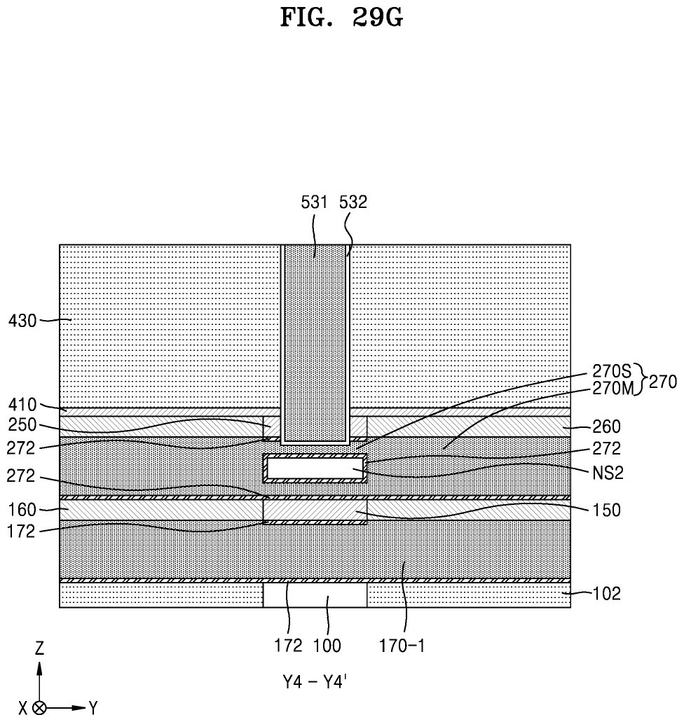

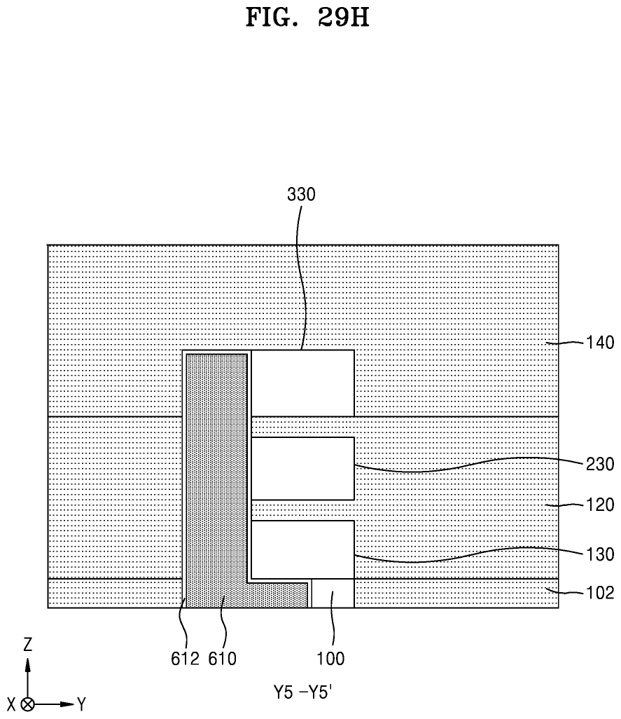

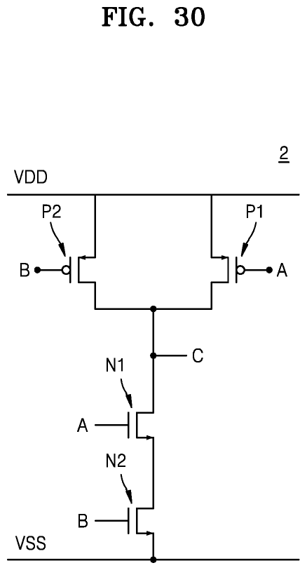

Referring to FIG. 30, a NAND circuit 2 may include first and second PMOSFETs P1 and P2 connected in parallel with each other and first and second NMOSFETs N1 and N2 connected in series with each other, and the first and second PMOSFETs P1 and P2 may be connected in series with the first NMOSFET N1. An output node may be located between the first NMOSFET N1 and the first and second PMOSFETs P1 and P2. The first and second PMOSFETs P1 and P2 may be connected in parallel to each other between the output node and a supply voltage terminal for providing the first power VDD, and the first and second NMOSFETs N1 and N2 may be connected in series with each other between the output node and a ground voltage terminal for providing the second power VSS. In the NAND circuit 2, each of the first PMOSFET P1 and the first NMOSFET N1 may receive a first signal A through a gate thereof, each of the second PMOSFET P2 and the second NMOSFET N2 may receive a second signal B through a gate thereof, and a third signal C may be output from the output node.

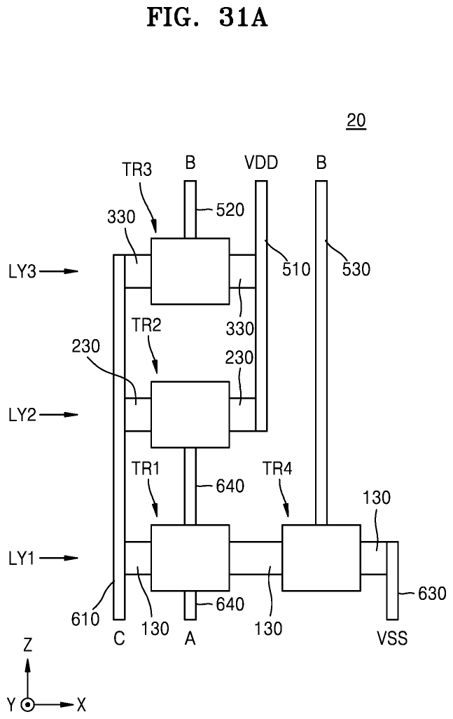

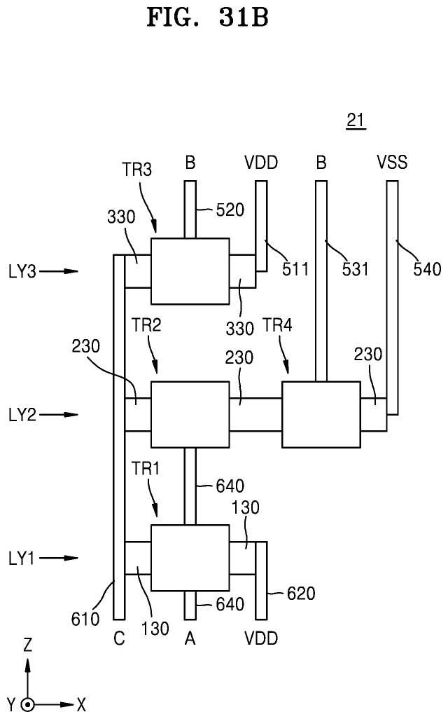

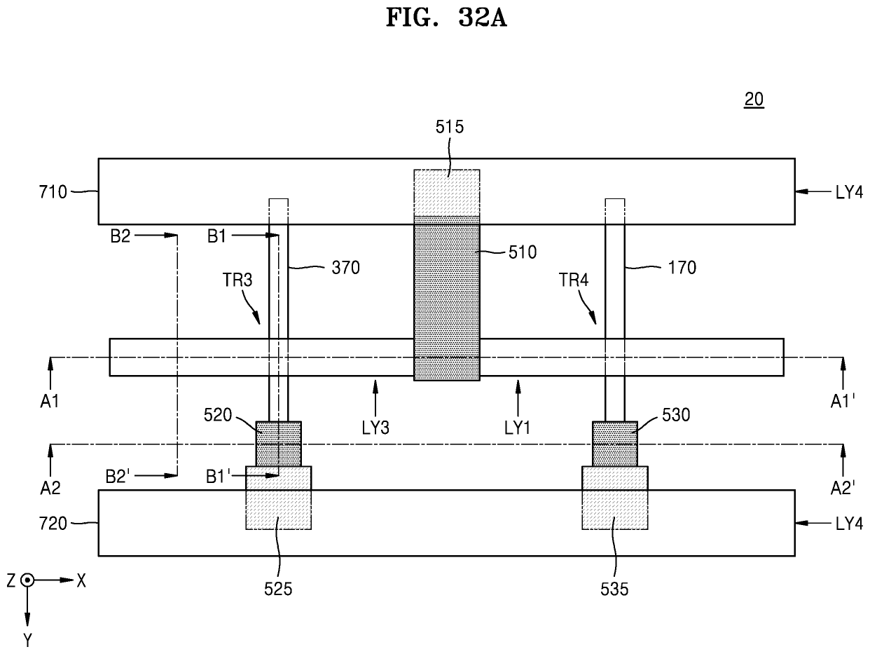

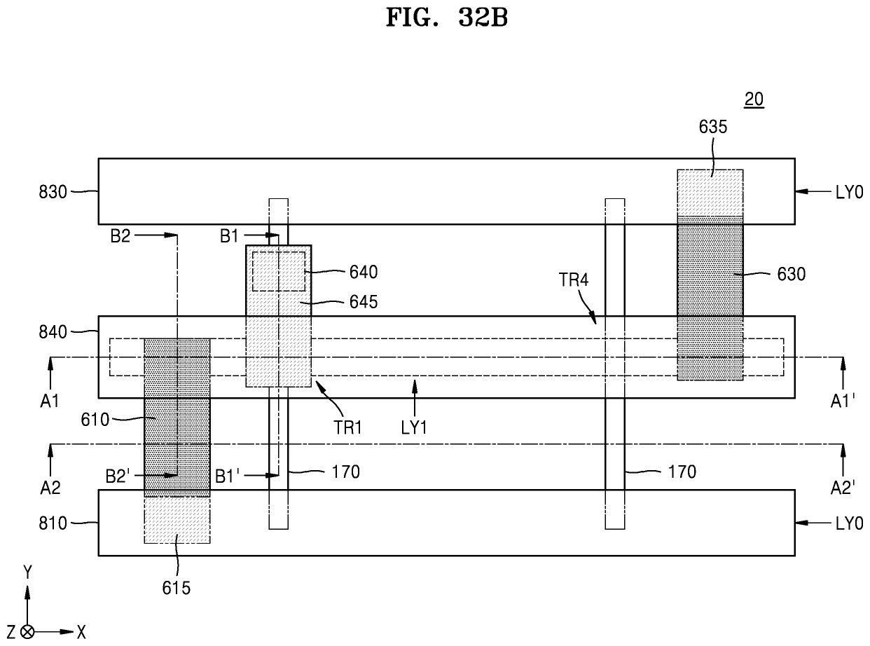

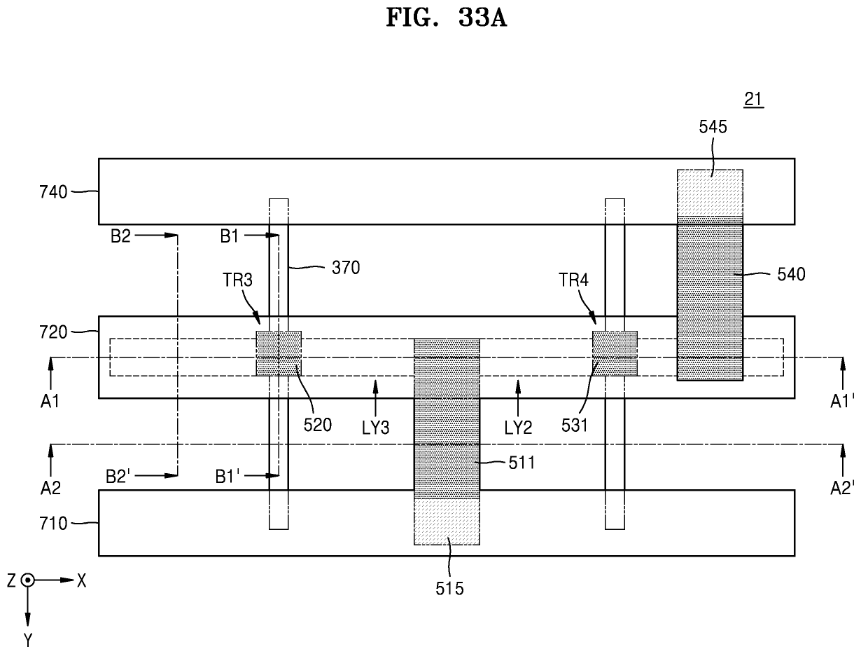

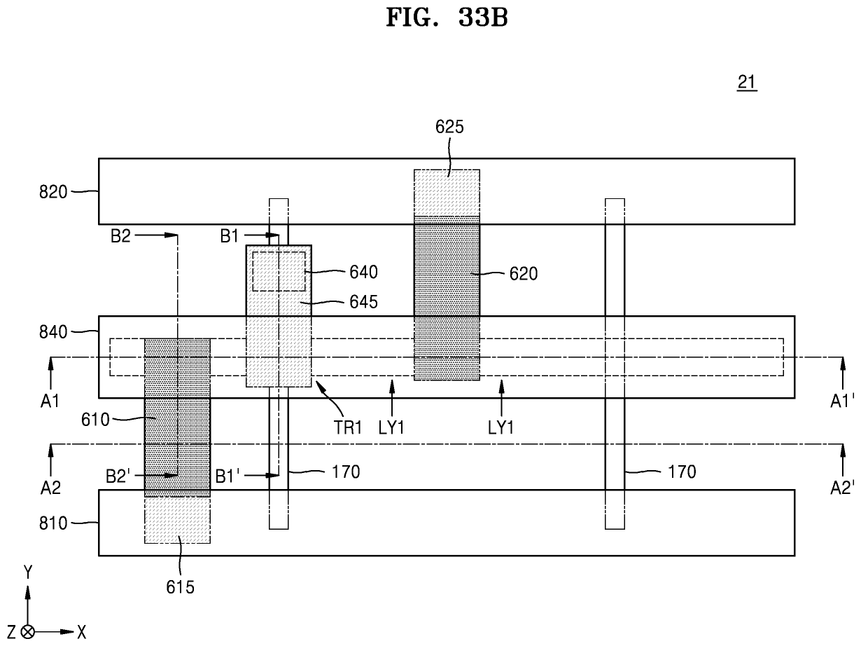

FIGS. 31A and 31B are schematic diagrams illustrating multi-stack semiconductor devices according to the inventive concept for implementing the NAND circuit 2 of FIG. 30. FIGS. 32A and 32B are plan views depicting layout diagrams for describing the multi-stack semiconductor device of FIG. 31A. FIGS. 33A and 33B are plan views depicting layout diagrams for describing the multi-stack semiconductor device of FIG. 31B. Hereinafter, redundant descriptions with those given above with reference to FIGS. 1 and 29H will be omitted and differences therebetween will be mainly described.

Referring to FIGS. 31A to 33B, multi-stack semiconductor devices 20 and 21 implementing the NAND circuit 2 may have substantially the same structure as the multi-stack semiconductor devices 10 and 11 implementing the NOR circuit 1; however, in the multi-stack semiconductor devices 20 and 21, the first power VDD may be provided from the first upper source/drain contact 510 (FIG. 31A) or the first upper source/drain contact 511 (FIG. 31B), the second power VSS may be provided from the second upper source/drain contact 540 (FIG. 31B), and the second signal B may be provided from the first upper gate contact 520 (FIGS. 31A and 31B) and the second upper gate contact 530 (FIG. 31A) or the second upper gate contact 531 (FIG. 31B). Also, the second power VSS may be provided from the second lower source/drain contact 630, the first power VDD may be provided from the third lower source/drain contact 620, and the first signal A may be provided from the first lower gate contact 640.

Also, the first upper signal line 710 of the multi-stack semiconductor device 20 may be configured to provide the first power VDD to the first upper source/drain contact 510, and the second upper signal line 720 may be configured to provide the second signal B to each of the first upper gate contact 520 and the second upper gate contact 530. The second lower signal line 830 may be configured to provide the second power VSS to the second lower source/drain contact 630, and the third lower signal line 840 may be configured to provide the first signal A to the first lower gate contact 640.

The third upper signal line 740 of the multi-stack semiconductor device 21 may be configured to provide the second power VSS to the second upper source/drain contact 540, and the second lower signal line 820 may be configured to provide the first power VDD to the third lower source/drain contact 620.

While the inventive concept has been particularly shown and described with reference to embodiments thereof, it will be understood that various changes in form and details may be made therein without departing from the spirit and scope of the following claims.

What is claimed is:

1. A multi-stack semiconductor device, comprising:
a substrate;
a device isolation layer defining an active area of the substrate;
first channels over the active area in a vertical direction perpendicular to an upper surface of the substrate and spaced apart from each other in a first horizontal direction parallel to the upper surface of the substrate;
first gate lines on the respective first channels, each of the first gate lines extending in a second horizontal direction intersecting the first horizontal direction, and spaced apart from each other in the first horizontal direction;
first source/drain areas on opposing sides of each of the first channels in the first horizontal direction;
a second channel over and spaced apart from any one of the first gate lines in the vertical direction;
a second gate line on the second channel and extending in the second horizontal direction;
second source/drain areas on opposing sides of the second channel in the first horizontal direction;
a third channel over and spaced apart from the second gate line in the vertical direction;
a third gate line on the third channel and extending in the second horizontal direction;
third source/drain areas on opposing sides of the third channel in the first horizontal direction; and
a first lower source/drain contact extending in the vertical direction and electrically connected to a given one of the first source/drain areas, a given one of the second source/drain areas, and a given one of the third source/drain areas.

2. The multi-stack semiconductor device of claim 1, wherein
each of the first gate lines comprises a first sub-gate and a first main gate,
a first sub-gate insulating layer is on an upper surface of the first sub-gate and a first main gate insulating layer is on an upper surface of the first main gate, and
the second gate line comprises a second sub-gate and a second main gate, a second sub-gate insulating layer is on an upper surface of the second sub-gate, and a second main gate insulating layer is on an upper surface of the second main gate.

3. The multi-stack semiconductor device of claim 2, wherein a first insulating layer is on an upper surface of each of the first source/drain areas and the second source/drain areas.

4. The multi-stack semiconductor device of claim 3, wherein
one of the first gate lines not overlapping the second gate line in the vertical direction is spaced apart from a fifth insulating layer in the vertical direction with the first sub-gate insulating layer therebetween, and
the fifth insulating layer at least partially overlaps each of the second gate line and the third gate line in the first horizontal direction.

5. The multi-stack semiconductor device of claim 1, further comprising:
a first upper gate contact electrically connected to the third gate line;
a second upper gate contact electrically connected to a first one of the first gate lines not overlapping the second gate line in the vertical direction;
a first lower gate contact electrically connected to a second one of the first gate lines overlapping the second gate line in the vertical direction;
a first upper source/drain contact electrically connected to each of the second source/drain areas and the third source/drain areas; and
a second lower source/drain contact electrically connected to one of the first source/drain areas on a side of the second upper gate contact in the first horizontal direction.

6. The multi-stack semiconductor device of claim 5, further comprising:
a first upper signal line electrically connected to the first upper source/drain contact;
a second upper signal line electrically connected to the first upper gate contact and the second upper gate contact;
a first lower signal line electrically connected to the first lower source/drain contact;
a second lower signal line electrically connected to the second lower source/drain contact; and
a third lower signal line electrically connected to the first lower gate contact.

7. The multi-stack semiconductor device of claim 6, wherein
the second lower signal line is configured to provide first power to the second lower source/drain contact,
the first upper signal line is configured to provide second power to the first upper source/drain contact,
the second upper signal line is configured to provide a first signal to each of the first upper gate contact and the second upper gate contact, and
the third lower signal line is configured to provide a second signal to the first lower gate contact.

8. The multi-stack semiconductor device of claim 6, wherein
the first upper signal line is configured to provide first power to the first upper source/drain contact,
the second lower signal line is configured to provide second power to the second lower source/drain contact,
the second upper signal line is configured to provide a second signal to each of the first upper gate contact and the second upper gate contact, and
the third lower signal line is configured to provide a first signal to the first lower gate contact.

9. The multi-stack semiconductor device of claim 1, wherein a subset of the first gate lines spaced apart from each other in the first horizontal direction share a corresponding one of the first source/drain areas between the subset of the first gate lines.

10. The multi-stack semiconductor device of claim 1, wherein
one of the first channels that does not overlap the second gate line in the vertical direction is free of another channel thereon.

11. A multi-stack semiconductor device, comprising:
a substrate;
a device isolation layer defining an active area of the substrate;
a first channel spaced apart from the active area in a vertical direction perpendicular to an upper surface of the substrate;
a first gate line on the first channel and extending in a second horizontal direction parallel to the upper surface of the substrate;
a fourth gate line spaced apart from the first gate line in a first horizontal direction intersecting the second horizontal direction and extending in the second horizontal direction;
first source/drain areas arranged on opposing sides of the first channel in the first horizontal direction;
second channels, a first one of the second channels over and spaced apart from the first gate line in the vertical direction, and a second one of the second channels over and spaced apart from the fourth gate line in the vertical direction;
second gate lines on the respective second channels, extending in the second horizontal direction, and spaced apart from each other in the first horizontal direction;
second source/drain areas on opposing sides of each of the second channels in the first horizontal direction;
a third channel over a given one of the second gate lines at least partially overlapping the first channel in the vertical direction;
a third gate line on the third channel and extending in the second horizontal direction;
third source/drain areas on opposing sides of the third channel in the first horizontal direction; and
a first lower source/drain contact extending in the vertical direction and electrically connected to a given one of the first source/drain areas, a given one of the second source/drain areas, and a given one of the third source/drain areas.

12. The multi-stack semiconductor device of claim 11, wherein
the first gate line comprises a first sub-gate and a first main gate,
a first sub-gate insulating layer is on an upper surface of the first sub-gate and a first main gate insulating layer is on an upper surface of the first main gate,
the first sub-gate insulating layer and the first main gate insulating layer are on an upper surface of the fourth gate line, and
each of the second gate lines comprises a second sub-gate and a second main gate, a second sub-gate insulating layer is on an upper surface of the second sub-gate, a second main gate insulating layer is on an upper surface of the second main gate, and a first insulating layer is on an upper surface of each of the first source/drain areas and the second source/drain areas.

13. The multi-stack semiconductor device of claim 11, further comprising:
a first upper gate contact electrically connected to the third gate line;
a second upper gate contact electrically connected to one of the second gate lines not overlapping the first gate line in the vertical direction;
a first lower gate contact electrically connected to the first gate line;
a first upper source/drain contact electrically connected to one of the third source/drain areas;
a second upper source/drain contact electrically connected to one of the second source/drain areas on a side of the second upper gate contact in the first horizontal direction; and
a third lower source/drain contact electrically connected to one of the first source/drain areas.

14. The multi-stack semiconductor device of claim 13, further comprising:
a first upper signal line electrically connected to the first upper source/drain contact;
a second upper signal line electrically connected to the first upper gate contact and the second upper gate contact;
a third upper signal line electrically connected to the second upper source/drain contact;
a first lower signal line electrically connected to the first lower source/drain contact;
a second lower signal line electrically connected to the third lower source/drain contact; and
a third lower signal line electrically connected to the first lower gate contact.

15. The multi-stack semiconductor device of claim 11, wherein a subset of the second gate lines spaced apart from each other in the first horizontal direction share a corresponding one of the second source/drain areas arranged between the subset of the second gate lines.

16. The multi-stack semiconductor device of claim 11, wherein
a fifth insulating layer is over one of the second gate lines at least partially overlapping the fourth gate line in the vertical direction, and
the fifth insulating layer at least partially overlaps the third gate line in the first horizontal direction and does not overlap one of the second gate lines over the first gate line, in the first horizontal direction.

17. The multi-stack semiconductor device of claim 11, wherein
one of the second channels that does not overlap the fourth gate line in the vertical direction is free of another channel thereon.

18. A multi-stack semiconductor device, comprising:
a substrate;
a device isolation layer defining an active area of the substrate;
first channels over the active area in a vertical direction perpendicular to an upper surface of the substrate and spaced apart from each other in a first horizontal direction parallel to the upper surface of the substrate;
first gate lines on the first channel, extending in a second horizontal direction intersecting the first horizontal direction, and spaced apart from each other in the first horizontal direction;
first source/drain areas on opposing sides of each of the first channels in the first horizontal direction;
a second channel over and spaced apart from any one of the first gate lines in the vertical direction;
a second gate line on the second channel and extending in the second horizontal direction;
second source/drain areas on opposing sides of the second channel in the first horizontal direction;
a first insulating layer on an upper surface of each of the first source/drain areas and the second source/drain areas;
a third channel over and spaced apart from the second gate line in the vertical direction;
a third gate line on the third channel and extending in the second horizontal direction;
third source/drain areas on opposing sides of the third channel in the first horizontal direction;
a fifth insulating layer on a first one of the first gate lines not overlapping the second gate line in the vertical direction;
a first lower source/drain contact extending in the vertical direction and electrically connected to a given one of the first source/drain areas, a given one of the second source/drain areas, and a given one of the third source/drain areas;
a first upper gate contact electrically connected to the third gate line;
a second upper gate contact electrically connected to a first one of the first gate lines not overlapping the second gate line in the vertical direction;
a first lower gate contact electrically connected to a second one of the first gate lines overlapping the second gate line in the vertical direction;
a first upper source/drain contact electrically connected to a given one of the second source/drain areas and a given one of the third source/drain areas;
a second lower source/drain contact electrically connected to one of the first source/drain areas on a side of the second upper gate contact in the first horizontal direction;
a first upper signal line electrically connected to the first upper source/drain contact;
a second upper signal line electrically connected to the first upper gate contact and the second upper gate contact;
a first lower signal line electrically connected to the first lower source/drain contact;
a second lower signal line electrically connected to the second lower source/drain contact; and
a third lower signal line electrically connected to the first lower gate contact,
wherein each of the first gate lines comprises a first sub-gate and a first main gate, a first sub-gate insulating layer is on an upper surface of the first sub-gate, and a first main gate insulating layer is on an upper surface of the first main gate,
the second gate line comprises a second sub-gate and a second main gate, a second sub-gate insulating layer is on an upper surface of the second sub-gate, and a second main gate insulating layer is on an upper surface of the second main gate, and
the fifth insulating layer overlaps each of the second gate line and the third gate line in the first horizontal direction.

19. The multi-stack semiconductor device of claim 18, wherein
the second lower signal line is configured to provide first power to the second lower source/drain contact,
the first upper signal line is configured to provide second power to the first upper source/drain contact,
the second upper signal line is configured to provide a first signal to each of the first upper gate contact and the second upper gate contact, and
the third lower signal line is configured to provide a second signal to the first lower gate contact.

20. The multi-stack semiconductor device of claim 18, wherein
the first upper signal line is configured to provide first power to the first upper source/drain contact,
the second lower signal line is configured to provide second power to the second lower source/drain contact,
the second upper signal line is configured to provide a second signal to each of the first upper gate contact and the second upper gate contact, and
the third lower signal line is configured to provide a first signal to the first lower gate contact.
